(19) United States
(12) Patent Application Publication
(10) Pub. No.: US 2025/0248215 A1
(43) Pub. Date: Jul. 31, 2025

(54) SEMICONDUCTOR DEVICE

(71) Applicant: Semiconductor Energy Laboratory Co., Ltd., Atsugi-shi (JP)

(72) Inventors: Hidetomo KOBAYASHI, Isehara (JP); Toshihiko SAITO, Atsugi (JP); Hajime KIMURA, Atsugi (JP); Shunpei YAMAZAKI, Setagaya (JP)

(21) Appl. No.: 19/019,596

(22) Filed: Jan. 14, 2025

(30) Foreign Application Priority Data
Jan. 30, 2024 (JP) 2024-012045

(51) Int. Cl. H10K 59/121; G09G 3/3233; H10K 59/131

(52) U.S. Cl. CPC H10K 59/1213; H10K 59/131; G09G 3/3233; G09G 2300/0852; G09G 2310/08

(57) ABSTRACT

A novel semiconductor device is provided. The semiconductor device includes first to seventh transistors. The first transistor is between a wiring to which a video signal is supplied and a gate of the second transistor. The third transistor is between the gate and a source of the second transistor. The fourth transistor is connected to a back gate of the second transistor. The fifth transistor is between the source of the second transistor and a light-emitting element. The sixth transistor is connected to the source of the second transistor. The seventh transistor is connected to a gate of the fifth transistor. The channel length of the first transistor is longer than that of each of the third, fourth, and seventh transistors.

### BACKGROUND OF THE INVENTION

### 1. Field of the Invention

One embodiment of the present invention relates to a semiconductor device.

Note that one embodiment of the present invention is not limited to the above technical field. Examples of the technical field of one embodiment of the present invention disclosed in this specification and the like include a semiconductor device, a display device, a light-emitting apparatus, a power storage device, a memory device, an electronic device, a lighting device, an input device, an input/output device, a driving method thereof, and a manufacturing method thereof.

### 2. Description of the Related Art

In recent years, electronic devices such as smartphones and tablet terminals have been widespread. In addition, goggles-type devices and glasses-type devices have been developed as electronic devices for virtual reality (VR), augmented reality (AR), and mixed reality (MR).

Examples of display devices included in such electronic devices include a liquid crystal display device and a self-luminous display device. A self-luminous display device includes a light-emitting element such as an organic electroluminescent (EL) element or a light-emitting diode (LED).

An organic EL element has a structure in which a layer containing a light-emitting organic compound is interposed between a pair of electrodes, for example. When a potential difference is generated between the pair of electrodes so that current flows through the layer containing the light-emitting organic compound, light emission can be obtained. A display device including such an organic EL element needs no backlight, which is necessary for a liquid crystal display device and the like; thus, thin, lightweight, high-contrast, and low-power display devices can be obtained. Patent Document 1, for example, discloses an example of a display device including an organic EL element.

Patent Document 2 discloses a circuit configuration of a pixel circuit for controlling the emission luminance of an organic EL element, in which a threshold voltage variation between transistors is corrected in each pixel to increase the display quality of a display device.

### REFERENCES

### Patent Documents

[Patent Document 1] Japanese Published Patent Application No. 2002-324673
[Patent Document 2] Japanese Published Patent Application No. 2015-132816

### SUMMARY OF THE INVENTION

Meanwhile, a high voltage is sometimes needed for obtaining light emission at required luminance, depending on the structure of an organic EL element. Thus, a high voltage is sometimes applied to at least some of transistors included in a pixel circuit. Application of a high voltage to the transistors for a long time easily changes the electrical characteristics of the transistors. Changes in the electrical characteristics of the transistors cause a decrease in display quality, an increase in power consumption, a decrease in reliability, and the like of a display device.

An object of one embodiment of the present invention is to provide a display device with high display quality. Another object of one embodiment of the present invention is to provide a high-resolution display device. Another object of one embodiment of the present invention is to provide a highly reliable display device. Another object of one embodiment of the present invention is to provide a display device with low power consumption. Another object of one embodiment of the present invention is to provide a novel display device. Another object of one embodiment of the present invention is to provide a highly reliable semiconductor device. Another object of one embodiment of the present invention is to provide a semiconductor device with low power consumption. Another object of one embodiment of the present invention is to provide a novel semiconductor device.

Note that the description of the above objects does not preclude the existence of other objects. Those skilled in the art can find and extract other objects from the description of the specification, the drawings, the claims, and the like. Note that one embodiment of the present invention does not necessarily achieve all of these objects (the above objects and the other objects).
(1) One embodiment of the present invention is a semiconductor device including first to seventh transistors, first to third capacitors, and a light-emitting element. The first to seventh transistors each include a gate, a first terminal, and a second terminal. The first to third capacitors and the light-emitting element each include a first terminal and a second terminal. The second transistor includes a back gate. The second terminal of the first transistor is electrically connected to the gate of the second transistor, the first terminal of the third transistor, and the first terminal of the first capacitor. The back gate of the second transistor is electrically connected to the second terminal of the fourth transistor and the first terminal of the second capacitor. The second terminal of the second transistor is electrically connected to the second terminal of the third transistor, the second terminal of the first capacitor, the second terminal of the second capacitor, the first terminal of the fifth transistor, and the first terminal of the sixth transistor. The gate of the fifth transistor is electrically connected to the first terminal of the third capacitor and the second terminal of the seventh transistor. The second terminal of the fifth transistor is electrically connected to the second terminal of the third capacitor and the first terminal of the light-emitting element. The channel length of the first transistor is longer than that of each of the third, fourth, and seventh transistors.
(2) Another embodiment of the present invention is a semiconductor device including first to seventh transistors, first to third capacitors, and a light-emitting element. The first to seventh transistors each include a gate, a first terminal, and a second terminal. The first to third capacitors and the light-emitting element each include a first terminal and a second terminal. The second transistor includes a back gate. The second terminal of the first transistor is electrically connected to the gate of the second transistor, the first terminal of the third transistor, and the first terminal of the first capacitor. The back gate of the second transistor is electrically connected to the second terminal of the fourth transistor and the first terminal of the second capacitor. The second terminal of the second transistor is electrically connected to the second terminal of the third transistor, the second terminal of the first capacitor, the second terminal of the second capacitor, the first terminal of the fifth transistor, and the first terminal of the sixth transistor. The gate of the fifth transistor is electrically connected to the first terminal of the third capacitor and the second terminal of the seventh transistor. The second terminal of the fifth transistor is electrically connected to the second terminal of the third capacitor and the first terminal of the light-emitting element. The first transistor is a multi-gate transistor with a series number greater than or equal to 3. The third, fourth, and seventh transistors are each a multi-gate transistor with a series number less than or equal to the series number of the first transistor.

For example, the gate of the first transistor is electrically connected to a first wiring, the gate of the third transistor and the gate of the fourth transistor are electrically connected to a second wiring, the first terminal of the seventh transistor is electrically connected to a third wiring, the gate of the sixth transistor and the gate of the seventh transistor are electrically connected to a fourth wiring, the first terminal of the first transistor is electrically connected to a fifth wiring, the first terminal of the second transistor is electrically connected to a sixth wiring, the first terminal of the fourth transistor is electrically connected to a seventh wiring, the second terminal of the sixth transistor is electrically connected to an eighth wiring, and the second terminal of the light-emitting element is electrically connected to a ninth wiring.

It is preferable to use, as the first transistor, a transistor including an oxide semiconductor in a semiconductor layer where a channel is formed. As the light-emitting element, an organic EL element can be used, for example.

According to one embodiment of the present invention, a display device with high display quality can be provided. A high-resolution display device can be provided. A highly reliable display device can be provided. According to another embodiment of the present invention, a display device with low power consumption can be provided. A novel display device can be provided. A highly reliable semiconductor device can be provided. A semiconductor device with low power consumption can be provided. A novel semiconductor device can be provided.

Note that the description of the above effects does not preclude the existence of other effects. Those skilled in the art can find and extract other effects from the description of the specification, the drawings, the claims, and the like. Note that one embodiment of the present invention does not necessarily have all of these effects (the above effects and the other effects).

### BRIEF DESCRIPTION OF THE DRAWINGS

In the accompanying drawings:

FIG. 1 illustrates an example of a circuit configuration of a semiconductor device;

FIG. 2 illustrates an example of a circuit configuration of a semiconductor device;

FIG. 3 illustrates an example of a circuit configuration of a semiconductor device;

FIG. 4 illustrates an example of a circuit configuration of a semiconductor device;

FIGS. 5A and 5B illustrate structure examples of a transistor;

FIG. 6 illustrates an example of a circuit configuration of a semiconductor device;

FIG. 7 illustrates an example of a circuit configuration of a semiconductor device;

FIG. 8 illustrates an example of a circuit configuration of a semiconductor device;

FIG. 9 illustrates an example of a circuit configuration of a semiconductor device;

FIG. 10 illustrates an example of a circuit configuration of a semiconductor device;

FIG. 11 illustrates an example of a circuit configuration of a semiconductor device;

FIG. 12 illustrates an example of a circuit configuration of a semiconductor device;

FIG. 13 illustrates an example of a circuit configuration of a semiconductor device;

FIG. 14 illustrates an example of a circuit configuration of a semiconductor device;

FIG. 15 is a timing chart showing an operation example of a semiconductor device;

FIG. 16 illustrates an operation example of a semiconductor device;

FIG. 17 illustrates an operation example of a semiconductor device;

FIG. 18 illustrates an operation example of a semiconductor device;

FIG. 19 illustrates an operation example of a semiconductor device;

FIG. 20 illustrates an operation example of a semiconductor device;

FIG. 21 illustrates an operation example of a semiconductor device;

FIGS. 22A1 to 22A7 and FIGS. 22B1 to 22B6 each illustrate electrical connection;

FIGS. 23A to 23C illustrate a structure example of a transistor;

FIGS. 24A to 24C illustrate a structure example of a transistor;

FIGS. 25A and 25B illustrate a structure example of a transistor;

FIGS. 26A and 26B illustrate a structure example of a transistor;

FIGS. 27A and 27B illustrate a structure example of a transistor;

FIGS. 28A to 28C illustrate a structure example of a transistor;

FIGS. 29A to 29C illustrate a structure example of a transistor;

FIGS. 30A to 30C illustrate a structure example of a transistor;

FIGS. 31A to 31E illustrate a structure example of a transistor;

FIGS. 32A and 32B illustrate a structure example of a transistor;

FIGS. 33A to 33E illustrate a structure example of a transistor;

FIG. 34 illustrates a structure example of a transistor;

FIGS. 35A to 35E illustrate a structure example of a transistor;

FIGS. 36A to 36D are cross-sectional views illustrating a method for forming a metal oxide;

FIGS. 37A to 37D are cross-sectional views illustrating a method for forming a metal oxide;

FIG. 38 illustrates an example of a planar layout of a semiconductor device;

FIGS. 39A and 39B illustrate cross-sectional structure examples of a semiconductor device;

FIG. 40 illustrates an example of a planar layout of a semiconductor device;

FIG. 41 illustrates an example of a planar layout of a semiconductor device;

FIG. 42 illustrates an example of a planar layout of a semiconductor device;

FIGS. 43A and 43B illustrate cross-sectional structure examples of a semiconductor device;

FIG. 44A is a perspective view illustrating a structure example of a display device, and

FIGS. 44B to 44F are plan views illustrating examples of pixel arrangement;

FIGS. 45A to 45D illustrate structure examples of a light-emitting element;

FIGS. 46A to 46D illustrate structure examples of light-emitting elements;

FIGS. 47A to 47D illustrate structure examples of light-emitting elements;

FIGS. 48A to 48C illustrate structure examples of light-emitting elements;

FIG. 49 is a block diagram illustrating a structure example of a display device;

FIGS. 50A and 50B are block diagrams each illustrating a structure example of a display device;

FIGS. 51A and 51B are block diagrams each illustrating a structure example of a display device;

FIGS. 52A to 52C are circuit diagrams illustrating a structure example of a semiconductor device, FIG. 52D is a timing chart showing an operation example of the semiconductor device, and FIG. 52E is a circuit diagram illustrating a structure example of the semiconductor device;

FIGS. 53A and 53B illustrate structure examples of a display device;

FIGS. 54A to 54D illustrate examples of electronic devices;

FIGS. 55A to 55F illustrate examples of electronic devices;

FIGS. 56A to 56G illustrate examples of electronic devices;

FIGS. 57A and 57B show evaluation results of the reliability of transistors; and

FIGS. 58A and 58B show evaluation results of the reliability of transistors.

### DETAILED DESCRIPTION OF THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

In this specification and the like, a semiconductor device refers to a device that utilizes semiconductor characteristics, and means a circuit including a semiconductor element (e.g., a transistor, a diode, or a photodiode), a device including the circuit, and the like. The semiconductor device also means devices that can function by utilizing semiconductor characteristics. For example, an integrated circuit, a chip including an integrated circuit, and an electronic component including a chip in a package are examples of the semiconductor device. In some cases, a memory device, a display device, a light-emitting apparatus, a lighting device, an electronic device, and the like themselves are semiconductor devices and also include a semiconductor device.

In the drawings and the like related to this specification, the size, the layer thickness, or the region is exaggerated for clarity in some cases. Therefore, embodiments of the present invention are not limited to the size, aspect ratio, or the like shown in the drawings. The drawings are schematic views showing ideal examples, and embodiments of the present invention are not limited to shapes, values, or the like shown in the drawings.

Note that in the structures of the invention described in the embodiments, the same portions or portions having similar functions are denoted by the same reference numerals in different drawings and the description of such portions is not repeated in some cases. The same hatching pattern is used for portions having similar functions, and the portions are not denoted by specific reference numerals in some cases. Moreover, some components may be omitted in a perspective view, a plan view, or the like for easy understanding of the drawings.

Ordinal numbers such as “first” and “second” in this specification and the like are used in order to avoid confusion among components. Thus, the terms do not limit the number of components. The terms do not limit the order of components, either. For example, a “first” component in one embodiment in this specification and the like can be referred to as a “second” component in other embodiments, claims, or the like. For another example, a “first” component in one embodiment in this specification and the like can be omitted in other embodiments, claims, or the like. A term without an ordinal number in this specification might be provided with an ordinal number in a claim in order to avoid confusion among components. A term with an ordinal number in this specification might be provided with a different ordinal number in a claim. Moreover, a term with an ordinal number in this specification might not be provided with any ordinal number in a claim and the like.

In this specification and the like, terms for describing arrangement, such as “over”, “under”, “above”, and “below”, are sometimes used for convenience to describe the positional relation between components with reference to drawings. The positional relation between components is changed as appropriate in accordance with the direction in which each component is described. Thus, the positional relation is not limited to that described with a term used in this specification and the like and can be explained with another term as appropriate depending on the situation. For example, the expression “an insulator over (on) the top surface of a conductor” can be replaced with the expression “an insulator on the bottom surface of a conductor” when the direction of a drawing showing these components is rotated by 180°.

The term such as “over” or “under” does not necessarily mean that a component is placed directly on or under and directly in contact with another component. For example, the expression “an electrode B over an insulating layer A” does not necessarily mean that the electrode B is on and in direct contact with the insulating layer A, and can mean the case where another component is provided between the insulating layer A and the electrode B.

The term “overlap”, for example, in this specification and the like does not limit a state such as the stacking order of components. For example, the expression “an electrode B overlapping with an insulating layer A” does not necessarily mean the state where the electrode B is formed over the insulating layer A, and includes the case where the electrode B is formed under the insulating layer A and the case where the electrode B is formed on the right (or left) side of the insulating layer A.

In this specification and the like, the terms “film” and “layer” can be interchanged with each other depending on circumstances. For example, the term “conductive layer” can be changed into the term “conductive film” in some cases. For another example, the term “insulating film” can be changed into the term “insulating layer” in some cases. Moreover, such terms can be replaced with a word not including the term “film” or “layer” depending on the case or circumstances. For example, the term “conductive layer” or “conductive film” can be changed into the term “conductor” in some cases. Alternatively, the term “conductor” can be changed into the term “conductive layer” or “conductive film” in some cases. For another example, the term “insulating layer” or “insulating film” can be changed into the term “insulator” in some cases. For another example, the term “insulator” can be changed into the term “insulating layer” or “insulating film” in some cases.

In this specification and the like, the terms “electrode”, “wiring”, “terminal”, and the like do not limit the functions of components. For example, an “electrode” is used as part of a “wiring” in some cases, and vice versa. Furthermore, for example, the term “electrode” or “wiring” can also mean a combination of a plurality of “electrodes” or “wirings” provided in an integrated manner. For another example, a “terminal” is used as part of a “wiring” or an “electrode” in some cases, and vice versa. Furthermore, the term “terminal” includes the case where a plurality of “electrodes”, “wirings”, “terminals”, or the like are formed in an integrated manner. Therefore, for example, an “electrode” can be part of a “wiring” or a “terminal”, and a “terminal” can be part of a “wiring” or an “electrode”. Moreover, the terms “electrode”, “wiring”, and “terminal” are sometimes replaced with the term “region” and “conductive layer”, for example.

In this specification and the like, the terms “wiring”, “signal line”, “power supply line”, and the like can be interchanged with each other depending on the case or in accordance with circumstances. For example, the term “wiring” can be changed into the term “signal line” in some cases. For another example, the term “wiring” can be changed into the term such as “power supply line” in some cases. Conversely, the term such as “signal line” or “power supply line” can be changed into the term “wiring” in some cases. The term “power supply line” or the like can be changed into the term “signal line” or the like in some cases. Conversely, the term “signal line” or the like can be changed into the term “power supply line” or the like in some cases. The term “potential” that is applied to a wiring can be changed into the term “signal” or the like depending on the case or in accordance with circumstances. Conversely, the term “signal” or the like can be changed into the term “potential” in some cases.

In this specification, a “source” refers to a source region, a source electrode, or a source wiring. A source region refers to one of two regions adjacent to a channel formation region in a semiconductor layer. A source electrode refers to a conductive layer including part connected to a source region.

In this specification, a “drain” refers to a drain region, a drain electrode, or a drain wiring. A drain region refers to the other of the two regions adjacent to the channel formation region in the semiconductor layer. A drain electrode refers to a conductive layer including part connected to a drain region.

In this specification, a “gate” refers to a gate electrode or a gate wiring. A gate electrode refers to an electrode that overlaps with a semiconductor layer of a transistor and has a function of controlling the resistance between a source and a drain of the transistor with use of a supplied voltage.

In this specification, in some cases, one of a source and a drain of a transistor is referred to as a “first terminal of a transistor” and the other of the source and the drain of the transistor is referred to as a “second terminal of a transistor”.

In this specification, the term “parallel” indicates a state where the angle formed between two straight lines is greater than or equal to −10° and less than or equal to 10°. Thus, the case where the angle is greater than or equal to −5° and less than or equal to 5° is also included. The terms “approximately parallel” and “substantially parallel” indicate a state where the angle formed between two straight lines is greater than or equal to −15° and less than or equal to 15°. The term “perpendicular” indicates a state where the angle formed between two straight lines is greater than or equal to 80° and less than or equal to 100°. Thus, the case where the angle is greater than or equal to 85° and less than or equal to 95° is also included. The terms “approximately perpendicular” and “substantially perpendicular” indicate a state where the angle formed between two straight lines is greater than or equal to 60° and less than or equal to 120°.

Voltage refers to a difference between a given potential and a reference potential (e.g., a ground potential or a source potential) in many cases. Therefore, the terms “voltage” and “potential” can be replaced with each other in many cases. In this specification and the like, “voltage” and “potential” can be replaced with each other unless otherwise specified.

In this specification and the like, a high power supply potential VDD (hereinafter, also simply referred to as “VDD”) refers to a power supply potential higher than a low power supply potential VSS (hereinafter, also simply referred to as “VSS”). In addition, a ground potential GND (hereinafter, also simply referred to as “GND”) can be used as VDD or VSS. For example, VSS is a potential lower than GND when VDD is GND, and VDD is a potential higher than GND when VSS is GND.

In this specification, an “on state” of a transistor refers to a state where electrical continuity is established between a source and a drain of the transistor (a state where current can flow between the source and the drain). Furthermore, an “off state” of a transistor refers to a state where electrical continuity is not established between a source and a drain of the transistor (a state where the source and the drain can be regarded as being electrically disconnected).

In this specification and the like, “on-state current” means current that flows between a source and a drain when a transistor is in an on state. In addition, “off-state current” means current that flows between a source and a drain when a transistor is in an off state.

In this specification and the like, a potential H is a potential with which an n-channel field-effect transistor (also referred to as an “n-type transistor”) is turned on and also a potential with which a p-channel field-effect transistor (also referred to as a “p-type transistor”) is turned off. A potential L is a potential with which an n-type transistor is turned off and a p-type transistor is turned on. Thus, the potential H is higher than the potential L. The potential H is sometimes equal to VDD. The potential L is sometimes equal to VSS. Unless otherwise specified, transistors described in this specification are enhancement (normally-off) n-type transistors.

In the drawings and the like, for easy understanding of the potentials of a wiring, an electrode, and the like, “H” representing the potential H or “L” representing the potential L is sometimes written near the wiring, the electrode, and the like. In addition, enclosed “H” or “L” is sometimes written near a wiring, an electrode, and the like whose potentials are changed. Moreover, a symbol “x” is sometimes written on a transistor in an off state. Furthermore, arrows indicating the direction of current flowing are shown in some cases.

In this specification and the like, the terms “identical”, “the same”, “equal”, “uniform”, and the like (including synonyms thereof) used in describing calculation values and actual measurement values allow for a margin of error of +10% unless otherwise specified.

In the drawings and the like related to this specification, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

In general, “capacitance” has a structure in which two electrodes face each other with an insulator (dielectric) therebetween. This specification and the like include a case where a “capacitor” is the above-described “capacitance”. That is, in this specification and the like, the “capacitor” includes one having a structure in which two electrodes face each other with an insulator therebetween, one having a structure in which two wirings face each other with an insulator therebetween, or one having a structure in which two wirings are placed with an insulator therebetween. In this specification, one electrode of a capacitor may be referred to as a “first terminal of a capacitor”, and the other electrode may be referred to as a “second terminal of a capacitor”.

In this specification and the like, a “switch” includes a plurality of terminals and has a function of switching (selecting) electrical continuity and discontinuity between the terminals. For example, in the case where a switch includes two terminals and electrical continuity is established between the two terminals, the switch is in an “on state”. In the case where electrical continuity is not established between the two terminals, the switch is in an “off state”. Note that switching to one of electrical continuity and discontinuity or maintaining one of electrical continuity and discontinuity is sometimes referred to as “controlling electrical continuity”. In the case where a switch includes two terminals in this specification, for example, one of the terminals may be referred to as a “first terminal of a switch” and the other terminal may be referred to as a “second terminal of a switch”.

That is, a switch has a function of controlling electrical continuity. Alternatively, a switch has a function of selecting and changing a current path. For example, an electrical switch or a mechanical switch can be used. That is, a switch is not limited to a certain element and can be any element capable of controlling current.

As a switch, an electrical switch, a mechanical switch, or the like can be used. Examples of an electrical switch include a transistor (e.g., a bipolar transistor and a MOS transistor), a diode (e.g., a PN diode, a PIN diode, a Schottky diode, a metal-insulator-metal (MIM) diode, a metal-insulator-semiconductor (MIS) diode, and a diode-connected transistor), and a logic circuit in which such elements are combined. When a transistor is used as a switch, a “conduction state” of the transistor refers to a state where a source and a drain of the transistor are short-circuited. Furthermore, a “non-conduction state” of the transistor refers to a state where the source and the drain of the transistor are electrically disconnected. In the case where a transistor operates just as a switch, there is no particular limitation on the polarity (conductivity type) of the transistor.

An example of a mechanical switch is a switch using a microelectromechanical systems (MEMS) technology. Such a switch includes an electrode that can be moved mechanically, and its conduction or non-conduction is selected with movement of the electrode.

In this specification, when a plurality of components denoted by the same reference numerals need to be distinguished from each other, identification signs such as “A”, “b”, “1”, “[n]”, and “[m,n]” are sometimes added to the reference numerals.

The expression “connection” in this specification includes “electrical connection”, for example. When the expression “electrical connection” is used to specify the connection relation of a circuit element as an object, “electrical connection” includes “direct connection” and “indirect connection”, for example. The expression “A and B are directly connected” means that A and B are connected to each other without a circuit element (e.g., a transistor or a switch; a wiring is not a circuit element) therebetween, for example. Meanwhile, the expression “A and B are indirectly connected” means that A and B are connected to each other with at least one circuit element therebetween, for example. Note that A, B, and later-described C each denote an object such as an element, a circuit, a wiring, an electrode, a terminal, or a conductive layer.

Here, in the case where a connection relation is specified as “A and B are indirectly connected”, the following connection relations are included, for example. That is, on the assumption that a circuit is in operation, the circuit can be specified as “A and B are indirectly connected” as an object when electric signal transmission and reception, potential interaction, or the like between A and B occurs at some point during the operation period of the circuit. Note that even when neither electric signal transmission and reception nor potential interaction between A and B occurs at some point during the operation of the circuit, the circuit can be specified as “A and B are indirectly connected” as long as electric signal transmission and reception or potential interaction between A and B occurs at another point during the operation period of the circuit. Note that the expression “A and B are indirectly connected” specifies the connection relation of a circuit element as an object. Thus, even when a circuit is not supplied with a power supply voltage and is not in operation, for example, the circuit can be specified as “A and B are indirectly connected” as an object (note that this specification is limited to, for example, the case where electric signal transmission and reception, potential interaction, or the like between A and B occurs during the operation period of the circuit when the circuit is supplied with a power supply voltage to be in operation).

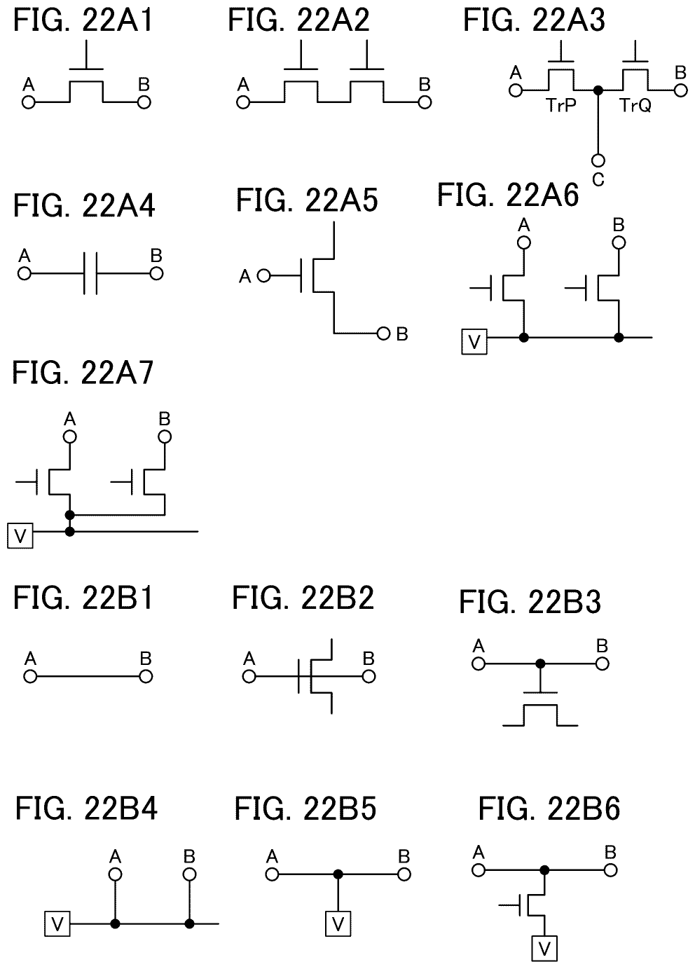

Specific examples of the case of “indirect connection” are described below. First, examples of the case where the expression “A and B are indirectly connected” can be used include the case where A and B are connected to each other through a source and a drain of at least one transistor as in FIG. 22A1 and FIG. 22A2. Another example thereof is the case where A and B are connected to each other with at least one switch therebetween. In the case where the expression “A and B are indirectly connected” can be used, one transistor between A and B is brought into the on state, the conduction state, or the state where current can flow at least once on the assumption that a circuit is in operation. The case where the expression “A and B are indirectly connected” can be used may include a period at which the one transistor between A and B is brought into the off state or the non-conduction state. In the case where the expression “A and B are indirectly connected” can be used, each of a plurality of transistors between A and B is brought into the on state, the conduction state, or the state where current can flow at least once when the plurality of transistors are connected between A and B on the assumption that a circuit is in operation. That is, in the case where the expression “A and B are indirectly connected” can be used, it is not necessary that all of the plurality of transistors be brought into the on state, the conduction state, or the state where current can flow at the same time. Accordingly, in the case where the expression “A and B are indirectly connected” can be used, the plurality of transistors between A and B may be brought into the off state or the non-conduction state at the same time or at different times. For another example, when A and C are connected to each other through a source and a drain of a transistor TrP and B and C are connected to each other through a source and a drain of a transistor TrQ as illustrated in FIG. 22A3, it can be specified as “A and C are indirectly connected”, “B and C are indirectly connected”, or “A and B are indirectly connected”. Note that in the case where a constant potential V is supplied to C from a power source, GND, or the like as described later, the expression “A and C are indirectly connected” or “B and C are indirectly connected” can be used; however, the expression “A and B are indirectly connected” cannot be used.

The examples of the cases where the expression “indirect connection” can be used and cannot be used are described above, and another example of the case where the expression “indirect connection” cannot be used is described below. Even when electric signal transmission and reception, potential interaction, or the like between A and B occurs during the operation period of the circuit, the expression “A and B are indirectly connected” cannot be used in some cases exceptionally. Examples of the exceptional case include the case where A and B are connected to each other with an insulator therebetween. That is, in the case where A and B are connected to each other with an insulator therebetween, the expression “A and B are indirectly connected” cannot be used. A specific example of the case where A and B are connected to each other with an insulator therebetween is the case where a capacitor is connected between A and B as in FIG. 22A4. Another example thereof is the case where there is a gate insulating film of a transistor or the like between A and B as in FIG. 22A5. In that case, the expression “A (a gate of the transistor) and B (a source or a drain of the transistor) are indirectly connected” cannot be used.

Another example of the case where the expression “A and B are indirectly connected” cannot be used is the case where neither electric signal transmission and reception nor potential interaction between A and B occurs. For example, a plurality of transistors are connected through their sources and drains on the path from A to B and a constant potential V is supplied from a power source, GND, or the like to a node between one of the transistors and another one of the transistors as in FIGS. 22A6 and 22A7. In that case, the expression “A and B are indirectly connected” cannot be used; however, the expression “A and V are indirectly connected” or “B and V are indirectly connected” can be used. Note that in FIG. 22A3, when A and C are connected to each other through the source and the drain of the transistor TrP, B and C are connected to each other through the source and the drain of the transistor TrQ, and a constant potential V is supplied to C from a power source, GND, or the like, the same connection relation as that in FIG. 22A6 or FIG. 22A7 is established; thus, the expression “A and B are indirectly connected” cannot be used; however, the expression “A and C are indirectly connected” or “B and C are indirectly connected” can be used.

The examples of “indirect connection” are described above. The specification of “indirect connection” is included in the specification of “electrical connection”, for example; thus, in the case where the expression “A and B are indirectly connected” is used, the expression “A and B are electrically connected” can also be used.

Next, specific examples of the case of “direct connection” are described. Examples of the case where the expression “A and B are directly connected” can be used include the case where A and B are connected to each other without a circuit element therebetween as in FIGS. 22B1, 22B2, and 22B3. When A and B are connected to a power source, GND, or the like from which a constant potential V is supplied without a circuit element therebetween as in FIGS. 22B4 and 22B5, the expression “A and B are directly connected”, “A and V are directly connected”, or “B and V are directly connected” can be used. Note that when A (or B) is connected to a constant potential V through a source and a drain of a transistor as in FIG. 22B6, the expression “A and B are directly connected” can also be used. Note that A and V or B and V are connected to each other through the source and the drain of the transistor and thus they cannot be regarded as being in direct connection, and the expression “A and V are indirectly connected” or “B and V are indirectly connected” can be used.

The examples of “direct connection” are described above. The specification of “direct connection” is included in the specification of “electrical connection”, for example; thus, in the case where the expression “A and B are directly connected” is used, the expression “A and B are electrically connected” can also be used.

Note that one embodiment of the present invention includes a structure in which at least one of a gate, a source, and a drain of one or more transistors is connected to nothing or a given node. One embodiment of the present invention also includes a structure in which nothing, a given signal, or a given voltage is input to one or more wirings.

### Embodiment 1

A semiconductor device 10A of one embodiment of the present invention will be described with reference to drawings. The semiconductor device 10A can be used as a pixel of a display device, for example.

### Configuration Example

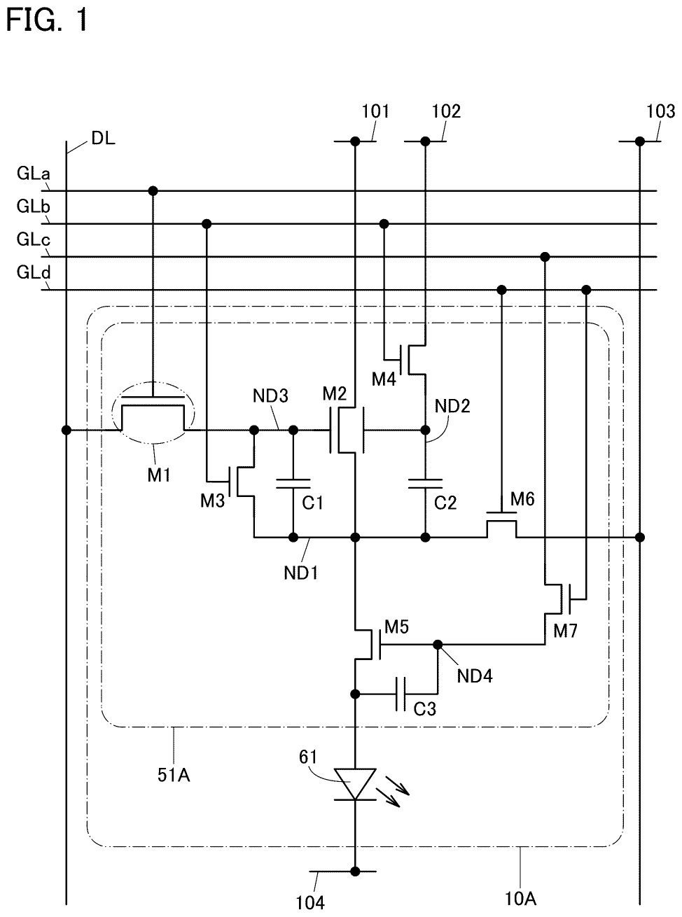

FIG. 1 illustrates an example of a circuit configuration of the semiconductor device 10A. The semiconductor device 10A includes a pixel circuit 51A and a light-emitting element 61. The pixel circuit 51A includes transistors M1 to M7 and capacitors C1 to C3. In the semiconductor device 10A illustrated in FIG. 1, the transistors M1 to M7 are n-channel transistors, and their threshold voltages (also referred to as “Vth”) are higher than 0 V.

A gate of the transistor M1 is connected to a wiring GLa, one of a source and a drain of the transistor M1 is connected to a wiring DL, and the other of the source and the drain is connected to a gate of the transistor M2. The transistor M1 has a function of selecting whether to establish electrical continuity between the gate of the transistor M2 and the wiring DL.

The gate of the transistor M2 is connected to one terminal of the capacitor C1, one of a source and a drain of the transistor M2 is connected to a wiring 101, and the other of the source and the drain is connected to the other terminal of the capacitor C1 (see FIG. 1). The transistor M2 has a back gate. The back gate of the transistor M2 is connected to one terminal of the capacitor C2. The other terminal of the capacitor C2 is connected to the other of the source and the drain of the transistor M2.

A gate of the transistor M3 is connected to a wiring GLb, one of a source and a drain of the transistor M3 is connected to the one terminal of the capacitor C1, and the other of the source and the drain is connected to the other terminal of the capacitor C1. The transistor M3 has a function of selecting whether to establish electrical continuity between the gate and the other of the source and the drain of the transistor M2.

A gate of the transistor M4 is connected to the wiring GLb, one of a source and a drain of the transistor M4 is connected to a wiring 102, and the other of the source and the drain is connected to the one terminal of the capacitor C2 and the back gate of the transistor M2. The transistor M4 has a function of selecting whether to establish electrical continuity between the wiring 102 and the one terminal of the capacitor C2. The transistor M4 also has a function of selecting whether to establish electrical continuity between the wiring 102 and the back gate of the transistor M2.

A gate of the transistor M5 is connected to one terminal of the capacitor C3, and one of a source and a drain of the transistor M5 is connected to the other of the source and the drain of the transistor M2, the other of the source and the drain of the transistor M3, the other terminal of the capacitor C1, the other terminal of the capacitor C2, and one of a source and a drain of the transistor M6. The other of the source and the drain of the transistor M5 is connected to the other terminal of the capacitor C3 and a first terminal (e.g., an anode terminal) of the light-emitting element 61. A second terminal (e.g., a cathode terminal) of the light-emitting element 61 is connected to a wiring 104.

A gate of the transistor M6 is connected to a wiring GLd, and the other of the source and the drain of the transistor M6 is connected to a wiring 103. The transistor M6 has a function of selecting whether to establish electrical continuity between the other of the source and the drain of the transistor M2 and the wiring 103.

A gate of the transistor M7 is connected to the wiring GLd, one of a source and a drain of the transistor M7 is connected to a wiring GLc, and the other of the source and the drain is connected to the gate of the transistor M5. The transistor M7 has a function of selecting whether to establish electrical continuity between the gate of the transistor M5 and the wiring GLc.

A region where the other terminal of the capacitor C1, the other terminal of the capacitor C2, the other of the source and the drain of the transistor M2, the other of the source and the drain of the transistor M3, the one of the source and the drain of the transistor M5, and the one of the source and the drain of the transistor M6 are connected to one another and always have the same potential in a circuit operation is referred to as a node ND1.

A region where the one terminal of the capacitor C2, the back gate of the transistor M2, and the other of the source and the drain of the transistor M4 are connected to one another and always have the same potential in a circuit operation is referred to as a node ND2.

A region where the other of the source and the drain of the transistor M1, the one of the source and the drain of the transistor M3, the one terminal of the capacitor C1, and the gate of the transistor M2 are connected to one another and always have the same potential in a circuit operation is referred to as a node ND3.

A region where the gate of the transistor M5, the one terminal of the capacitor C3, and the other of the source and the drain of the transistor M7 are connected to one another and always have the same potential in a circuit operation is referred to as a node ND4.

The capacitor C1 has a function of retaining a potential difference between the gate of the transistor M2 and the other of the source and the drain of the transistor M2 when the node ND3 is in a floating state. The capacitor C2 has a function of retaining a potential difference between the back gate of the transistor M2 and the other of the source and the drain of the transistor M2 when the node ND2 is in a floating state. The capacitor C3 has a function of retaining a potential difference between the gate of the transistor M5 and the other of the source and the drain of the transistor M5 when the node ND4 is in a floating state.

Note that the transistor M2 has a function of controlling the amount of current Ie flowing through the light-emitting element 61. That is, the transistor M2 has a function of controlling the amount of light emitted from the light-emitting element 61. Thus, the transistor M2 is also referred to as a “driving transistor”. Among the transistors included in the pixel circuit 51A, the transistors M1, M3, M4, M5, M6, and M7 function as switches.

The transistor M5 has a function of switching electrical continuity and discontinuity between the transistor M2 and the light-emitting element 61. The light-emitting element 61 is off when the transistor M5 is in the off state, and can emit light when the transistor M5 is in the on state. Thus, the transistor M5 is also referred to as a “light-emitting transistor”. In order to surely supply current with the amount determined by the driving transistor to the light-emitting element 61, the transistor M5 needs to be surely turned on regardless of the values of the source potential and the drain potential. The capacitor C3 is a capacitor for surely turning on the transistor M5.

It is generally known that an increase in the channel length L of a transistor leads to an improvement in the electrical characteristics (also referred to as saturation characteristics) in a saturation region of the transistor. Since the driving transistor of the semiconductor device 10A operates in a saturation region, saturation characteristics are important. By contrast, saturation characteristics are not so important for a transistor functioning as a switch. Thus, the channel length L of the driving transistor is preferably longer than that of the transistor functioning as a switch. For example, in the pixel circuit 51A, the channel length L of the transistor M2 is preferably longer than that of each of the transistors M1, M3, M4, M5, M6, and M7.

Note that the channel length L of the transistor M2 can be the same as that of at least one of the transistors M1, M3, M4, M5, M6, and M7. Alternatively, the channel length L of the transistor M2 can be shorter than that of at least one of the transistors M1, M3, M4, M5, M6, and M7.

The present inventors have found that an increase in the channel length L of a transistor leads not only to an improvement in saturation characteristics but also to an improvement in the reliability of the transistor. For example, when a potential lower than a source potential is applied to a gate of a transistor, the “Id-Vg characteristics”, which are kinds of electrical characteristics of a transistor and show a drain current (Id) change with respect to a gate voltage (Vg) change, are likely to shift in the negative direction. Thus, the transistor is likely to be normally on. In this specification, application of a potential lower than a source potential to a gate of a transistor is rephrased as “application of a negative bias to a gate”. In addition, application of a potential higher than a source potential to a gate of a transistor is rephrased as “application of a positive bias to a gate”.

The amount of shift in the electrical characteristics of a transistor depends on the amount, application time, application temperature, and the like of a negative bias applied to a gate. The present inventors have found that an increase in the channel length L of a transistor inhibits a shift in the electrical characteristics that would be caused when a negative bias is applied to a gate.

In terms of the operation of the semiconductor device 10A, a strong negative bias is likely to be applied to the gate of the transistor M1. When the transistor M1 becomes normally on because of a change in its electrical characteristics, it becomes difficult to maintain the potential of the node ND3. This causes a decrease in the display quality of a display device including the semiconductor device 10A. Application of a stronger negative bias to the gate of the transistor M1 for surely turning off the transistor M1 that has become normally on increases the power consumption. The present inventors have found that the use of a transistor having a long channel length L as the transistor M1 can reduce the influence of a negative bias and thus enables a display device including the semiconductor device 10A to have higher reliability, higher display quality, and lower power consumption.

In terms of the operation of the semiconductor device 10A, the strongest negative bias is likely to be applied to the gate of the transistor M1 as described above. Thus, the channel length L of the transistor M1 is preferably longer than that of each of the transistors M3, M4, M5, M6, and M7.

Note that the channel length L of the transistor M1 can be the same as that of at least one of the transistors M3, M4, M5, M6, and M7. Alternatively, the channel length L of the transistor M1 can be shorter than that of at least one of the transistors M3, M4, M5, M6, and M7.

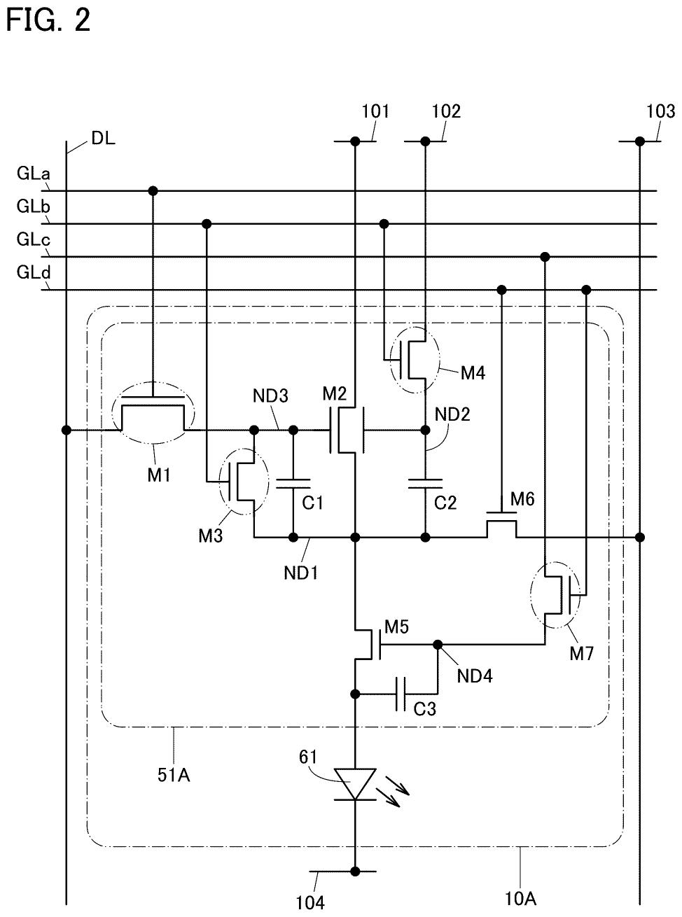

In terms of the circuit operation, the second strongest negative bias is likely to be applied to the transistors M3, M4, and M7 among the transistors included in the semiconductor device 10A (see FIG. 2). Note that the negative bias applied to the gate of each of the transistors M3, M4, and M7 is weaker than that applied to the gate of the transistor M1; thus, the transistors M3, M4, and M7 are less likely to be affected by the negative bias than the transistor M1. Accordingly, the channel length L of each of the transistors M3, M4, and M7 can be shorter than that of the transistor M1.

In terms of the circuit operation, the transistors M5 and M6 are less likely to be affected by a negative bias among the transistors included in the semiconductor device 10A. Thus, the channel length L of each of the transistors M5 and M6 can be shorter than that of each of the transistors M3, M4, and M7.

When the channel length L is set for each of the transistors included in the semiconductor device 10A in this manner, the area occupied by the semiconductor device 10A can be reduced. In addition, the power consumption of the semiconductor device 10A can be reduced.

Furthermore, one or both of the definition and the resolution of a display device including the semiconductor device 10A as a pixel can be increased.

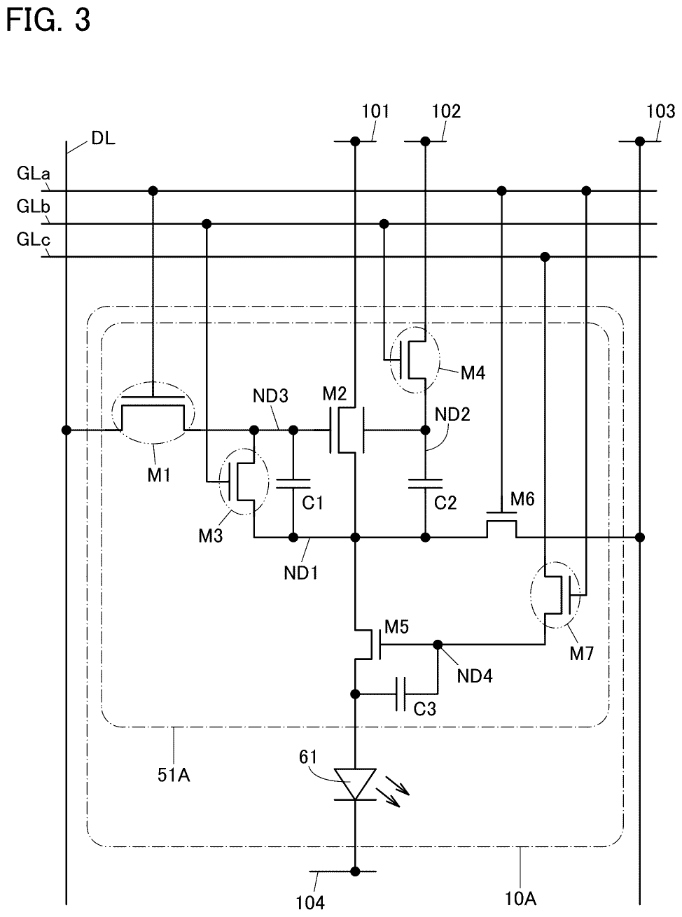

Although FIG. 1 and FIG. 2 illustrate the example in which the semiconductor device 10A is connected to four wirings GL (the wirings GLa to GLd), the wiring GLd can be omitted when the gates of the transistors M6 and M7 are connected to the wiring GLa. Omitting the wiring GLd can increase one or both of the definition and the resolution of a display device including the semiconductor device 10A as a pixel (see FIG. 3).

Furthermore, omitting the wiring GLd can increase the area occupied by the semiconductor device 10A functioning as a pixel. An increase in the area occupied by the semiconductor device 10A can improve the design flexibility of the semiconductor device 10A, thereby increasing the productivity of the semiconductor device 10A. An increase in the area occupied by the semiconductor device 10A can also increase the light-emitting area of the light-emitting element 61. This can increase the emission luminance of the light-emitting element 61 without a change in the density of current supplied to the light-emitting element 61. Moreover, the same emission luminance can be obtained at a lower density of current, so that the reliability of the light-emitting element 61 can be increased. Accordingly, the reliability of the semiconductor device 10A can be increased. In addition, the reliability of a display device including the semiconductor device 10A as a pixel can be increased.

The present inventors have found that a multi-gate transistor in which a plurality of transistors are connected in series and substantially function as one transistor can offer an effect similar to the effect obtained by increasing the channel length L. That is, the present inventors have found that the saturation characteristics are improved also in the multi-gate transistor. In addition, the present inventors have found that a shift in the electrical characteristics that would be caused when a negative bias is applied to a gate is less likely to occur also in the multi-gate transistor.

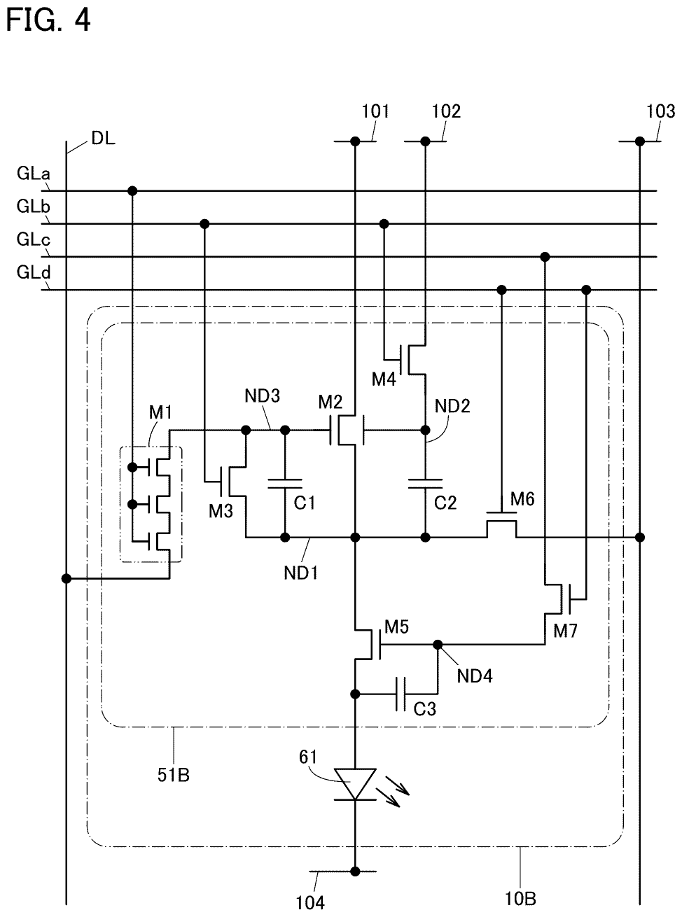

FIG. 4 illustrates an example of a circuit configuration of a semiconductor device 10B. The semiconductor device 10B includes a pixel circuit 51B and the light-emitting element 61. The semiconductor device 10B has a configuration similar to that of the semiconductor device 10A. The pixel circuit 51B has a circuit configuration similar to that of the pixel circuit 51A. Thus, in order to avoid repeated description, differences of the semiconductor device 10B from the semiconductor device 10A are mainly described.

The transistor M1 in the semiconductor device 10B illustrated in FIG. 4 has a structure in which three transistors are connected in series. The semiconductor device 10B is different from the semiconductor device 10A in that a multi-gate transistor in which three or more transistors are connected in series and substantially function as one transistor is used as the transistor M1.

### [Multi-Gate Transistor]

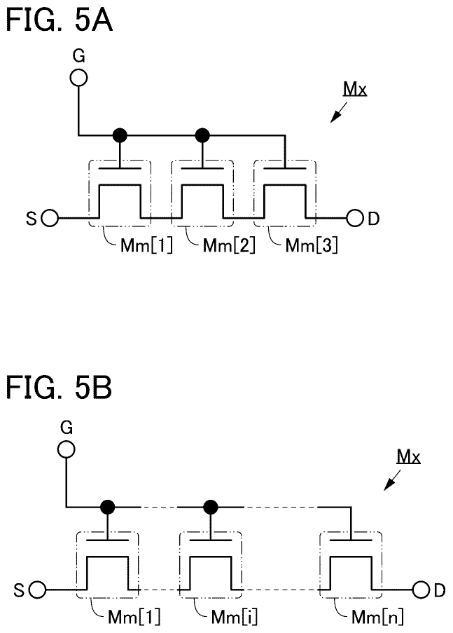

FIGS. 5A and 5B illustrate structure examples of a transistor Mx as a multi-gate transistor that can be used as the transistor M1.

The transistor Mx illustrated in FIG. 5A has a structure in which a transistor Mm[1], a transistor Mm[2], and a transistor Mm[3] are connected in series. Specifically, the transistor Mx illustrated in FIG. 5A has a structure in which one of a source and a drain of the transistor Mm[1] is connected to a terminal S, the other of the source and the drain of the transistor Mm[1] is connected to one of a source and a drain of the transistor Mm[2], the other of the source and the drain of the transistor Mm[2] is connected to one of a source and a drain of the transistor Mm[3], and the other of the source and the drain of the transistor Mm[3] is connected to a terminal D. In addition, gates of the transistors Mm[1], Mm[2], and Mm[3] are connected to one another and connected to a terminal G.

The transistor Mx illustrated in FIG. 5A has a function of switching electrical continuity and discontinuity between the terminal S and the terminal D by changing the potential of the terminal G. Thus, the transistor Mx illustrated in FIG. 5A includes the transistors Mm[1], Mm[2], and Mm[3] and functions as one transistor.

That is, it can be said that in FIG. 5A, one of a source and a drain of the transistor Mx is connected to the terminal S, the other of the source and the drain is connected to the terminal D, and a gate of the transistor Mx is connected to the terminal G. A transistor that includes three transistors and substantially functions as one transistor, like the transistor Mx illustrated in FIG. 5A, is also referred to as a triple-gate transistor. Note that a transistor that includes two transistors and substantially functions as one transistor is also referred to as a double-gate transistor. A transistor that includes a plurality of transistors and substantially functions as one transistor as described above is referred to as a “multi-gate type transistor” or a “multi-gate transistor”.

In this specification, the number of transistors included in the transistor Mx and connected in series is referred to as the “series number”. FIG. 5B illustrates a structure example of the transistor Mx whose series number is n (n is an integer greater than or equal to 2). The i-th transistor Mm (i is an integer greater than or equal to 2 and less than n) in the case where n is greater than or equal to 3 is illustrated as a transistor Mm[i] in FIG. 5B.

In the transistor Mx illustrated in FIG. 5B, one of the source and the drain of the transistor Mm[1] is connected to the terminal S, and one of a source and a drain of the transistor Mm[i] is connected to the other of a source and a drain of a transistor Mm[i−1]. The other of the source and the drain of the transistor Mm[i] is connected to one of a source and a drain of a transistor Mm[i+1]. The other of a source and a drain of a transistor Mm[n] is connected to the terminal D. Gates of the transistors Mm[1] to Mm[n] are connected to one another and connected to the terminal G.

The series number of the transistor Mx that can be used as the transistor M1 may be two or more but is preferably three or more. The use of the transistor Mx with a series number of 3 or more as the transistor M1 can reduce a change in the electrical characteristics of the transistor M1, which can increase the reliability of the semiconductor device 10B.

As in the semiconductor device 10A, a strong negative bias is likely to be applied to the gate of the transistor M1 in terms of the circuit operation in the semiconductor device 10B. Thus, when the transistor M1 becomes normally on, it becomes difficult to maintain the potential of the node ND3. This causes a decrease in display quality and an increase in power consumption of a display device including the semiconductor device 10B.

The present inventors have found that the use of a multi-gate transistor as the transistor M1 can reduce the influence of a negative bias and thus enables a display device including the semiconductor device 10B to have higher display quality and lower power consumption. The present inventors have also found that the use of the transistor Mx with a series number of 3 or more, in particular, has a significant effect of reducing the influence of a negative bias. With the use of the transistor Mx with a series number of 3 or more as the transistor M1, a display device including the semiconductor device 10B can have higher reliability, higher display quality, and lower power consumption. Note that the series number and reliability of the transistor Mx will be described in Example.

A transistor having a back gate can also be used as the transistors other than the transistor M2.

A gate and a back gate of a transistor are provided such that a channel formation region of a semiconductor layer is sandwiched therebetween. A gate and a back gate are each formed using a conductive layer or a semiconductor layer with low resistivity. A back gate can function in a manner similar to that of a gate.

In the case where a gate is used for control of the on/off states of a transistor, the gate and a back gate can have the same potential. In the case where a transistor is turned on, for example, supplying a potential for turning on the transistor to both a gate and a back gate can increase the amount of on-state current as compared with the case of supplying the potential to only one of them. By controlling the potential of a back gate independently of the potential of a gate, the threshold voltage of a transistor can be adjusted.

Since a gate and a back gate are each formed using a conductive layer or the like, when a channel formation region of a semiconductor layer is sandwiched between the gate and the back gate, an electric field generated outside a transistor is unlikely to affect the channel formation region (such a phenomenon is also referred to as an “electric field blocking effect”). Accordingly, the operation of a transistor having a back gate is stable. In addition, when a plurality of transistors have back gates, a variation in characteristics between the transistors is reduced. A transistor having a back gate can have higher reliability. Thus, a semiconductor device including the transistor can have higher reliability. Although an electric field blocking effect can be obtained even when one or both of a gate and a back gate are in an electrically floating state (also referred to as a “floating state”), the effect can be enhanced by supplying a potential to the gate and the back gate.

When a channel formation region of a transistor is irradiated with light, the electrical characteristics of the transistor may change. When a channel formation region of a transistor to which voltage is being applied is irradiated with light, the electrical characteristics of the transistor may be degraded. That is, the reliability of the transistor may be reduced. With the use of a light-blocking conductive material for both a gate and a back gate, degradation of the electrical characteristics of a transistor can be inhibited and its reliability can be increased.

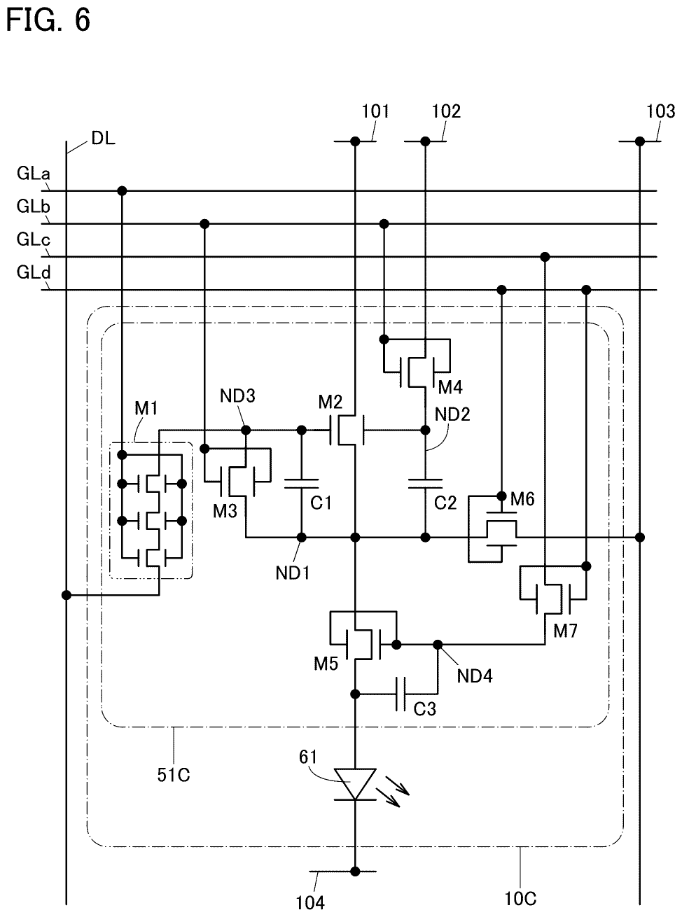

FIG. 6 illustrates an example of a circuit configuration of a semiconductor device 10C in which a transistor having a back gate is used not only as the transistor M2 but also as each of the transistors M1 and M3 to M7. The semiconductor device 10C includes a pixel circuit 51C and the light-emitting element 61. The semiconductor device 10C has the same circuit configuration as the semiconductor device 10B except that all the transistors have back gates.

FIG. 6 illustrates an example in which the gate and the back gate are connected to each other in each of the transistors M1 and M3 to M7. Note that not all the transistors included in the semiconductor device necessarily have a back gate.

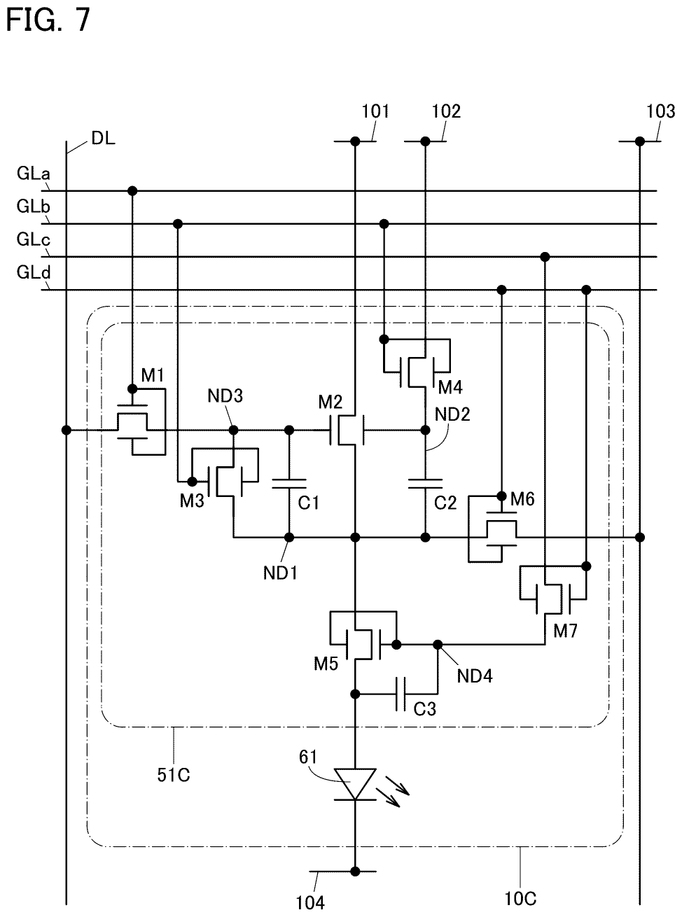

Although the transistor M1 is illustrated as a multi-gate transistor with back gates in FIG. 6, the transistor M1 can be a single-gate transistor with a back gate as illustrated in FIG. 7.

It is not necessary to connect a gate and a back gate, and a given potential can be supplied to the back gate. Note that a potential supplied to a back gate is not limited to a fixed potential.

Potentials supplied to back gates of transistors included in a semiconductor device may be different from one another or may be the same.

### Modification Example

Although FIG. 4 illustrates the example in which the transistor Mx is used as the transistor M1 in the semiconductor device 10B, the transistor Mx can also be used as another transistor.

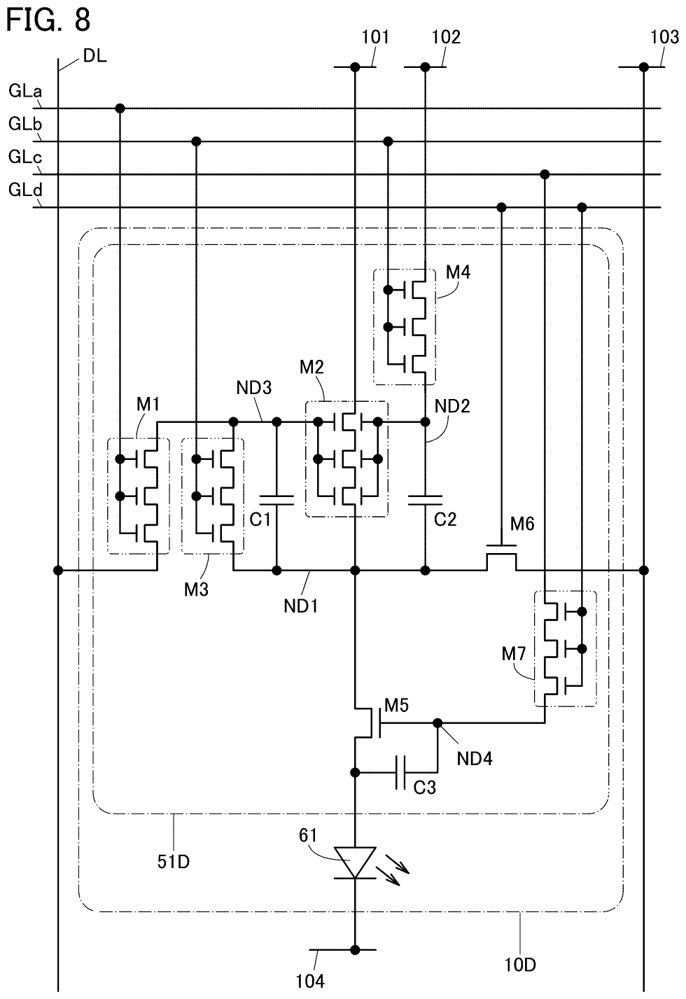

FIG. 8 illustrates an example of a circuit configuration of a semiconductor device 10D, which is a modification example of the semiconductor device 10B. The semiconductor device 10D includes a pixel circuit 51D and the light-emitting element 61. The semiconductor device 10D has the same circuit configuration as the semiconductor device 10B except that a multi-gate transistor with a series number of 3 is used as each of the transistors M2, M3, M4, and M7 in addition to the transistor M1.

The use of a multi-gate transistor as the transistor M2 serving as a driving transistor can improve the saturation characteristics of the transistor M2. Also in the semiconductor device 10D, the transistor M1 is the most likely to be affected by a negative bias, and the transistors M3, M4, and M7 are the second most likely to be affected by a negative bias. When a multi-gate transistor is used as each of the transistors M3, M4, and M7 in addition to the transistor M1, the semiconductor device 10D can have higher reliability than the semiconductor device 10B.

As described above, the transistors M3, M4, and M7 are less likely to be affected by a negative bias than the transistor M1. Thus, a multi-gate transistor used as each of the transistors M3, M4, and M7 can have a smaller series number than a multi-gate transistor used as the transistor M1. The transistors M5 and M6 are unlikely to be affected by a negative bias. Thus, a single-gate transistor can be used as each of the transistors M5 and M6.

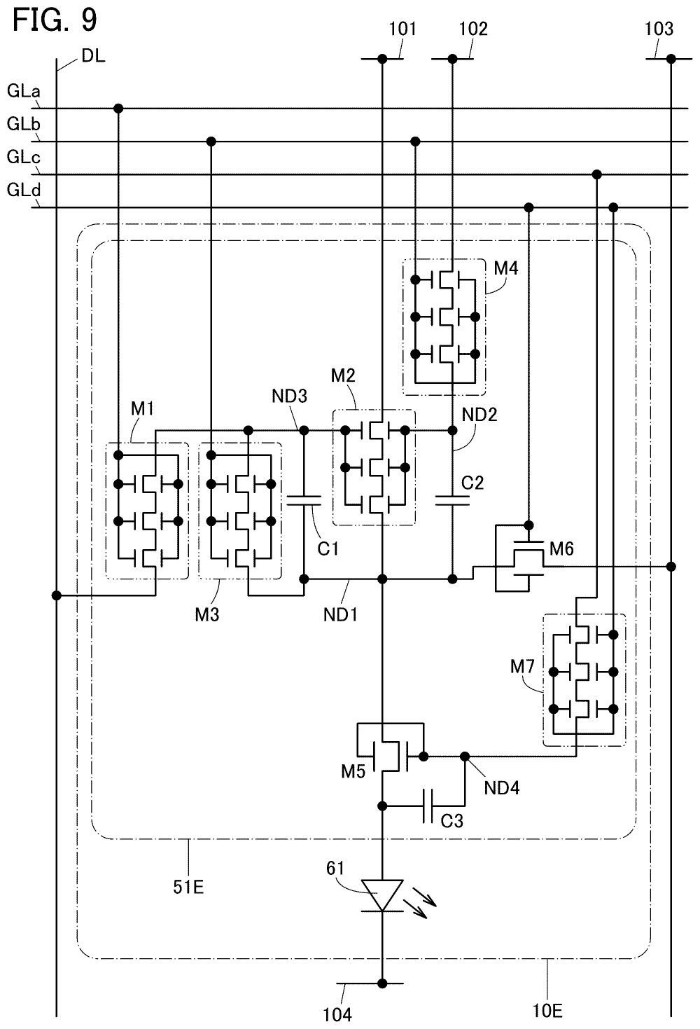

A transistor having a back gate can be used as any of the transistors included in the semiconductor device 10D. FIG. 9 illustrates an example of a circuit configuration of a semiconductor device 10E, which is a modification example of the semiconductor device 10D. The semiconductor device 10E includes a pixel circuit 51E and the light-emitting element 61. The semiconductor device 10E is different from the semiconductor device 10D in that a transistor having a back gate is used as each of the transistors M1, M3, M4, M5, M6, and M7 included in the semiconductor device 10E.

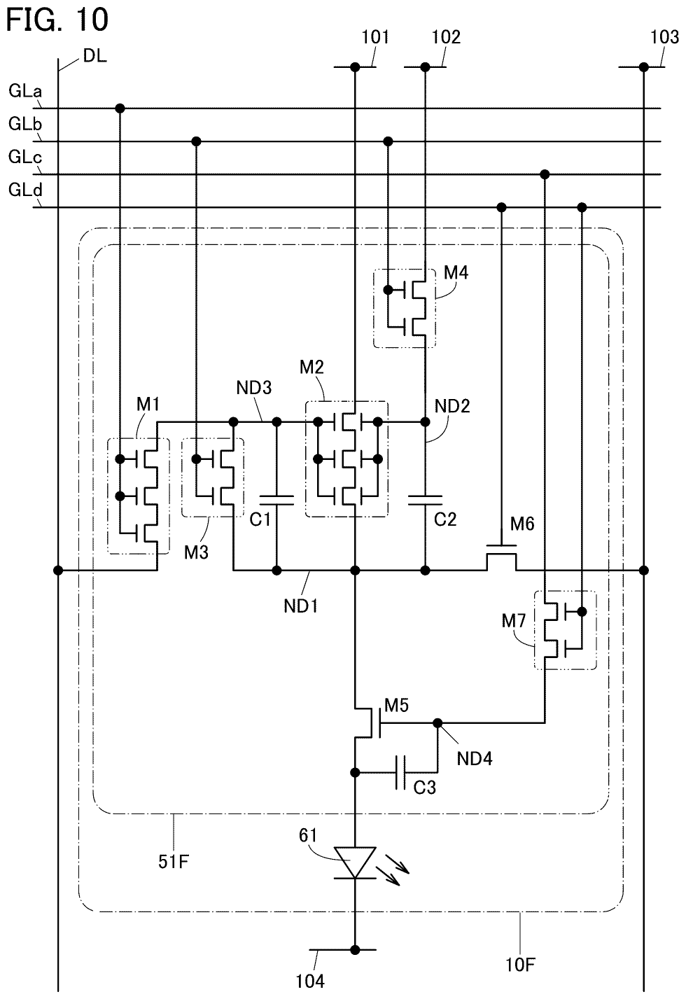

FIG. 10 illustrates an example of a circuit configuration of a semiconductor device 10F, which is a modification example of the semiconductor device 10D. The semiconductor device 10F includes a pixel circuit 51F and the light-emitting element 61. The semiconductor device 10F is different from the semiconductor device 10D in that a multi-gate transistor with a series number of 3 is used as each of the transistors M1 and M2 and a multi-gate transistor with a series number of 2 is used as each of the transistors M3, M4, and M7. When the series number of the multi-gate transistor used as each of the transistors M3, M4, and M7 is reduced, the area occupied by the semiconductor device 10F can be reduced. This can increase one or both of the definition and the resolution of a display device including the semiconductor device 10F as a pixel.

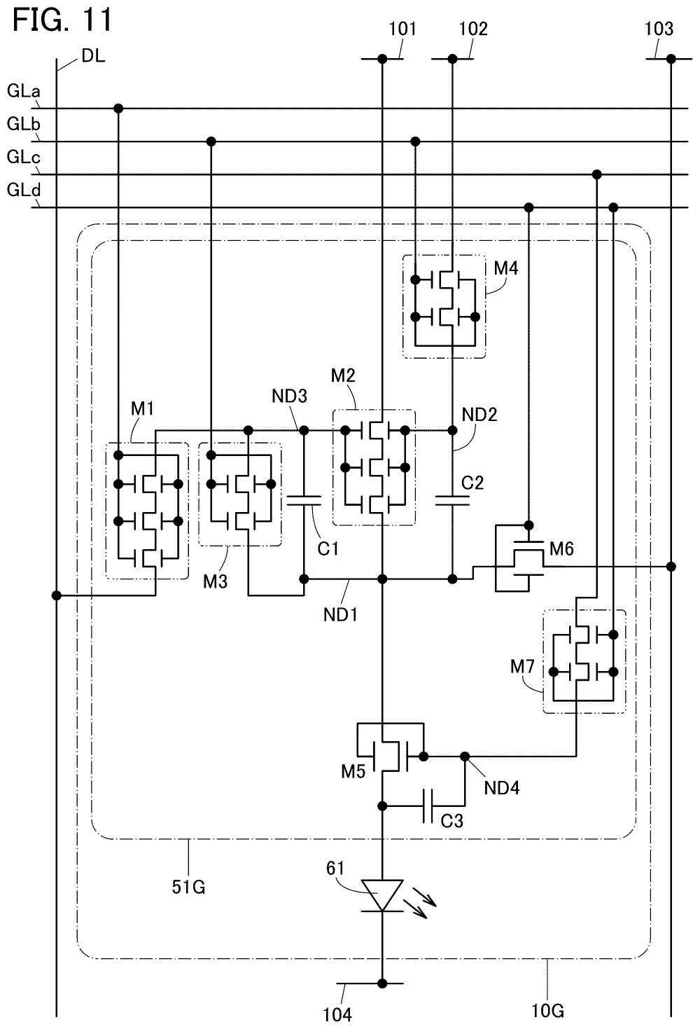

A transistor having a back gate can be used as any of the transistors included in the semiconductor device 10F. FIG. 11 illustrates an example of a circuit configuration of a semiconductor device 10G, which is a modification example of the semiconductor device 10F. The semiconductor device 10G includes a pixel circuit 51G and the light-emitting element 61. The semiconductor device 10G is different from the semiconductor device 10F in that a transistor having a back gate is used as each of the transistors M1, M3, M4, M5, M6, and M7 included in the semiconductor device 10G.

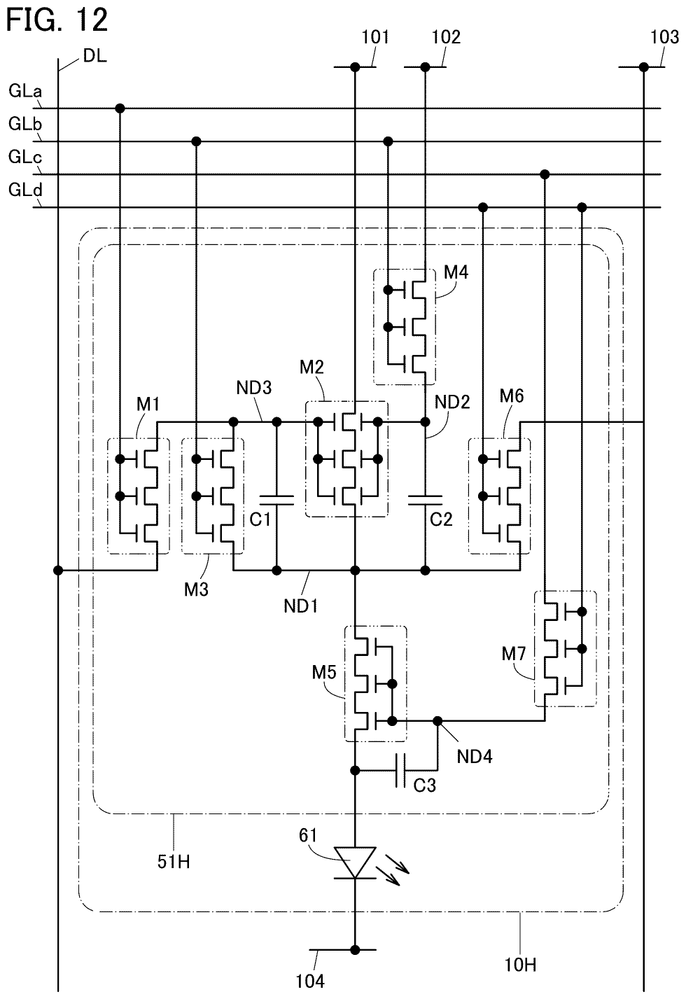

As illustrated in FIG. 12, a multi-gate transistor can be used as each of the transistors M1 to M7. FIG. 12 illustrates an example of a circuit configuration of a semiconductor device 10H, which is a modification example of the semiconductor device 10B. Note that the semiconductor device 10H is also a modification example of the semiconductor device 10D. The semiconductor device 10H includes a pixel circuit 51H and the light-emitting element 61. The semiconductor device 10H has the same circuit configuration as the semiconductor device 10B except that a multi-gate transistor with a series number of 3 is used as each of the transistors M1 to M7.

When a multi-gate transistor is used as each of the transistors included in the pixel circuit 51H, the semiconductor device 10H can have higher reliability than the semiconductor device 10B. In addition, the semiconductor device 10H can have higher reliability than the semiconductor device 10D.

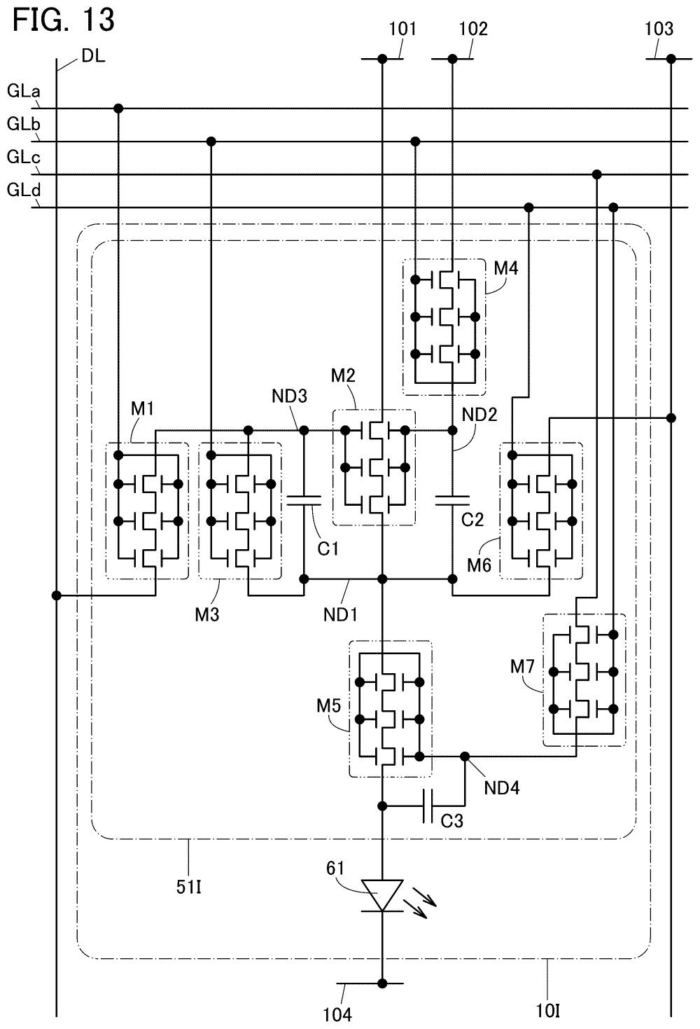

Alternatively, a multi-gate transistor having back gates can be used as each of the transistors M1 to M7. FIG. 13 illustrates an example of a circuit configuration of a semiconductor device 10I, which is a modification example of the semiconductor device 10H. The semiconductor device 10I includes a pixel circuit 51I and the light-emitting element 61. The semiconductor device 10I is different from the semiconductor device 10H in that a multi-gate transistor having back gates is used as each of the transistors M1 to M7.

This embodiment describes the example in which the semiconductor device 10 (the semiconductor devices 10A to 10I) is formed using n-channel transistors; however, one embodiment of the present invention is not limited thereto. As some or all of the transistors included in the semiconductor device 10, p-channel transistors can be used.

Any of transistors having a variety of structures can be used in the pixel circuit 51 (the pixel circuits 51A to 51I) of one embodiment of the present invention. For example, any of transistors having a variety of structures such as a planar type, a FIN-type, a tri-gate type, a top-gate type, a bottom-gate type, and a tandem type (with gates over and under a channel) can be used. In addition, a MOS transistor, a junction transistor, a bipolar transistor, or the like can be used as the transistor of one embodiment of the present invention.

As each of the transistors included in the pixel circuit 51, an OS transistor (a transistor including an oxide semiconductor in a semiconductor layer where a channel is formed) can be used, for example. An oxide semiconductor has a band gap of 2 eV or more, achieving an extremely low off-state current.

The off-state current per micrometer of channel width of an OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current per micrometer of channel width of a Si transistor (a transistor containing silicon in a semiconductor layer where a channel is formed) at room temperature is higher than or equal to 1 fA (1×10⁻¹⁵ A) and lower than or equal to 1 pA (1×10⁻¹² A). In other words, the off-state current of an OS transistor is lower than that of a Si transistor by approximately ten orders of magnitude.

When the OS transistor is used as each of the transistors included in the pixel circuit 51, charge written to the nodes can be retained for a long period. For example, in the case of displaying a still image for which rewriting every frame is not required, displaying an image can be kept even when the operation of a peripheral driver circuit is stopped. Such a driving method in which the operation of a peripheral driver circuit is stopped during displaying a still image is also referred to as “idling stop driving”. The power consumption of a display device can be reduced by performing idling stop driving.

When the OS transistor is used as the transistor M1, charge written to the node ND3 can be retained for a long period. When the OS transistor is used as each of the transistors M1 and M3, charge written to the node ND3 can be retained for a longer period. When the OS transistor is used as the transistor M4, charge written to the node ND2 can be retained for a long period.

When the OS transistor is used as the transistor M7, charge written to the node ND4 can be retained for a long period.

The off-state current of the OS transistor hardly increases even in a high-temperature environment, specifically, at temperatures higher than or equal to room temperature and lower than or equal to 200° C. In addition, the on-state current of the OS transistor is unlikely to decrease even in a high-temperature environment. A semiconductor device including the OS transistor can operate stably and have high reliability even in a high-temperature environment.

The OS transistor has a high withstand voltage between its source and drain. When the OS transistor is used as each of the transistors included in the pixel circuit 51, the semiconductor device can operate stably and have high reliability even in the case where a potential difference between the wiring 101 and the wiring 104 is large. In particular, the OS transistor is preferably used as one or both of the transistors M2 and M5.

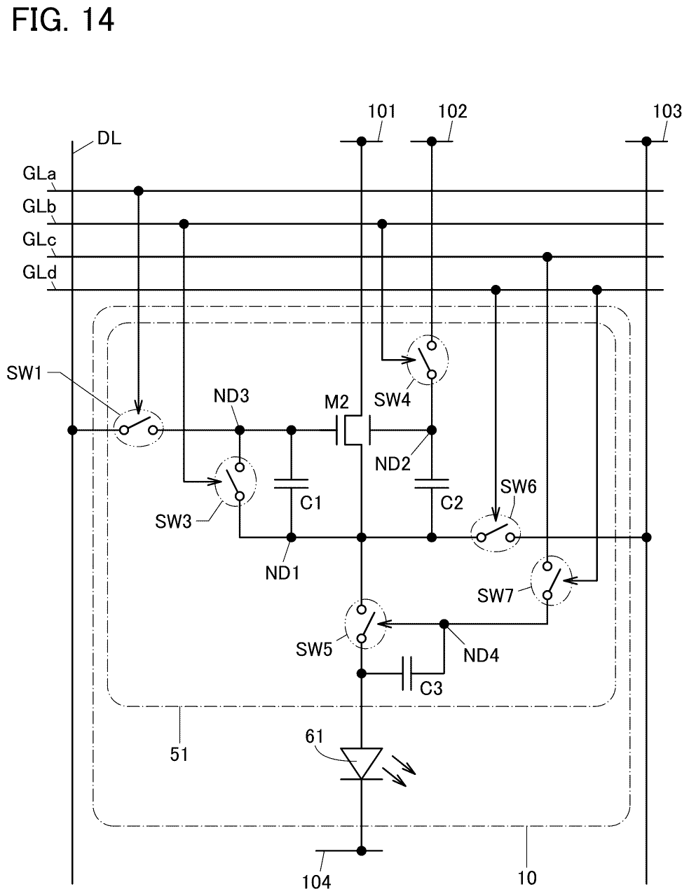

Among the transistors included in the pixel circuit 51, the transistors M1, M3, M4, M5, M6, and M7 function as switches as described above. Thus, the semiconductor device 10 can be illustrated as in FIG. 14.

In FIG. 14, a switch SW1 corresponds to the transistor M1, a switch SW3 corresponds to the transistor M3, a switch SW4 corresponds to the transistor M4, a switch SW5 corresponds to the transistor M5, a switch SW6 corresponds to the transistor M6, and a switch SW7 corresponds to the transistor M7.

Thus, a first terminal of the switch SW1 corresponds to one of the source and the drain of the transistor M1, and a second terminal of the switch SW1 corresponds to the other of the source and the drain of the transistor M1. The same applies to the switches SW3 to SW7.

As the light-emitting element 61, it is possible to use any of a variety of display elements such as an EL element (e.g., an EL element containing an organic material and an inorganic material, an organic EL element, and an inorganic EL element), an LED (e.g., a white LED, a red LED, a green LED, and a blue LED), a micro LED, a quantum-dot light-emitting diode (QLED), and an electron emitter device.

### Operation Example

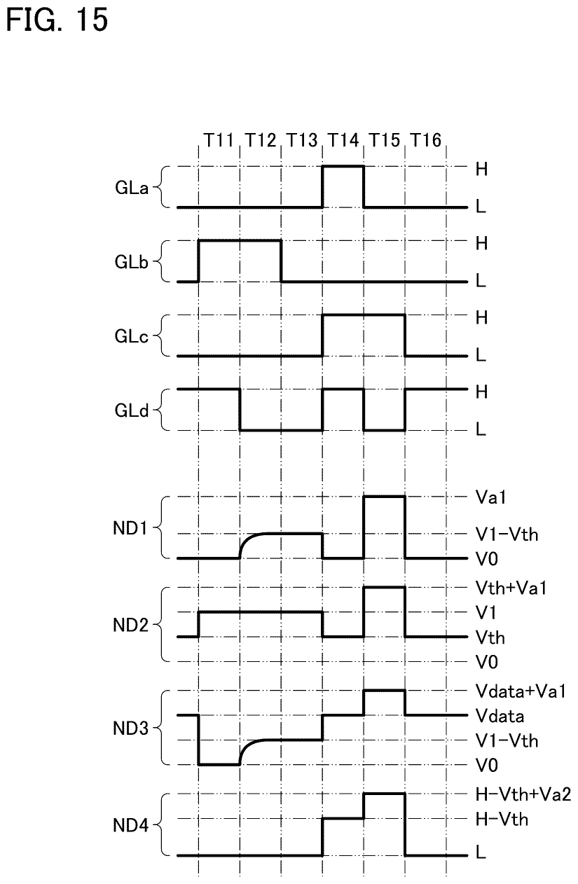

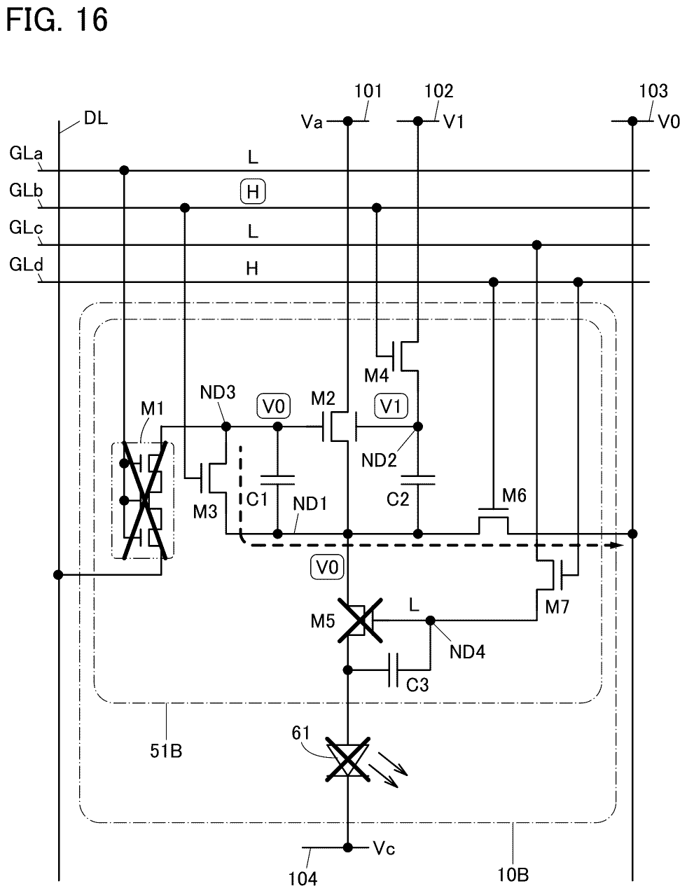

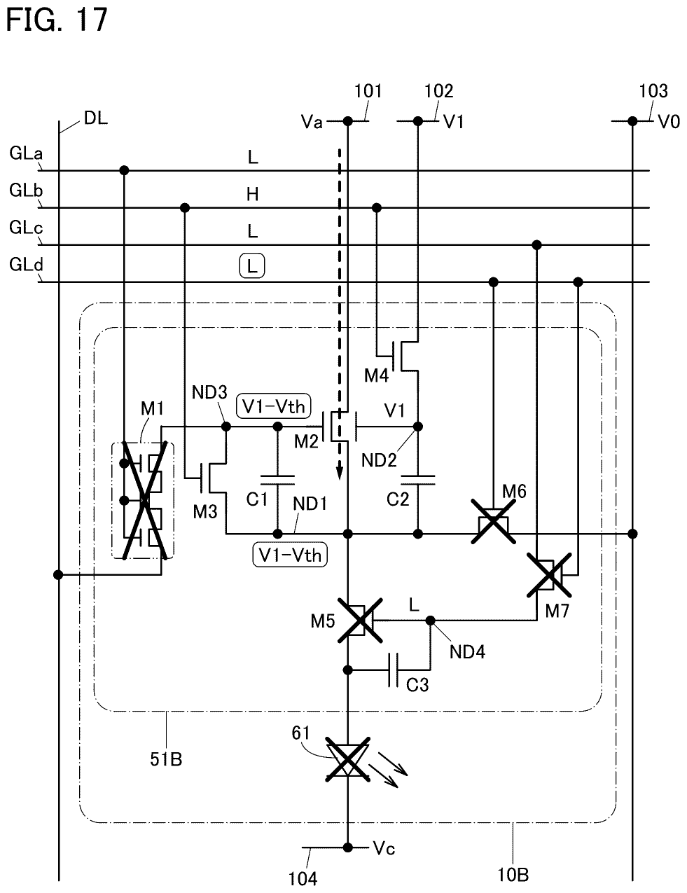

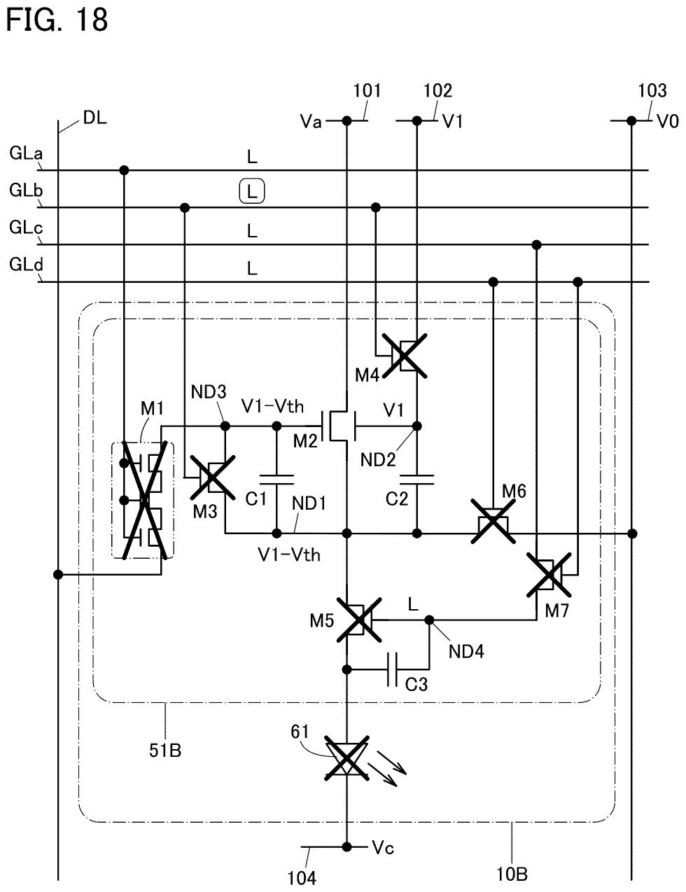

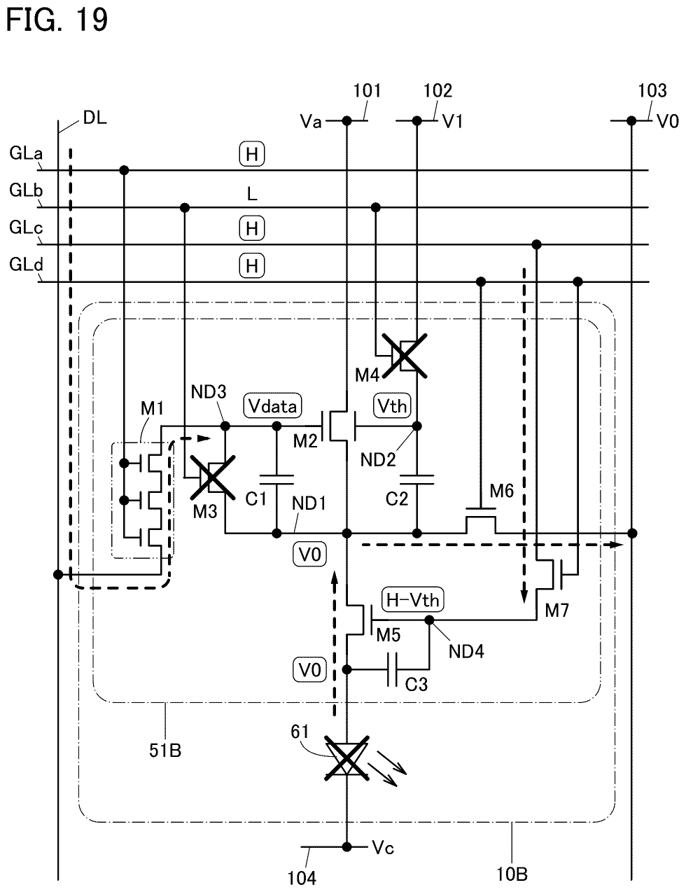

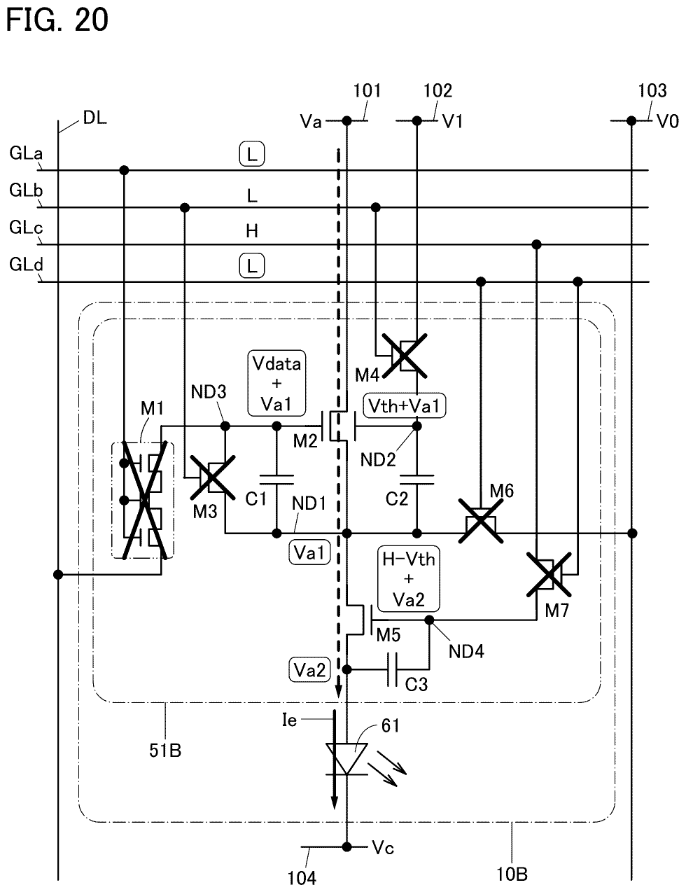

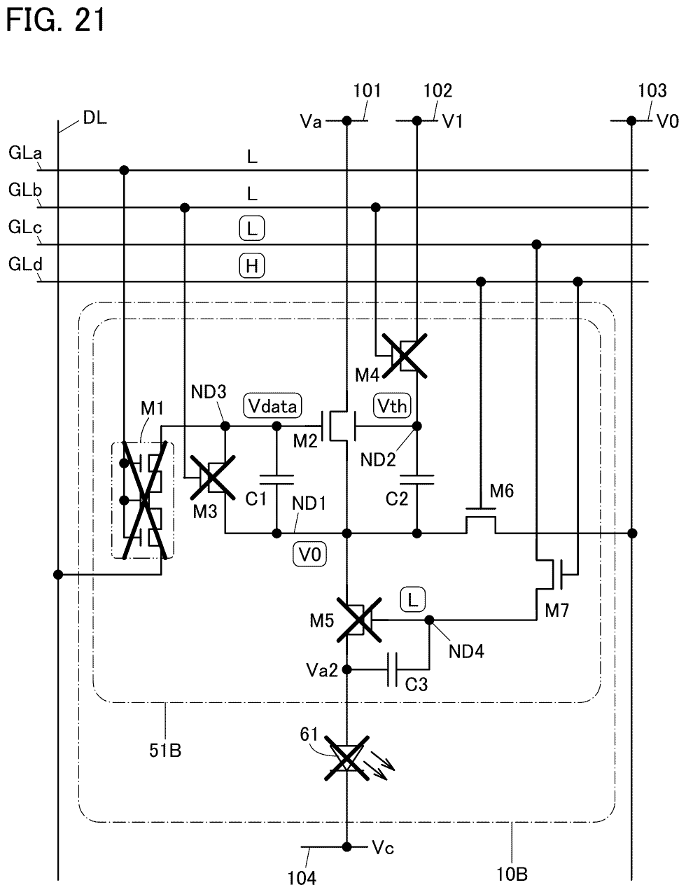

Next, an operation example of the semiconductor device 10B is described with reference to drawings. FIG. 15 is a timing chart showing the operation example of the semiconductor device 10B. FIG. 16, FIG. 17, FIG. 18, FIG. 19, FIG. 20, and FIG. 21 are circuit diagrams illustrating the operation example of the semiconductor device 10B. Note that one embodiment of the present invention is some or all of the circuit configurations described in this specification and the like. Thus, one embodiment of the present invention meets the support requirements and the clarity requirements even when not including some or all of the operations described in this specification and the like.

A video signal Vdata is supplied to the wiring DL. A potential Va is supplied to the wiring 101, a potential V1 is supplied to the wiring 102, a potential V0 is supplied to the wiring 103, and a potential Vc is supplied to the wiring 104. A potential H or a potential L is supplied to each of the wirings GLa, GLb, GLc, and GLd.

The potential Va is an anode potential and the potential Vc is a cathode potential. The potential V1 is higher than the potential V0, and is a potential with which a transistor can be turned on when being supplied to a gate of the transistor. The potential V0 is a potential with which a transistor can be turned off when being supplied to a gate of the transistor. The potential V0 is, for example, 0 V or a potential L. In this embodiment and the like, the potential V0 is 0 V and the potential V1 is 3 V. The potential Va is 15 V and the potential Vc is 0 V. The gate capacitance and the back gate capacitance of the transistor M2 are equal to each other.

The semiconductor device 10B has a function of controlling the amount of current Ie (see FIG. 20) flowing through the light-emitting element 61 on the basis of the video signal Vdata supplied from the wiring DL. The emission luminance of the light-emitting element 61 is controlled by the amount of current Ie.

The current Ie flowing through the light-emitting element 61 is determined mainly by the video signal Vdata and Vth of the transistor M2. Thus, even when the same video signal Vdata is supplied to a plurality of pixel circuits, a Vth variation between the transistors M2 included in the pixel circuits makes the current Ie different between the pixels. Accordingly, the Vth variation between the transistors M2 is a factor in reducing display quality.

In view of this, Vth of the transistor M2 in each pixel is obtained and a variation in the current Ie is reduced. Note that an operation of obtaining Vth of the transistor M2 is sometimes referred to as a “threshold correction operation”.

It is assumed that, in the initial state, the potential L is supplied to the wirings GLa, GLb, and GLc, and the potential H is supplied to the wiring GLd.

### [Vth Correction Operation]

First, in Period T11, a reset operation is performed. Specifically, the potential H is supplied to the wiring GLb, the wirings GLa and GLc are kept at the potential L, and the wiring GLd is kept at the potential H (see FIG. 15 and FIG. 16). In Period T11, the transistors M1 and M5 are in the off state, the transistors M3 and M4 are turned on, and the transistors M6 and M7 are in the on state.

The potential V0 is supplied to the node ND1 through the transistor M6. Furthermore, the potential V0 is supplied to the node ND3 through the transistors M6 and M3. The potential V1 is supplied to the node ND2 through the transistor M4.

Next, in Period T12, the potential L is supplied to the wiring GLd (see FIG. 15 and FIG. 17). Thus, the transistors M6 and M7 are turned off.

Since the potential V1 is supplied to the node ND2 through the transistor M4, the transistor M2 is in the on state. Thus, the potential of the node ND1 increases through the wiring 101 and the transistor M2. Since the transistor M3 is also in the on state, the potential of the node ND3 also increases. Specifically, the potentials of the nodes ND1 and ND3 each increase to a value obtained by subtracting Vth of the transistor M2 from the potential V1.

Next, in Period T13, the potential L is supplied to the wiring GLb (see FIG. 15 and FIG. 18). Thus, the transistors M3 and M4 are turned off. Consequently, the nodes ND1, ND2, and ND3 are brought into a floating state, and charge supplied to the nodes is retained.

### [Video Signal Writing Operation]

In Period T14, the potential H is supplied to the wirings GLa, GLc, and GLd (see FIG. and FIG. 19). When the potential H is supplied to the wiring GLa, the transistor M1 is turned on and the video signal Vdata is supplied to the node ND3. When the potential H is supplied to the wiring GLd, the transistors M6 and M7 are turned on.

When the transistor M6 is in the on state, the potential V0 is supplied to the node ND1. The node ND2 is in a floating state and the nodes ND1 and ND2 are capacitively coupled through the capacitor C2; thus, when the potential of the node ND1 changes from V1−Vth to V0, the potential of the node ND2 similarly changes. Since the potential V0 is 0 V in this embodiment, the potential of the node ND2 becomes the potential V1−(the potential V1−Vth). That is, the potential of the node ND2 becomes Vth.

In addition, when the transistor M7 is in the on state, charge is supplied from the wiring GLc to the node ND4. The potential of the node ND4 increases to a value obtained by subtracting Vth of the transistor M7 from the potential H. Assuming that the potential H is 6 V and Vth of each of the transistors M5 and M7 is 1 V in this embodiment and the like, the potential of the node ND4, (the potential H-Vth), becomes 5 V. Accordingly, the transistor M5 is turned on.

### [Light-Emitting Operation]

In Period T15, the potential L is supplied to the wirings GLa and GLd (see FIG. 15 and FIG. 20). Thus, the transistors M1 and M6 are turned off and current flows from the wiring 101 to the wiring 104. That is, the current Ie flows through the light-emitting element 61, and the light-emitting element 61 emits light at luminance corresponding to the current Ie. When current flows from the wiring 101 to the wiring 104, the potentials of the node ND1 and the anode terminal of the light-emitting element 61 increase.

The node ND3 is in a floating state, and the nodes ND1 and ND3 are capacitively coupled through the capacitor C1. As described above, the node ND2 is in a floating state, and the nodes ND1 and ND2 are capacitively coupled through the capacitor C2. When the potential of the node ND1 changes from the potential V0 to a potential Va1, the potentials of the nodes ND2 and ND3 similarly change. Here, the potential of the node ND3 becomes the video signal Vdata+the potential Va1. In addition, the potential of the node ND2 becomes Vth+the potential Va1.

That is, even when the source potential of the transistor M2 changes, the potential difference between the gate and the source of the transistor M2 is kept at the video signal Vdata. Similarly, the potential difference between the back gate and the source of the transistor M2 is kept at Vth. The capacitor C1 has a function of keeping a potential difference between the nodes ND1 and ND3. The capacitor C2 has a function of keeping a potential difference between the nodes ND1 and ND2.

The anode terminal of the light-emitting element 61 and the node ND4 are capacitively coupled through the capacitor C3. Thus, when the potential of the anode terminal of the light-emitting element 61 changes from the potential V0 to a potential Va2, the potential of the node ND4 similarly changes. Here, the potential of the node ND4 becomes the potential H-Vth+the potential Va2. That is, even when the potential of the anode terminal of the light-emitting element 61 changes, the potential difference between the gate and the source of the transistor M5 is kept at the potential H-Vth.

In the case where the gate of the transistor M5 has a fixed potential, for example, an increase in the source potential of the transistor M5 reduces the potential difference between its gate and source. When the potential difference between the gate and the source falls below the threshold voltage of the transistor M5, the transistor M5 is turned off. Thus, increasing the anode potential of the light-emitting element 61 requires supply of a high potential also to the gate of the transistor M5, which creates the need for adding a power source or a power supply circuit for supplying the high potential.

In the semiconductor device 10B of one embodiment of the present invention, the capacitor C3 is provided between the gate and the source of the transistor M5 so that a bootstrap circuit can be formed; thus, even when the anode potential is increased, the transistor M5 can be kept in the on state without addition of a power supply circuit. Accordingly, the current Ie can be stably supplied to the light-emitting element 61. Note that the capacitor C3 is sometimes referred to as a “bootstrap capacitor”. The capacitors C1 and C2 each also function as a bootstrap capacitor.

The semiconductor device 10B of one embodiment of the present invention is suitably used not only in a light-emitting element having a single structure but also in a light-emitting element having a tandem structure that requires a higher driving voltage than the light-emitting element having a single structure.

As described above, the amount of current Ie flowing through the light-emitting element 61 is determined by the video signal Vdata and Vth of the transistor M2. Since the influence of a Vth variation in the transistor M2 is reduced in the semiconductor device 10B of one embodiment of the present invention, the current Ie corresponding to the video signal Vdata can be supplied to the light-emitting element 61 more accurately. In addition, the current Ie can be controlled accurately so that the color reproducibility of halftones can be increased. Consequently, the display quality of a display device can be increased.

### [Light-Stopping Operation]

In Period T16, the potential L is supplied to the wiring GLc, and the potential H is supplied to the wiring GLd (see FIG. 15 and FIG. 21). Thus, the transistors M6 and M7 are turned on. When the transistor M6 is in the on state, the potential V0 is supplied to the node ND1 from the wiring 103. When the transistor M7 is in the on state, the potential L is supplied to the node ND4 from the wiring GLc so that the transistor M5 is turned off. Current does not flow through the light-emitting element 61 when the transistor M5 is in the off state; thus, light emission from the light-emitting element 61 is stopped.

Note that when the potential of the node ND1 changes from the potential Va1 to the potential V0, the potential of the node ND2 becomes Vth and the potential of the node ND3 becomes Vdata.

In a display device including a light-emitting element such as an EL element as a display element, the light-emitting element can continuously emit light during one frame period. Such a driving method is also referred to as a “hold type” or “hold-type driving”. When the hold-type driving is used as a driving method of a display device, a flicker phenomenon or the like on a display screen can be reduced. However, the hold-type driving is likely to cause an afterimage, an image blur, and the like in moving image display. The definition that is perceived by a person in displaying moving images is also referred to as “moving image definition”. That is, the hold-type driving is likely to decrease the moving image definition.

Furthermore, “black insertion driving,” which solves an afterimage, an image blur, and the like in moving image display, is known. The “black insertion driving” is also referred to as a “pseudo impulsive type” or “pseudo impulsive driving”. The black insertion driving refers to a driving method in which black display is performed in every other frame or black display is performed for a certain period in one frame.

The semiconductor device 10B of one embodiment of the present invention easily achieves the black insertion driving by the light-stopping operation. A display device including the semiconductor device 10B of one embodiment of the present invention can achieve high-quality moving image display whose moving image definition is unlikely to decrease.

The structure described in this embodiment can be used in appropriate combination with any of the structures described in the other embodiments and example.

### Embodiment 2

In this embodiment, a transistor that can be used for a semiconductor device of one embodiment of the present invention will be described.

### <Structure Example 1 of Transistor>

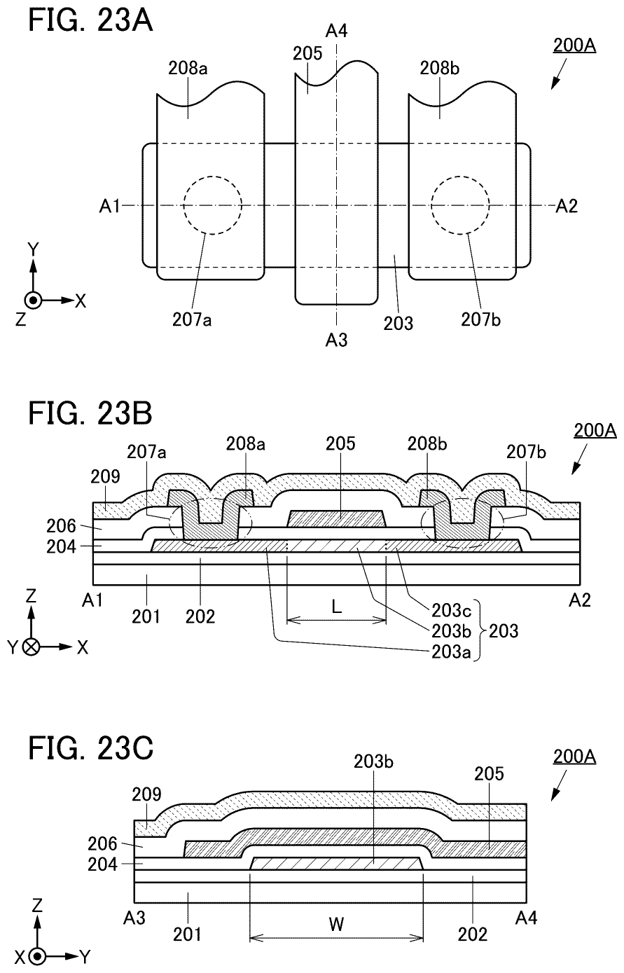

FIG. 23A is a plan view of a transistor 200A that can be used for the semiconductor device of one embodiment of the present invention. The transistor 200A is an example of a planar transistor. In this specification, a planar transistor has a structure in which a source electrode and a drain electrode are positioned at the same or substantially the same height and current flowing through a semiconductor contains components in the lateral direction.

FIG. 23B is a cross-sectional view taken along the dashed-dotted line A1-A2 in FIG. 23A. FIG. 23C is a cross-sectional view taken along the dashed-dotted line A3-A4 in FIG. 23A. Note that for simplification, some components are not illustrated in the plan view of FIG. 23A. Some components may be omitted also in other plan views.

The transistor 200A includes an insulating layer 202 over a substrate 201 and a semiconductor layer 203 over the insulating layer 202. An insulating layer 204 is provided over the insulating layer 202 and the semiconductor layer 203. A conductive layer 205 is provided over the insulating layer 204. The semiconductor layer 203 includes a region overlapping with the conductive layer 205 with the insulating layer 204 therebetween.

The semiconductor layer 203 includes a region 203a, a channel formation region 203b, and a region 203c. The region 203a functions as one of a source region and a drain region. The region 203c functions as the other of the source region and the drain region. The region of the semiconductor layer 203 that overlaps with the conductive layer 205 functions as the channel formation region 203b. Thus, the conductive layer 205 functions as a gate electrode of the transistor 200A. The insulating layer 204 functions as a gate insulating layer of the transistor 200A.

The length of the channel formation region 203b in the X direction corresponds to the channel length L of the transistor 200A (see FIG. 23B). The length of the channel formation region 203b in the Y direction corresponds to the channel width W of the transistor 200A (see FIG. 23C).

Furthermore, an insulating layer 206 is provided over the insulating layer 204 and the conductive layer 205. The insulating layer 204 and the insulating layer 206 are provided with an opening 207a in a region overlapping with the region 203a of the semiconductor layer 203. The insulating layer 204 and the insulating layer 206 are provided with an opening 207b in a region overlapping with the region 203c of the semiconductor layer 203.

A conductive layer 208a is provided to overlap with the insulating layer 206 and the opening 207a, and a conductive layer 208b is provided to overlap with the insulating layer 206 and the opening 207b. The conductive layer 208a is connected to the region 203a of the semiconductor layer 203 at the bottom portion of the opening 207a. The conductive layer 208b is connected to the region 203c of the semiconductor layer 203 at the bottom portion of the opening 207b. Thus, the conductive layer 208a functions as one of a source electrode and a drain electrode of the transistor 200A, and the conductive layer 208b functions as the other of the source electrode and the drain electrode of the transistor 200A.

An insulating layer 209 is provided over the insulating layer 206 and the conductive layer 208 (the conductive layers 208a and 208b).

### <Structure Example 2 of Transistor>

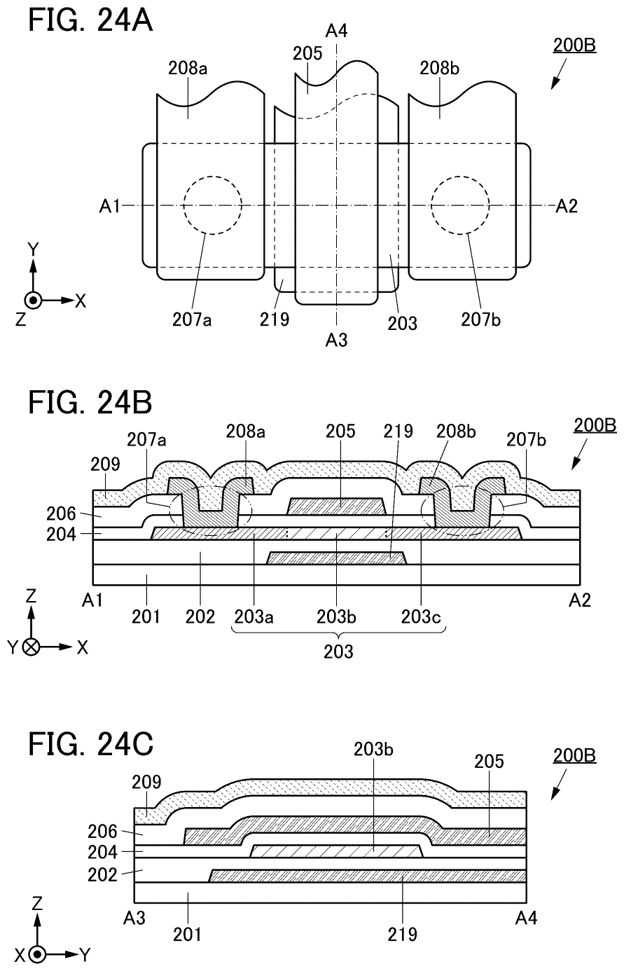

FIG. 24A is a plan view of a transistor 200B that can be used for the semiconductor device of one embodiment of the present invention. The transistor 200B is a modification example of the transistor 200A. Differences of the transistor 200B from the transistor 200A are mainly described to reduce repeated description.

FIG. 24B is a cross-sectional view taken along the dashed-dotted line A1-A2 in FIG. 24A. FIG. 24C is a cross-sectional view taken along the dashed-dotted line A3-A4 in FIG. 24A.

The transistor 200B is different from the transistor 200A in that a conductive layer 219 is provided between the substrate 201 and the insulating layer 202. The conductive layer 219 functions as a back gate electrode of the transistor 200B. Thus, the conductive layer 219 includes a region overlapping with the channel formation region 203b in a plan view. The conductive layer 219 preferably includes a region extending beyond an end portion of the channel formation region 203b in a plan view. Surrounding the channel formation region 203b by the conductive layers 205 and 219 can enhance the electric field blocking effect described in the above embodiment.

### <Structure Example 3 of Transistor>

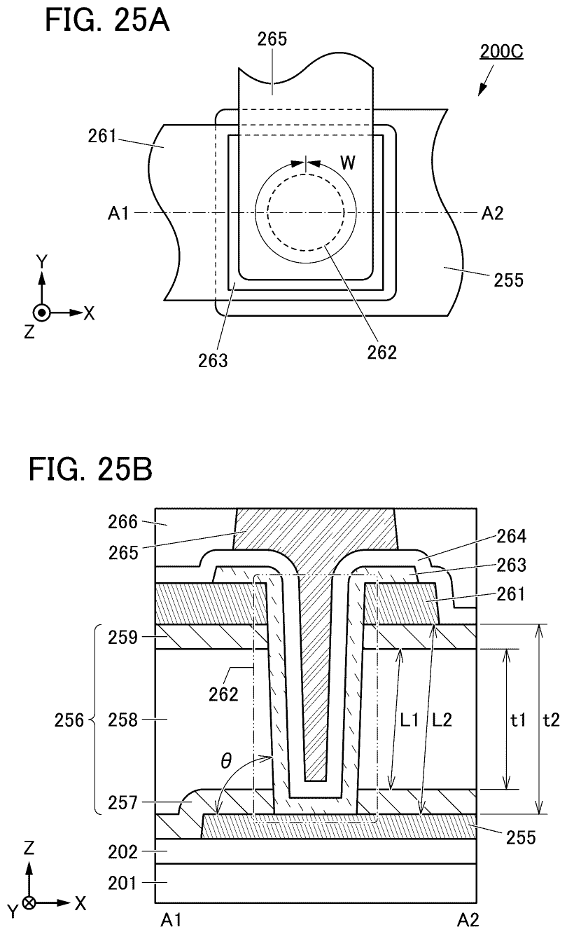

FIG. 25A is a plan view of a transistor 200C that can be used for the semiconductor device of one embodiment of the present invention. FIG. 25B is a cross-sectional view taken along the dashed-dotted line A1-A2 in FIG. 25A.

The transistor 200C includes the insulating layer 202 over the substrate 201 and a conductive layer 255 over the insulating layer 202. An insulating layer 257 is provided over the conductive layer 255, an insulating layer 258 is provided over the insulating layer 257, and an insulating layer 259 is provided over the insulating layer 258. In this specification, the insulating layers 257, 258, and 259 are sometimes collectively referred to as an insulating layer 256 or a spacer layer. A conductive layer 261 is provided over the insulating layer 259.

The conductive layer 261 and the insulating layers 259, 258, and 257 are penetrated by an opening 262 in a region overlapping with part of the conductive layer 255. A semiconductor layer 263 is provided to cover the inner wall of the opening 262.

The semiconductor layer 263 includes a region overlapping with the bottom portion of the opening 262 and a region overlapping with the side surface of the opening 262. That is, the semiconductor layer 263 includes a region in contact with the insulating layer 256 in the opening 262. In addition, the semiconductor layer 263 includes a region in contact with the conductive layer 255 and a region in contact with the conductive layer 261 in the opening 262.

An insulating layer 264 is provided over the insulating layer 259, the conductive layer 261, and the semiconductor layer 263. A conductive layer 265 is provided over the insulating layer 264. The conductive layer 265 includes a region overlapping with the semiconductor layer 263. The conductive layer 265 includes a region overlapping with the semiconductor layer 263 with the insulating layer 264 therebetween.

The insulating layer 264 and the conductive layer 265 each include a region overlapping with the opening 262. The insulating layer 264 and the conductive layer 265 each include a region overlapping with the inner side of the opening 262. In the opening 262, the semiconductor layer 263 includes a region overlapping with the conductive layer 265 with the insulating layer 264 therebetween and a region overlapping with the side surface of the opening 262 (the side surface of the insulating layer 256).

An insulating layer 266 is provided over the insulating layer 264. Note that the top surface of the insulating layer 266 is preferably flat. Alternatively, it is preferable that the level (the position in the Z direction) of the top surface of the insulating layer 266 be the same or substantially the same as that of the top surface of the conductive layer 265. For example, the flatness of the top surface of the insulating layer 266 can be improved by chemical mechanical polishing (CMP) treatment or the like. In addition, CMP treatment enables the top surfaces of the insulating layer 266 and the conductive layer 265 to be level or substantially level with each other. CMP treatment can reduce unevenness of a sample surface, so that coverage with an insulating layer and a conductive layer to be formed later can be increased.

In the case where the semiconductor layer 263 is formed using an oxide semiconductor, the conductive layers 255 and 261, each of which is in contact with the semiconductor layer 263, is preferably formed using a conductive material that makes the oxide semiconductor have n-type conductivity. For example, a conductive material containing nitrogen may be used. For example, a conductive material containing nitrogen and titanium or tantalum may be used. Another conductive material can be provided to overlap with the conductive material containing nitrogen.

When an oxide semiconductor is used for the semiconductor layer 263, a material in which hydrogen is reduced and oxygen is contained is preferably used for the insulating layer 258. For example, a material containing silicon and oxygen may be used. Specifically, silicon oxide, silicon oxynitride, or the like may be used. Hydrogen is an impurity element in an oxide semiconductor; thus, the semiconductor layer 263 that is an oxide semiconductor is less likely to have n-type conductivity when in contact with the insulating layer 258 in which the amount of hydrogen is reduced. Furthermore, when the semiconductor layer 263 that is an oxide semiconductor and the insulating layer 258 containing oxygen are in contact with each other, oxygen vacancies in the semiconductor layer 263 are reduced, enabling the transistor to have stable characteristics and improved reliability.

When an oxide semiconductor is used for the semiconductor layer 263, the insulating layer 258 preferably contains excess oxygen. In this specification, excess oxygen refers to oxygen that is released by heating. A material that releases oxygen by heating is a material in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in thermal desorption spectroscopy (TDS) analysis. Note that the temperature of the film surface in the TDS analysis is preferably in the range of 100° C. to 700° C. or 100° C. to 400° C.

In the case where a material containing excess oxygen is used for the insulating layer 258, a material through which oxygen is less likely to pass is preferably used for the insulating layers 257 and 259. Examples of the material through which oxygen is less likely to pass include a nitride of silicon and an oxide containing aluminum and/or hafnium. With the use of the material through which oxygen is less likely to pass for the insulating layers 257 and 259, excess oxygen contained in the insulating layer 258 is less likely to be released to a lower layer or an upper layer. Thus, sufficient oxygen can be supplied to the oxide semiconductor. For example, an insulating layer containing silicon and oxygen (the insulating layer 258) is preferably provided between two insulating layers containing silicon and nitrogen (the insulating layers 257 and 259). For the insulating layer containing silicon and nitrogen, silicon nitride, silicon nitride oxide, or the like can be used. For the insulating layer containing silicon and oxygen, silicon oxide, silicon oxynitride, or the like can be used.

When an oxide semiconductor is used for the semiconductor layer 263, the use of a material containing hydrogen for the insulating layers 257 and 259 allows hydrogen to be supplied to a region of the semiconductor layer 263 that is in contact with the insulating layer 257 and a region of the semiconductor layer 263 that is in contact with the insulating layer 259, so that the regions of the semiconductor layer 263 have n-type conductivity. Thus, the region of the semiconductor layer 263 that is in contact with the conductive layer 261 and the region of the semiconductor layer 263 that is in contact with the insulating layer 259 function as one of a source region and a drain region. The region of the semiconductor layer 263 that is in contact with the conductive layer 255 and the region of the semiconductor layer 263 that is in contact with the insulating layer 257 function as the other of the source region and the drain region.

The conductive layer 261 functions as one of a source electrode and a drain electrode of the transistor 200C. The conductive layer 255 functions as the other of the source electrode and the drain electrode of the transistor 200C. The source electrode and the drain electrode are provided in the Z direction in the transistor 200C. That is, a source and a drain of the transistor 200C are provided at different levels. In other words, the source and the drain of the transistor 200C are provided in different positions in the Z direction. Such a transistor is also referred to as a “vertical-channel transistor”, a “vertical transistor”, or a “vertical field-effect transistor (VFET)”.

In the transistor 200C as a VFET having the above structure, the length of the side surface of the insulating layer 258 seen from the X direction or the Y direction corresponds to the channel length L (channel length L1) (see FIG. 25B). Thus, the channel length L of the transistor 200C depends on the thickness t1 of the insulating layer 258.

A material that contains no hydrogen or an extremely small amount of hydrogen is preferably used for the insulating layers 257 and 259. For example, silicon nitride that contains an extremely small amount of hydrogen or silicon nitride oxide that contains an extremely small amount of hydrogen is preferably used. In that case, the region of the semiconductor layer 263 that is in contact with the insulating layer 257 and the region of the semiconductor layer 263 that is in contact with the insulating layer 259 do not have n-type conductivity. Thus, the region of the semiconductor layer 263 that is in contact with the conductive layer 261 functions as one of the source region and the drain region. The region of the semiconductor layer 263 that is in contact with the conductive layer 255 functions as the other of the source region and the drain region. The region of the semiconductor layer 263 that is in contact with the insulating layer 258 functions as a channel formation region.

In that case, the sum of the lengths of the side surfaces of the insulating layers 257, 258, and 259 seen from the X direction or the Y direction corresponds to the channel length L (channel length L2). Thus, the channel length L of the transistor 200C depends on the thickness t2, which is the total thickness of the insulating layers 257, 258, and 259. In this manner, the channel formation region of the transistor 200C includes a region along the side surface of the insulating layer 256.

Since the semiconductor layer 263 is provided in the opening 262, the length of the circumference of the opening 262 seen from the Z direction corresponds to the channel width W of the transistor 200C (see FIG. 25A). The length of the circumference is calculated at the position at the half of the thickness t1 of the insulating layer 258 or the position at the half of the thickness t2, for example. Note that the length of the circumference of the opening 262 at a given position can be regarded as the channel width W as necessary. For example, the length of the circumference of the lowest portion or the uppermost portion of the opening 262 can be regarded as the channel width W. Although the outline (the planar shape) of the opening 262 seen from the Z direction is circular in FIG. 25A, the outline is not limited to this. For example, the outline of the opening 262 seen from the Z direction can be elliptical or rectangular.

In the semiconductor device of one embodiment of the present invention, the channel length L is preferably shorter than at least the channel width W. The channel length L in one embodiment of the present invention is greater than or equal to 0.1 times and less than or equal to 0.99 times, preferably greater than or equal to 0.5 times and less than or equal to 0.8 times the channel width W.

In order to improve the coverage with the semiconductor layer 263, the insulating layer 264, and the conductive layer 265 that are formed inside the opening 262, the taper angle θ of the side surface of the opening 262, i.e., the taper angle θ of each of the side surfaces of the insulating layers 257, 258, and 259, is greater than or equal to 45° and less than 90°, preferably greater than or equal to 50° and less than or equal to 75°. The side surfaces of the insulating layers 257, 258, and 259 can have the same taper angle θ or different taper angles θ. Note that the taper angle θ of the side surface of a layer (an insulating layer, a conductive layer, or a semiconductor layer) refers to an angle formed between the bottom surface and the side surface of the layer (see FIG. 25B).

The area occupied by a vertical transistor can be smaller than the area occupied by a transistor whose channel formation region, source region, and drain region are provided separately on the XY plane (such a transistor is also referred to as a “lateral transistor”). Thus, the use of a vertical-channel transistor for a semiconductor device can reduce the area occupied by the semiconductor device. Furthermore, a semiconductor device including a vertical-channel transistor can have a high degree of integration.

The channel length of a lateral transistor has been limited by the light exposure limit of photolithography. The channel length of the vertical-channel transistor of one embodiment of the present invention can be set with the thickness of the insulating layer 256 or the insulating layer 258. Thus, the transistor can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm, or greater than or equal to 5 nm). Accordingly, the transistor 200C can have a higher on-state current and improved frequency characteristics. With the use of a vertical-channel transistor, a semiconductor device with a high operation speed can be provided.

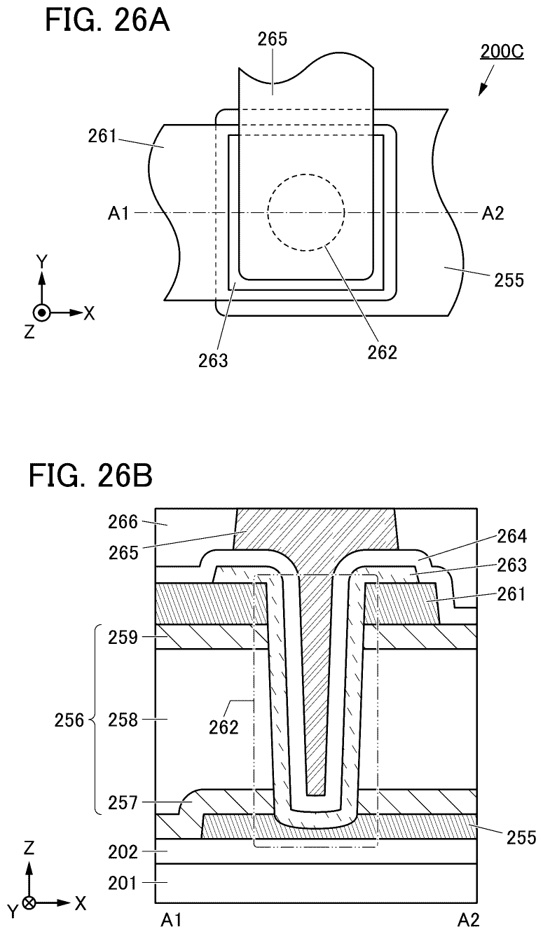

As illustrated in FIGS. 26A and 26B, the conductive layer 255 is sometimes partly removed at the time of forming the opening 262 depending on the etching conditions of the conductive layer 261 and the insulating layer 256. In addition, the bottom portion of the opening 262 sometimes has a curved portion.

### <Structure Example 4 of Transistor>

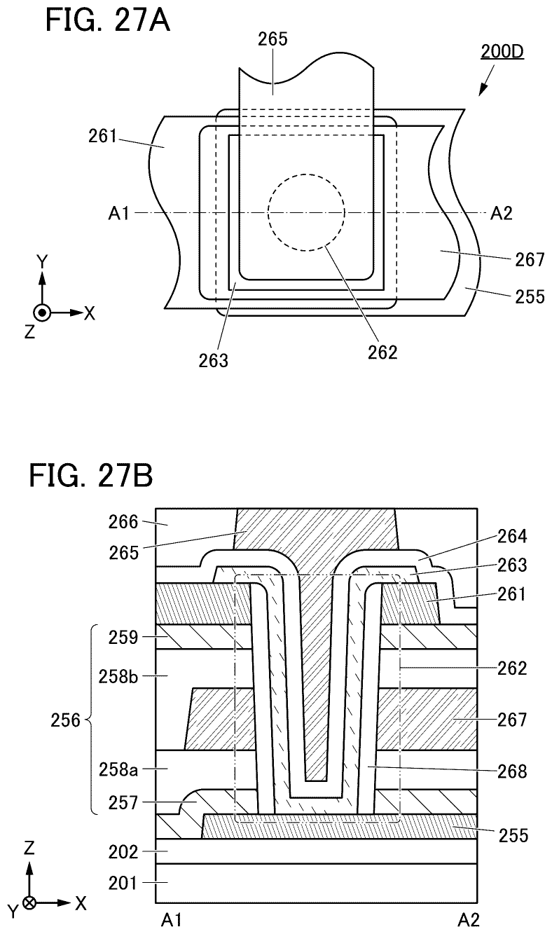

FIG. 27A is a plan view of a transistor 200D that can be used for the semiconductor device of one embodiment of the present invention. FIG. 27B is a cross-sectional view taken along the dashed-dotted line A1-A2 in FIG. 27A. The transistor 200D is a modification example of the transistor 200C. Differences of the transistor 200D from the transistor 200C are mainly described to reduce repeated description.

The transistor 200D includes an insulating layer 258a and an insulating layer 258b between the insulating layer 257 and the insulating layer 259, and includes a conductive layer 267 between the insulating layer 258a and the insulating layer 258b. The insulating layer 258a and the insulating layer 258b can be formed using a material and a method similar to those of the insulating layer 258. In the transistor 200D, the conductive layers 261 and 267 and the insulating layers 259, 258b, 258a, and 257 are penetrated by the opening 262 in a region overlapping with part of the conductive layer 255.

In the transistor 200D, an insulating layer 268 is provided along the side surface of the opening 262. In the opening 262, the insulating layer 268 includes a region overlapping with the side surface of the conductive layer 261, a region overlapping with the side surface of the insulating layer 259, a region overlapping with the side surface of the insulating layer 258b, a region overlapping with the side surface of the conductive layer 267, a region overlapping with the side surface of the insulating layer 258a, and a region overlapping with the side surface of the insulating layer 257.

The semiconductor layer 263 of the transistor 200D includes, in the opening 262, a region overlapping with the side surface of the conductive layer 261 with the insulating layer 268 therebetween, a region overlapping with the side surface of the insulating layer 259 with the insulating layer 268 therebetween, a region overlapping with the side surface of the insulating layer 258b with the insulating layer 268 therebetween, a region overlapping with the side surface of the conductive layer 267 with the insulating layer 268 therebetween, a region overlapping with the side surface of the insulating layer 258a with the insulating layer 268 therebetween, and a region overlapping with the side surface of the insulating layer 257 with the insulating layer 268 therebetween.

In the case where the conductive layer 265 is used as a gate electrode, the conductive layer 267 functions as a back gate electrode. In the case where the conductive layer 267 is used as a gate electrode, the conductive layer 265 functions as a back gate electrode. One of the insulating layers 264 and 268 functions as a gate insulating layer, and the other functions as a back gate insulating layer. The insulating layer 268 can be formed using a material and a method similar to those for the insulating layer 264.

### <Structure Example 5 of Transistor>

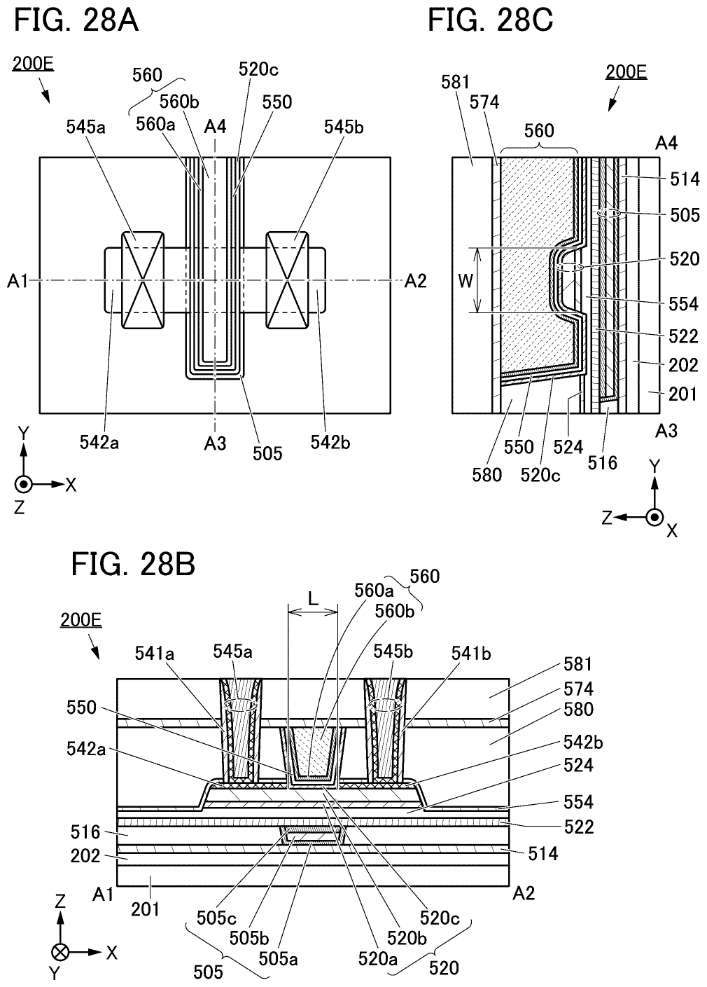

FIG. 28A is a plan view of a transistor 200E that can be used for the semiconductor device of one embodiment of the present invention. FIG. 28B is a cross-sectional view taken along the dashed-dotted line A1-A2 in FIG. 28A. FIG. 28C is a cross-sectional view taken along the dashed-dotted line A3-A4 in FIG. 28A. FIG. 28B is a cross-sectional view of the transistor 200E in the channel length direction, and FIG. 28C is a cross-sectional view of the transistor 200E in the channel width direction.

As illustrated in FIGS. 28A to 28C, the transistor 200E includes a semiconductor layer 520a placed over the substrate 201; a semiconductor layer 520b placed over the semiconductor layer 520a; a conductive layer 542a and a conductive layer 542b placed apart from each other over the semiconductor layer 520b; an insulating layer 580 that is placed over the conductive layers 542a and 542b and has an opening between the conductive layers 542a and 542b; a conductive layer 560 placed in the opening; an insulating layer 550 placed between the conductive layer 560 and each of the semiconductor layer 520b, the conductive layer 542a, the conductive layer 542b, and the insulating layer 580; and a semiconductor layer 520c placed between the insulating layer 550 and each of the semiconductor layer 520b, the conductive layer 542a, the conductive layer 542b, and the insulating layer 580.

Here, as illustrated in FIGS. 28B and 28C, the top surface of the conductive layer 560 is substantially level with the top surfaces of the insulating layer 550, the semiconductor layer 520c, and the insulating layer 580. Hereinafter, the semiconductor layers 520a, 520b, and 520c are sometimes collectively referred to as a semiconductor layer 520.

The conductive layer 542a functions as one of a source electrode and a drain electrode of the transistor 200E. The conductive layer 542b functions as the other of the source electrode and the drain electrode of the transistor 200E. In this specification, the conductive layers 542a and 542b are sometimes collectively referred to as a conductive layer 542.

As illustrated in FIGS. 28A to 28C, an insulating layer 554 is placed between the insulating layer 580 and each of an insulating layer 524, the semiconductor layer 520a, the semiconductor layer 520b, the conductive layer 542a, the conductive layer 542b, and the semiconductor layer 520c. The insulating layer 554 is in contact with the side surface of the semiconductor layer 520c, the top and side surfaces of the conductive layer 542a, the top and side surfaces of the conductive layer 542b, the side surfaces of the semiconductor layers 520a and 520b, and the top surface of the insulating layer 524.

The channel of the transistor 200E is formed in a region of the semiconductor layer 520 that overlaps with the conductive layer 560. Thus, the channel length L of the transistor 200E can be represented by the length of a region of the conductive layer 560 that overlaps with the semiconductor layer 520 in the X direction. The channel of the transistor 200E is formed in a region of the semiconductor layer 520 between a region functioning as the source and a region functioning as the drain. Thus, the channel length L of the transistor 200E can be represented by the distance between the end portion of the conductive layer 542a and the end portion of the conductive layer 542b.

The channel width W of the transistor 200E can be represented by the length of a region of the semiconductor layer 520 that overlaps with the conductive layer 560 in the Y direction.

The transistor 200E has a structure in which three layers of the semiconductor layers 520a, 520b, and 520c are stacked in the channel formation region and its vicinity; however, the present invention is not limited to this structure. For example, a two-layer structure of the semiconductor layers 520b and 520c or a stacked-layer structure of four or more layers can be employed. Moreover, each of the semiconductor layers 520a, 520b, and 520c can have a stacked-layer structure of two or more layers.

For example, in the case where the semiconductor layer 520 is formed using an oxide semiconductor, which is a kind of metal oxide, and the semiconductor layer 520c has a stacked-layer structure of a first metal oxide and a second metal oxide over the first metal oxide, it is preferable that the first metal oxide have a composition similar to that of the semiconductor layer 520b and the second metal oxide have a composition similar to that of the semiconductor layer 520a.

Here, the conductive layer 560 functions as a gate electrode of the transistor, and the conductive layers 542a and 542b function as a source electrode and a drain electrode. As described above, the conductive layer 560 is formed to be embedded in the opening in the insulating layer 580 and the region between the conductive layers 542a and 542b. Note that the conductive layers 560, 542a, and 542b are positioned in a self-aligned manner with respect to the opening in the insulating layer 580. That is, in the transistor 200E, the gate electrode can be positioned between the source electrode and the drain electrode in a self-aligned manner. Thus, the conductive layer 560 can be formed without an alignment margin, resulting in a reduction in the area occupied by the transistor 200E. This can reduce the area occupied by the semiconductor device. In addition, the degree of integration of the semiconductor device can be increased.

As illustrated in FIGS. 28A to 28C, the conductive layer 560 includes a conductive layer 560a provided inside the insulating layer 550 and a conductive layer 560b provided to be embedded inside the conductive layer 560a. Although the conductive layer 560 has a two-layer structure in the transistor 200E, the present invention is not limited thereto. For example, the conductive layer 560 may have a single-layer structure or a stacked-layer structure of three or more layers.

The transistor 200E includes the insulating layer 202 placed over the substrate 201; an insulating layer 514 placed over the insulating layer 202; an insulating layer 516 placed over the insulating layer 514; a conductive layer 505 placed to be embedded in the insulating layer 516; an insulating layer 522 placed over the insulating layer 516 and the conductive layer 505; and the insulating layer 524 placed over the insulating layer 522. The semiconductor layer 520a is placed over the insulating layer 524.

An insulating layer 574 and an insulating layer 581 functioning as interlayer films are placed over the transistor 200E. The insulating layer 574 is placed in contact with the top surfaces of the conductive layer 560, the insulating layer 550, the semiconductor layer 520c, and the insulating layer 580.

In the case where the semiconductor layer 520 is formed using an oxide semiconductor, an insulating layer having a function of inhibiting diffusion of hydrogen (e.g., at least one of a hydrogen atom, a hydrogen molecule, and the like) is preferably used as each of the insulating layers 522, 554, and 574. For example, as each of the insulating layers 522, 554, and 574, an insulating layer having a lower hydrogen permeability than the insulating layers 524, 550, and 580 is preferably used. For example, silicon nitride, silicon nitride oxide, or the like can be used.

Alternatively, an insulating layer having a function of inhibiting diffusion of oxygen (e.g., at least one of an oxygen atom, an oxygen molecule, and the like) is preferably used as each of the insulating layers 522 and 554. For example, as each of the insulating layers 522 and 554, an insulating layer having a lower oxygen permeability than the insulating layers 524, 550, and 580 is preferably used. For example, silicon nitride, silicon nitride oxide, or the like can be used.

Here, the insulating layer 524, the semiconductor layer 520, and the insulating layer 550 are separated from a layer above the insulating layer 574 and a layer below the insulating layer 522 by the insulating layers 522 and 574. This can inhibit entry of excess oxygen and impurities such as hydrogen contained in the layer above the insulating layer 574 and the layer below the insulating layer 522 into the insulating layer 524, the semiconductor layer 520, and the insulating layer 550.

FIG. 28B illustrates an example in which a conductive layer 545 (a conductive layer 545a and a conductive layer 545b) that is connected to the transistor 200E and functions as a plug is provided. In this example, an insulating layer 541 (an insulating layer 541a and an insulating layer 541b) is provided in contact with the side surface of the conductive layer 545 functioning as a plug. That is, the insulating layer 541 is provided in contact with the inner wall of an opening in the insulating layers 554, 580, 574, and 581. In FIG. 28B, a first conductive layer of the conductive layer 545 is provided in contact with the side surface of the insulating layer 541, and a second conductive layer of the conductive layer 545 is provided on the inner side of the first conductive layer.

Here, the top surface of the conductive layer 545 and the top surface of the insulating layer 581 can be substantially level with each other. Although the transistor 200E has a structure in which the first conductive layer of the conductive layer 545 and the second conductive layer of the conductive layer 545 are stacked, the present invention is not limited thereto. For example, the conductive layer 545 can have a single-layer structure or a stacked-layer structure of three or more layers. In the case where a component has a stacked-layer structure, layers may be distinguished by ordinal numbers corresponding to the formation order.

The semiconductor layer 520b in a region that does not overlap with the conductive layer 542 sometimes has a smaller thickness than the semiconductor layer 520b in a region that overlaps with the conductive layer 542. The thin region is formed when part of the top surface of the semiconductor layer 520b is removed at the time of forming the conductive layers 542a and 542b. When a conductive film to be the conductive layer 542 is formed, a low-resistance region is sometimes formed on the top surface of the semiconductor layer 520b in the vicinity of the interface with the conductive film. Removing the low-resistance region in the semiconductor layer 520b that is positioned between the conductive layer 542a and the conductive layer 542b in a plan view in this manner can prevent formation of a channel in the region.

Next, the structure of the transistor 200E that can be used for the semiconductor device of one embodiment of the present invention will be described in detail.

The conductive layer 505 is placed to include a region overlapping with the conductive layer 560 with the semiconductor layer 520 therebetween. When the conductive layer 505 is provided to be embedded in the insulating layer 516, unevenness of the top surfaces of the conductive layer 505 and the insulating layer 516 can be reduced and coverage with a layer formed in a later step can be improved.

The conductive layer 505 includes a conductive layer 505a, a conductive layer 505b, and a conductive layer 505c. The conductive layer 505a is provided in contact with the bottom surface and the sidewall of an opening provided in the insulating layer 516. The conductive layer 505b is provided to be embedded in a depressed portion formed by the conductive layer 505a. Here, the level of the top surface of the conductive layer 505b is lower than the levels of the top surfaces of the conductive layer 505a and the insulating layer 516. The conductive layer 505c is provided in contact with the top surface of the conductive layer 505b and the side surface of the conductive layer 505a. Here, the top surface of the conductive layer 505c is level or substantially level with the top surfaces of the conductive layer 505a and the insulating layer 516. That is, the conductive layer 505b is surrounded by the conductive layers 505a and 505c.

In the case where the semiconductor layer 520 is formed using an oxide semiconductor, the conductive layers 505a and 505c are formed using a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, the conductive layers 505a and 505c are formed using a conductive material having a function of inhibiting diffusion of oxygen (e.g., at least one of an oxygen atom, an oxygen molecule, and the like).

When the conductive layers 505a and 505c are formed using a conductive material having a function of inhibiting diffusion of hydrogen, impurities such as hydrogen contained in the conductive layer 505b can be inhibited from diffusing into the semiconductor layer 520 through the insulating layer 524 and the like. When the conductive layers 505a and 505c are formed using a conductive material having a function of inhibiting diffusion of oxygen, the conductivity of the conductive layer 505b can be inhibited from being lowered because of oxidation. As the conductive material having a function of inhibiting diffusion of oxygen, for example, titanium, titanium nitride, tantalum, tantalum nitride, ruthenium, or ruthenium oxide can be used. Thus, the conductive layer 505a can be a single layer or stacked layers of the above conductive materials. For example, titanium nitride can be used for the conductive layer 505a. A conductive material containing tungsten, copper, or aluminum as its main component is preferably used for the conductive layer 505b. For example, tungsten is preferably used for the conductive layer 505b. In the case where the conductive layer 560 is used as a gate electrode, the conductive layer 505 functions as a back gate electrode.

The conductive layer 505 is preferably larger than the channel formation region in the semiconductor layer 520. It is particularly preferable that the conductive layer 505 extend beyond an end portion of the semiconductor layer 520 that intersects with the channel width direction, as illustrated in FIG. 28C. That is, the conductive layers 505 and 560 preferably overlap with each other with the insulating layers therebetween, in a region beyond the side surface of the semiconductor layer 520 in the channel width direction.

With the above structure, the channel formation region in the semiconductor layer 520 can be surrounded by an electric field of the conductive layer 560 functioning as the gate electrode and an electric field of the conductive layer 505 functioning as the back gate electrode.

The conductive layer 505 extending beyond the end portion of the semiconductor layer 520 can be used as a wiring. However, without limitation to this structure, a structure in which a conductive layer functioning as a wiring is provided below the conductive layer 505 can be employed.

The insulating layer 514 is preferably formed using an insulating material that functions as a barrier insulating film inhibiting entry of impurities such as water or hydrogen to the transistor 200E from the substrate side. Accordingly, the insulating layer 514 is preferably formed using an insulating material having a function of inhibiting diffusion of impurities such as a hydrogen atom, a hydrogen molecule, a water molecule, a nitrogen atom, a nitrogen molecule, a nitrogen oxide molecule, and a copper atom (an insulating material through which the above impurities are less likely to pass). Alternatively, an insulating material having a function of inhibiting diffusion of oxygen (an insulating material through which oxygen is less likely to pass) is preferably used.

For example, aluminum oxide or silicon nitride is used for the insulating layer 514. Accordingly, it is possible to inhibit diffusion of impurities such as water or hydrogen to the transistor 200E side from the substrate side through the insulating layer 514. Alternatively, it is possible to inhibit diffusion of oxygen contained in the insulating layer 524 and the like to the substrate side through the insulating layer 514.

For the insulating layers 516, 580, and 581 functioning as interlayer films, an insulating material having a lower permittivity than the insulating layer 514 is preferably used. When a material with a low permittivity is used for an interlayer film, parasitic capacitance generated between wirings can be reduced. For example, for the insulating layers 516, 580, and 581, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, or the like is used as appropriate.

In the case where the conductive layer 560 is used as a gate electrode, the insulating layers 522 and 524 function as gate insulating layers.

Here, the insulating layer 524 in contact with the semiconductor layer 520 preferably contains excess oxygen. For example, silicon oxide or silicon oxynitride is used as appropriate for the insulating layer 524. When an insulating layer containing oxygen is provided in contact with the semiconductor layer 520, oxygen vacancies in the semiconductor layer 520 are reduced, whereby the reliability of the transistor 200E is improved.

As illustrated in FIG. 28C, the insulating layer 524 is sometimes thinner in a region overlapping with neither the insulating layer 554 nor the semiconductor layer 520b than in the other regions. In the insulating layer 524, the region overlapping with neither the insulating layer 554 nor the semiconductor layer 520b preferably has a thickness with which the above oxygen can be adequately diffused.

Like the insulating layer 514 or the like, the insulating layer 522 is formed using a material that functions as a barrier insulating film inhibiting entry of impurities such as water or hydrogen to the transistor 200E from the substrate side. For example, the insulating layer 522 is formed using a material having a lower hydrogen permeability than the insulating layer 524. When the insulating layer 524, the semiconductor layer 520, the insulating layer 550, and the like are surrounded by the insulating layers 522, 554, and 574, entry of impurities such as water or hydrogen to the transistor 200E from the outside can be inhibited.

Furthermore, the insulating layer 522 is preferably formed using a material having a function of inhibiting diffusion of oxygen (a material through which oxygen is less likely to pass). For example, the insulating layer 522 is formed using a material having a lower oxygen permeability than the insulating layer 524. When the insulating layer 522 has a function of inhibiting diffusion of oxygen and impurities, diffusion of oxygen from the semiconductor layer 520 to the substrate side can be inhibited. Moreover, the conductive layer 505 can be inhibited from reacting with oxygen contained in the insulating layer 524 or the semiconductor layer 520.

As the insulating layer 522, an insulating layer containing an oxide of one or both of aluminum and hafnium, which is an insulating material, is preferably used. As the insulating layer containing an oxide of one or both of aluminum and hafnium, aluminum oxide, hafnium oxide, an oxide containing aluminum and hafnium (hafnium aluminate), or the like is preferably used. The insulating layer 522 formed using such a material functions as a layer that inhibits release of oxygen from the semiconductor layer 520 and entry of impurities such as hydrogen from the periphery of the transistor 200E into the semiconductor layer 520.

Alternatively, aluminum oxide, bismuth oxide, germanium oxide, niobium oxide, silicon oxide, titanium oxide, tungsten oxide, yttrium oxide, or zirconium oxide can be added to the insulating layer 522, for example. Alternatively, the insulating layer 522 can be subjected to nitriding treatment. A stack of the insulating layer 522 and silicon oxide, silicon oxynitride, or silicon nitride can be used. For example, the insulating layer 522 can have a three-layer structure in which silicon nitride, silicon oxide, and aluminum oxide are stacked in this order.

The insulating layer 522 can have a single-layer structure or a stacked-layer structure of an insulating layer containing what is called a high-k material, such as aluminum oxide, hafnium oxide, tantalum oxide, zirconium oxide, lead zirconate titanate (PZT), strontium titanate (SrTiO₃), or (Ba,Sr)TiO₃ (BST), for example. As scaling down and high integration of transistors progress, a problem such as generation of leakage current may arise because of a thinner gate insulating layer. When a high-k material is used for an insulating layer functioning as a gate insulating layer, a gate potential during operation of the transistor can be reduced while the physical thickness is maintained.

Note that the insulating layers 522 and 524 can each have a stacked-layer structure of two or more layers. In that case, without limitation to a stacked-layer structure formed of the same material, a stacked-layer structure formed of different materials can be employed.

The semiconductor layer 520 includes the semiconductor layer 520a, the semiconductor layer 520b over the semiconductor layer 520a, and the semiconductor layer 520c over the semiconductor layer 520b. Since the semiconductor layer 520a is provided under the semiconductor layer 520b, impurities can be inhibited from diffusing into the semiconductor layer 520b from the structures formed below the semiconductor layer 520a. Since the semiconductor layer 520c is provided over the semiconductor layer 520b, impurities can be inhibited from diffusing into the semiconductor layer 520b from the structures formed above the semiconductor layer 520c.

In the case where an oxide semiconductor is used for the semiconductor layer 520, the semiconductor layer 520 preferably has a stacked-layer structure of oxide layers that differ in the atomic ratio of metal atoms. For example, in the case where the semiconductor layer 520 contains at least indium (In) and an element M, the proportion of the number of atoms of the element M contained in the semiconductor layer 520a in the number of atoms of all the elements that constitute the semiconductor layer 520a is higher than the proportion of the number of atoms of the element M contained in the semiconductor layer 520b in the number of atoms of all the elements that constitute the semiconductor layer 520b. The atomic ratio of the element M to In in the semiconductor layer 520a is higher than the atomic ratio of the element M to In in the semiconductor layer 520b. Here, for the semiconductor layer 520c, a metal oxide that can be used for the semiconductor layer 520a or the semiconductor layer 520b can be used.

The energy of the conduction band minimum of each of the semiconductor layers 520a and 520c is preferably higher than that of the semiconductor layer 520b. In other words, the electron affinity of each of the semiconductor layers 520a and 520c is preferably less than that of the semiconductor layer 520b. In that case, a metal oxide that can be used for the semiconductor layer 520a is used for the semiconductor layer 520c. Specifically, the proportion of the number of atoms of the element M contained in the semiconductor layer 520c in the number of atoms of all the elements that constitute the semiconductor layer 520c is preferably higher than the proportion of the number of atoms of the element M contained in the semiconductor layer 520b in the number of atoms of all the elements that constitute the semiconductor layer 520b. The atomic ratio of the element M to In in the semiconductor layer 520c is preferably higher than the atomic ratio of the element M to In in the semiconductor layer 520b.

The energy level of the conduction band minimum gradually changes in junction portions of the semiconductor layers 520a, 520b, and 520c. In other words, the energy level of the conduction band minimum in the junction portions of the semiconductor layers 520a, 520b, and 520c is continuously varied or continuously connected. To vary the energy level gradually, the density of defect states in each of a mixed layer formed at the interface between the semiconductor layer 520a and the semiconductor layer 520b and a mixed layer formed at the interface between the semiconductor layer 520b and the semiconductor layer 520c is preferably made low.

Specifically, when the semiconductor layers 520a and 520b or the semiconductor layers 520b and 520c contain the same element (as a main component) in addition to oxygen, a mixed layer with a low density of defect states can be formed. For example, in the case where the semiconductor layer 520b is an In—Ga—Zn oxide, it is possible to use an In—Ga—Zn oxide, a Ga—Zn oxide, gallium oxide, or the like for the semiconductor layers 520a and 520c. Furthermore, the semiconductor layer 520c can have a stacked-layer structure. For example, the semiconductor layer 520c can have a stacked-layer structure of an In—Ga—Zn oxide and a Ga—Zn oxide over the In—Ga—Zn oxide or a stacked-layer structure of an In—Ga—Zn oxide and gallium oxide over the In—Ga—Zn oxide. In other words, the semiconductor layer 520c can have a stacked-layer structure of an In—Ga—Zn oxide and an oxide that does not contain In.

Specifically, for the semiconductor layer 520a, a metal oxide having an atomic ratio of In:Ga:Zn=1:3:4 or in the neighborhood thereof or an atomic ratio of In:Ga:Zn=1:1:0.5 or in the neighborhood thereof is used. For the semiconductor layer 520b, a metal oxide having an atomic ratio of In:Ga:Zn=4:2:3 or in the neighborhood thereof, an atomic ratio of In:Ga:Zn=3:1:2 or in the neighborhood thereof, or an atomic ratio of In:Ga:Zn=1:1:1 or in the neighborhood thereof is used. For the semiconductor layer 520c, a metal oxide having an atomic ratio of In:Ga:Zn=1:3:4 or in the neighborhood thereof, an atomic ratio of In:Ga:Zn=4:2:3 or in the neighborhood thereof, an atomic ratio of Ga:Zn=2:1 or in the neighborhood thereof, or an atomic ratio of Ga:Zn=2:5 or in the neighborhood thereof is used. Specific examples of a stacked-layer structure of the semiconductor layer 520c include a stacked-layer structure of a layer having an atomic ratio of In:Ga:Zn=4:2:3 or in the neighborhood thereof and a layer having an atomic ratio of Ga:Zn=2:1 or in the neighborhood thereof, a stacked-layer structure of a layer having an atomic ratio of In:Ga:Zn=4:2:3 or in the neighborhood thereof and a layer having an atomic ratio of Ga:Zn=2:5 or in the neighborhood thereof, and a stacked-layer structure of a layer having an atomic ratio of In:Ga:Zn=4:2:3 or in the neighborhood thereof and gallium oxide.

In that case, the semiconductor layer 520b serves as a main carrier path. When the semiconductor layers 520a and 520c have the above structures, the density of defect states at the interface between the semiconductor layers 520a and 520b and the interface between the semiconductor layers 520b and 520c can be made low. This reduces the influence of interface scattering on carrier conduction, and the transistor 200E can have a high on-state current and excellent frequency characteristics. Note that in the case where the semiconductor layer 520c has a stacked-layer structure, not only the density of defect states at the interface between the semiconductor layers 520b and 520c would be made low, but also the constituent elements of the semiconductor layer 520c would be inhibited from diffusing to the insulating layer 550 side. Specifically, since the semiconductor layer 520c has a stacked-layer structure in which the oxide in the upper layer does not contain In, In can be inhibited from diffusing to the insulating layer 550 side. Since the insulating layer 550 functions as a gate insulating layer, the transistor would show poor characteristics when In diffuses into the insulating layer 550. Thus, the semiconductor layer 520c having a stacked-layer structure allows the semiconductor device to have high reliability.

The conductive layer 542 (the conductive layers 542a and 542b) functioning as the source electrode and the drain electrode is provided over the semiconductor layer 520b. In the case where the semiconductor layer 520b is formed using an oxide semiconductor, the conductive layer 542 is preferably formed using a conductive material that is less likely to be oxidized or a conductive material that maintains the conductivity even after absorbing oxygen.

A region of the semiconductor layer 520 that is in contact with the conductive layer 542 functions as a source region or a drain region of the transistor 200E. Here, a region between the conductive layers 542a and 542b is formed to overlap with the opening in the insulating layer 580. Accordingly, the conductive layer 560 can be placed in a self-aligned manner between the conductive layers 542a and 542b.

The insulating layer 550 functions as a gate insulating layer. The insulating layer 550 is placed in contact with the top surface of the semiconductor layer 520c. For the insulating layer 550, silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide can be used. For example, silicon oxide or silicon oxynitride is used for the insulating layer 550.

Like the insulating layer 524, the insulating layer 550 is formed using an insulating material in which the concentration of impurities such as water or hydrogen is reduced. The thickness of the insulating layer 550 is greater than or equal to 1 nm and less than or equal to 20 nm.

A metal oxide is preferably provided between the insulating layer 550 and the conductive layer 560. The metal oxide inhibits diffusion of oxygen from the insulating layer 550 to the conductive layer 560. Thus, oxidation of the conductive layer 560 due to oxygen contained in the insulating layer 550 can be inhibited.

Although the conductive layer 560 has a two-layer structure in FIGS. 28A to 28C, the conductive layer 560 can have a single-layer structure or a stacked-layer structure of three or more layers.

The conductive layer 560a is preferably formed using the above-described conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, the conductive layer 560a is preferably formed using a conductive material having a function of inhibiting diffusion of oxygen.

When the conductive layer 560a has a function of inhibiting diffusion of oxygen, the conductivity of the conductive layer 560b can be inhibited from being lowered because of oxidation due to oxygen contained in the insulating layer 550. As the conductive material having a function of inhibiting diffusion of oxygen, for example, tantalum, tantalum nitride, ruthenium, or ruthenium oxide can be used.

The conductive layer 560b can be formed using a conductive material containing tungsten, copper, or aluminum as its main component, for example. The conductive layer 560 also functions as a wiring and thus preferably has high conductivity. The conductive layer 560b can have a stacked-layer structure, for example, a stacked-layer structure of titanium or titanium nitride and the above conductive material.

As illustrated in FIGS. 28B and 28C, the side surface of the semiconductor layer 520 is covered with the conductive layer 560 in a region of the semiconductor layer 520b that does not overlap with the conductive layer 542, i.e., the channel formation region in the semiconductor layer 520. Accordingly, the electric field of the conductive layer 560 functioning as the gate electrode of the transistor 200E is likely to act on the side surface of the semiconductor layer 520. Hence, the transistor 200E can have a higher on-state current and improved frequency characteristics.

Like the insulating layer 514 or the like, the insulating layer 554 is formed using an insulating material that inhibits entry of impurities such as water or hydrogen to the transistor 200E from the insulating layer 580 side. For example, the insulating layer 554 is formed using an insulating material having a lower hydrogen permeability than the insulating layer 524. Furthermore, as illustrated in FIGS. 28B and 28C, the insulating layer 554 is provided in contact with the side surface of the semiconductor layer 520c, the top and side surfaces of the conductive layer 542a, the top and side surfaces of the conductive layer 542b, the side surfaces of the semiconductor layers 520a and 520b, and the top surface of the insulating layer 524. Such a structure can inhibit entry of hydrogen contained in the insulating layer 580 into the semiconductor layer 520 through the top surfaces or the side surfaces of the conductive layers 542a and 542b, the semiconductor layers 520a and 520b, and the insulating layer 524.

Moreover, the insulating layer 554 is formed using an insulating material having a function of inhibiting diffusion of oxygen (e.g., at least one of an oxygen atom, an oxygen molecule, and the like) (an insulating material through which oxygen is less likely to pass). For example, the insulating layer 554 is formed using an insulating material having a lower oxygen permeability than the insulating layer 580 or the insulating layer 524.

In the case where the semiconductor layer 520 is formed using an oxide semiconductor, the insulating layer 554 can be formed by a sputtering method. When the insulating layer 554 is formed by a sputtering method in an oxygen-containing atmosphere, oxygen can be added to the vicinity of a region of the insulating layer 524 that is in contact with the insulating layer 554. Thus, oxygen can be supplied from the region to the semiconductor layer 520 through the insulating layer 524. Here, with the insulating layer 554 having a function of inhibiting upward oxygen diffusion, oxygen can be prevented from diffusing from the semiconductor layer 520 into the insulating layer 580. In addition, with the insulating layer 522 having a function of inhibiting downward oxygen diffusion, oxygen can be prevented from diffusing from the semiconductor layer 520 to the substrate side. In the above manner, oxygen is supplied to the channel formation region in the semiconductor layer 520. Accordingly, oxygen vacancies in the semiconductor layer 520 can be reduced, so that the transistor can be inhibited from having normally-on characteristics.

As the insulating layer 554, an insulating layer containing an oxide of one or both of aluminum and hafnium is formed, for example. As the insulating layer containing an oxide of one or both of aluminum and hafnium, aluminum oxide, hafnium oxide, an oxide containing aluminum and hafnium (hafnium aluminate), or the like can be used.

The insulating layer 580 is provided over the insulating layer 524, the semiconductor layer 520, and the conductive layer 542 with the insulating layer 554 therebetween. For example, for the insulating layer 580, silicon oxide, silicon oxynitride, silicon nitride oxide, silicon oxide to which fluorine is added, silicon oxide to which carbon is added, silicon oxide to which carbon and nitrogen are added, porous silicon oxide, or the like is used. Silicon oxide and silicon oxynitride are particularly preferable because of their thermal stability. In particular, materials such as silicon oxide, silicon oxynitride, and porous silicon oxide are preferably used, in which case a region containing oxygen released by heating can be easily formed.

Like the insulating layer 514 or the like, the insulating layer 574 is formed using an insulating material that functions as a barrier insulating film inhibiting entry of impurities such as water or hydrogen to the insulating layer 580 from above. The insulating layer 574 is formed using an insulating material that can be used for the insulating layer 514, the insulating layer 554, and the like, for example.

FIGS. 28A to 28C illustrate an example in which the insulating layer 581 functioning as an interlayer film is provided over the insulating layer 574. Like the insulating layer 524 or the like, the insulating layer 581 is formed using an insulating material in which the concentration of impurities such as water or hydrogen is reduced.

The conductive layers 545a and 545b are placed in the openings formed in the insulating layers 581, 574, 580, and 554. The conductive layers 545a and 545b are provided with the conductive layer 560 sandwiched therebetween in a plan view. Note that the top surfaces of the conductive layers 545a and 545b are preferably on the same plane as the top surface of the insulating layer 581.

The insulating layer 541a is provided in contact with the inner wall of the opening in the insulating layers 581, 574, 580, and 554, and the first conductive layer of the conductive layer 545a is formed in contact with the side surface of the insulating layer 541a. The conductive layer 542a is positioned on at least part of the bottom portion of the opening, and the conductive layer 545a is in contact with the conductive layer 542a. Similarly, the insulating layer 541b is provided in contact with the inner wall of the opening in the insulating layers 581, 574, 580, and 554, and the first conductive layer of the conductive layer 545b is formed in contact with the side surface of the insulating layer 541b. The conductive layer 542b is positioned on at least part of the bottom portion of the opening, and the conductive layer 545b is in contact with the conductive layer 542b.

The conductive layers 545a and 545b are preferably formed using a conductive material containing tungsten, copper, or aluminum as its main component. The conductive layers 545a and 545b can each have a stacked-layer structure of two or more layers.

In the case where the conductive layer 545 has a stacked-layer structure, a conductive material having a function of inhibiting diffusion of impurities such as water or hydrogen is preferably used for the conductive layer in contact with the semiconductor layers 520a and 520b, the conductive layer 542, and the insulating layers 554, 580, 574, and 581. For example, tantalum, tantalum nitride, titanium, titanium nitride, ruthenium, or ruthenium oxide can be used. The use of the conductive material can inhibit oxygen contained in the insulating layer 580 from being absorbed by the conductive layers 545a and 545b. Moreover, impurities such as water or hydrogen can be inhibited from entering the semiconductor layer 520 through the conductive layers 545a and 545b from a layer above the insulating layer 581.

As each of the insulating layers 541a and 541b, for example, an insulating layer that can be used as the insulating layer 554 or the like is used. Since the insulating layers 541a and 541b are provided in contact with the insulating layer 554, impurities such as water or hydrogen can be inhibited from entering the semiconductor layer 520 from the insulating layer 580 or the like through the conductive layers 545a and 545b. Furthermore, oxygen contained in the insulating layer 580 can be inhibited from being absorbed by the conductive layers 545a and 545b.

### <Structure Example 6 of Transistor>

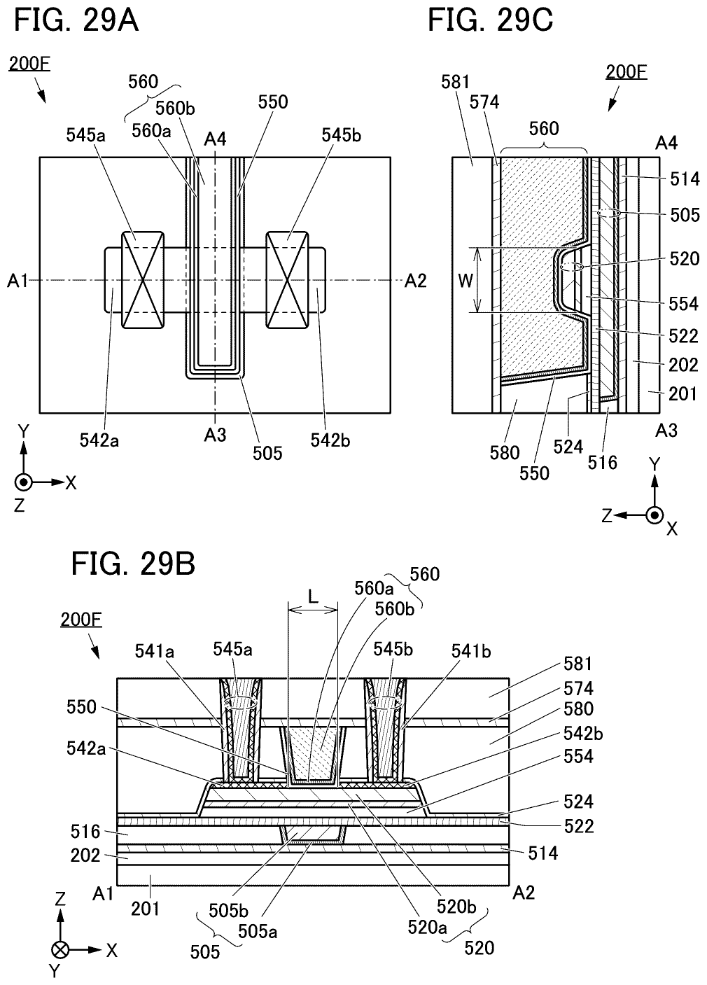

FIGS. 29A to 29C illustrate a modification example of the transistor 200E illustrated in FIGS. 28A to 28C. FIG. 29A is a plan view of a transistor 200F, which is a modification example of the transistor 200E. FIG. 29B is a cross-sectional view taken along the dashed-dotted line A1-A2 in FIG. 29A. FIG. 29C is a cross-sectional view taken along the dashed-dotted line A3-A4 in FIG. 29A. Since the transistor 200F is a modification example of the transistor 200E, differences of the transistor 200F from the transistor 200E are mainly described.

The transistor 200F has the structure of the transistor 200E from which the semiconductor layer 520c and the conductive layer 505c are omitted. A reduction in the number of components of the transistor can reduce the manufacturing cost. Furthermore, the manufacturing process is shortened when the number of components of the transistor is reduced, leading to an improvement in the manufacturing yield.

In the transistor 200F, the insulating layer 554 and the insulating layer 522 are in contact with each other in a region outside the semiconductor layer 520, and the side surface of the insulating layer 524 is covered with the insulating layer 554. In the case where the semiconductor layer 520 is formed using an oxide semiconductor, covering the side surface of the insulating layer 524 with the insulating layer 554 can prevent not only diffusion of oxygen to the outside through the insulating layer 524 but also excessive supply of oxygen from the insulating layer 524 side to the semiconductor layer 520.

An insulating layer is preferably provided between the insulating layer 550 and each of the insulating layers 580 and 554, the conductive layer 542, and the semiconductor layer 520b. For the insulating layer, aluminum oxide, hafnium oxide, or the like is preferably used. Providing the insulating layer can inhibit release of oxygen from the semiconductor layer 520 to the insulating layer 550 side, excessive supply of oxygen from the insulating layer 550 side to the semiconductor layer 520, oxidation of the conductive layer 542, and the like.

### <Structure Example 7 of Transistor>

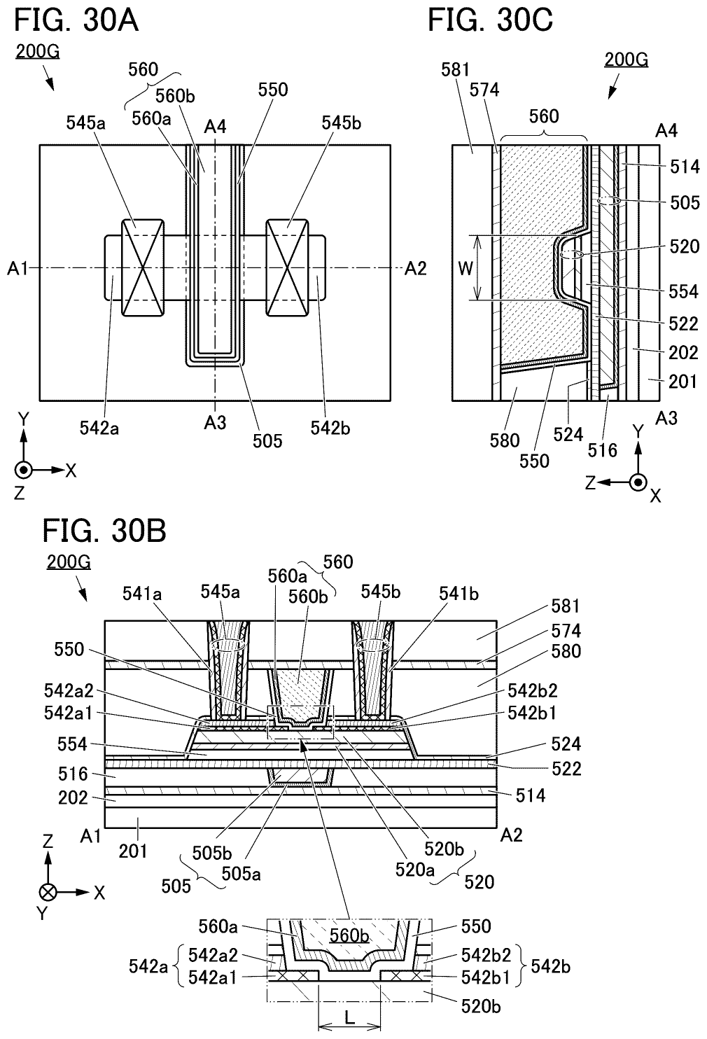

FIGS. 30A to 30C illustrate a modification example of the transistor 200F illustrated in FIGS. 29A to 29C. FIG. 30A is a plan view of a transistor 200G, which is a modification example of the transistor 200F. FIG. 30B is a cross-sectional view taken along the dashed-dotted line A1-A2 in FIG. 30A. FIG. 30C is a cross-sectional view taken along the dashed-dotted line A3-A4 in FIG. 30A. Since the transistor 200G is a modification example of the transistor 200F, differences of the transistor 200G from the transistor 200F are mainly described.

The transistor 200G is different from the transistor 200F in that the conductive layer 542 has a stacked-layer structure of two conductive layers. In FIG. 30B, the conductive layer 542a is illustrated as a conductive layer 542al and a conductive layer 542a2, and the conductive layer 542b is illustrated as a conductive layer 542b1 and a conductive layer 542b2. Specifically, the conductive layer 542al is provided over part of the semiconductor layer 520, and the conductive layer 542a2 is provided over the conductive layer 542a1. The conductive layer 542b1 is provided over another part of the semiconductor layer 520, and the conductive layer 542b2 is provided over the conductive layer 542b1.

The transistor 200G illustrated in FIG. 30B includes a region where the end portion of the conductive layer 542al extends beyond the end portion of the conductive layer 542a2, and the region includes a region overlapping with the conductive layer 560 with the insulating layer 550 therebetween. The transistor 200G also includes a region where the end portion of the conductive layer 542b1 extends beyond the end portion of the conductive layer 542b2, and the region includes a region overlapping with the conductive layer 560 with the insulating layer 550 therebetween.

With such a structure, the distance between the source and the drain can be shortened, and the channel length L can be accordingly shortened. The channel length L of the transistor 200G is determined by the distance between the end portion of the conductive layer 542al and the end portion of the conductive layer 542b1 (see FIG. 30B). A reduction in the channel length L increases the on-state current of the transistor 200G, thereby increasing the operation speed of the transistor 200G. Thus, the operation speed of the semiconductor device including the transistor 200G can be increased.

### <Structure Example 8 of Transistor>

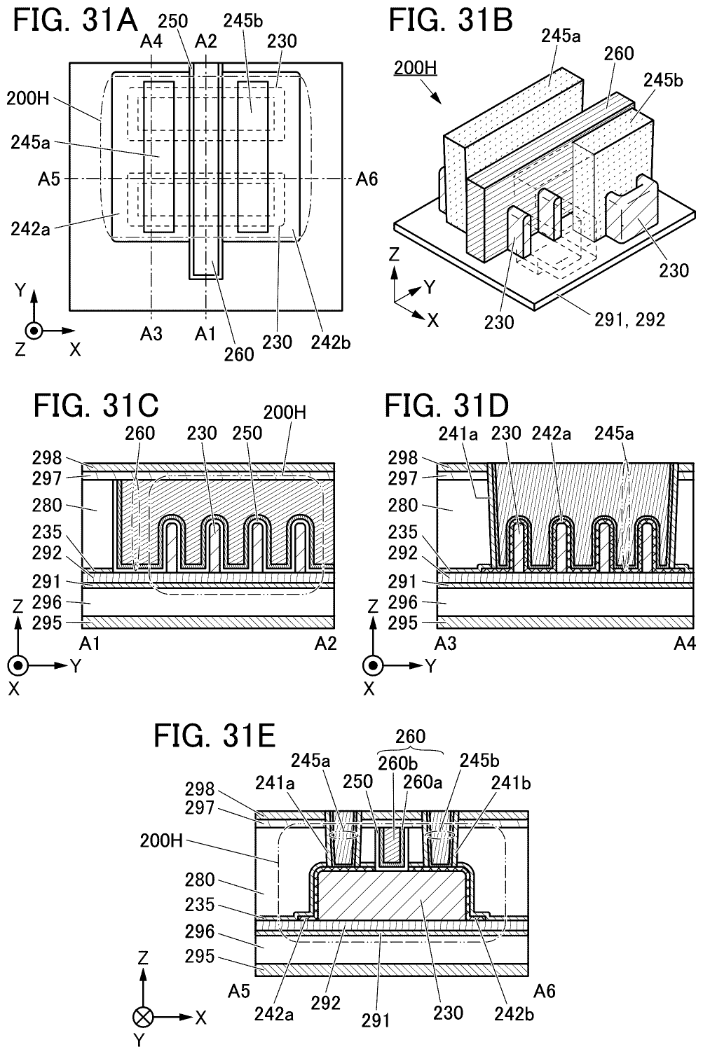

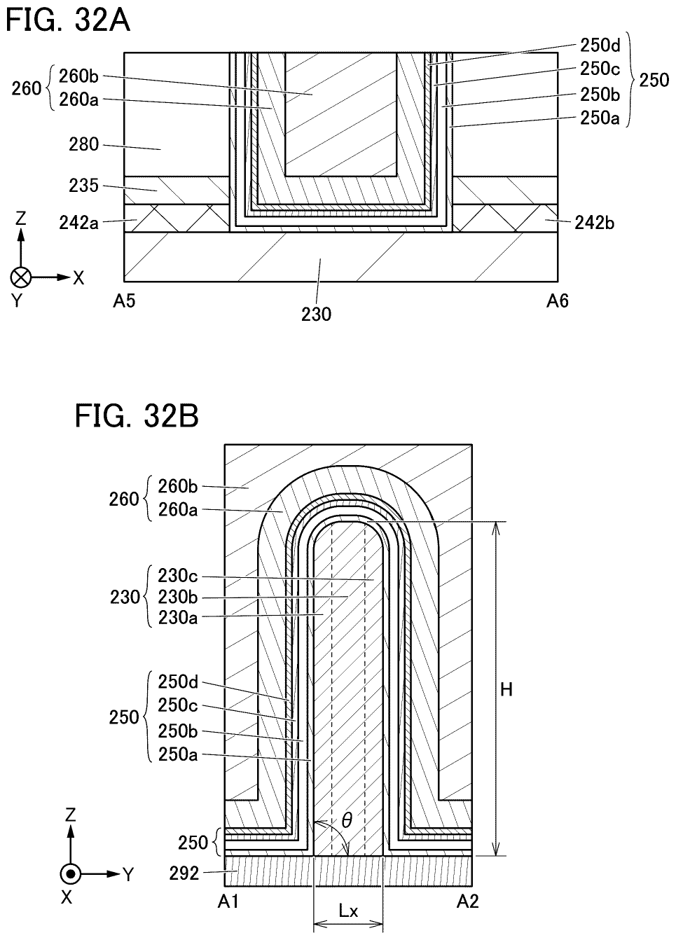

FIG. 31A is a plan view of a transistor 200H that can be used for the semiconductor device of one embodiment of the present invention. FIG. 31B is a schematic perspective view of the transistor 200H. FIGS. 31C to 31E are cross-sectional views of the transistor 200H. FIG. 31C is a cross-sectional view taken along the dashed-dotted line A1-A2 in FIG. 31A, which corresponds to a cross-sectional view of the transistor 200H in the channel width direction (the Y direction). FIG. 31D is a cross-sectional view taken along the dashed-dotted line A3-A4 in FIG. 31A, which corresponds to a cross-sectional view of the transistor 200H in the channel width direction. FIG. 31E is a cross-sectional view taken along the dashed-dotted line A5-A6 in FIG. 31A, which corresponds to a cross-sectional view of the transistor 200H in the channel length direction (the X direction). The dashed-dotted line A5-A6 is orthogonal to the dashed-dotted line A1-A2 and the dashed-dotted line A3-A4, and the dashed-dotted line A1-A2 is parallel to the dashed-dotted line A3-A4. Note that some components are not illustrated in the plan view of FIG. 31A and the schematic perspective view of FIG. 31B. FIG. 32A is an enlarged view of a conductive layer 260 and its vicinity in FIG. 31E. FIG. 32B is an enlarged view of a semiconductor layer 230 and its vicinity in FIG. 31C.

The transistor 200H of this embodiment includes an insulating layer 295 over a substrate (not illustrated), an insulating layer 296 over the insulating layer 295, an insulating layer 291 over the insulating layer 296, an insulating layer 292 over the insulating layer 291, the semiconductor layer 230 over the insulating layer 292, a conductive layer 242a and a conductive layer 242b over the semiconductor layer 230 and the insulating layer 292, an insulating layer 250 over the semiconductor layer 230, and the conductive layer 260 (a conductive layer 260a and a conductive layer 260b) over the insulating layer 250. In this specification, the conductive layers 242a and 242b are sometimes collectively referred to as a conductive layer 242.

An insulating layer 235 is provided over the conductive layer 242, and an insulating layer 280 is provided over the insulating layer 235. The insulating layer 250 and the conductive layer 260 are provided in a first opening that penetrates the insulating layers 280 and 235 and reaches the semiconductor layer 230. In the plan view, the first opening includes a region overlapping with the semiconductor layer 230 and a region extending along the Y direction beyond an end portion of the semiconductor layer 230. Thus, the insulating layer 250 and the conductive layer 260 provided in the first opening also include, in the plan view, a region overlapping with the semiconductor layer 230 and a region extending along the Y direction beyond the end portion of the semiconductor layer 230. The conductive layer 260 also functions as a wiring. The insulating layer 250 includes a region in contact with the semiconductor layer 230 in the first opening. An insulating layer 297 is provided over the insulating layer 280 and the conductive layer 260. An insulating layer 298 is provided over the insulating layer 297.

An insulating layer 241a is provided in contact with the inner wall of a second opening that penetrates the insulating layers 298, 297, 280, and 235 and reaches the conductive layer 242a, and a conductive layer 245a is provided in contact with the insulating layer 241a. The conductive layer 245a includes a region in contact with the conductive layer 242a at the bottom portion of the first opening.

An insulating layer 241b is provided in contact with the inner wall of a third opening that penetrates the insulating layers 298, 297, 280, and 235 and reaches the conductive layer 242b, and a conductive layer 245b is provided in contact with the insulating layer 241b. The conductive layer 245b includes a region in contact with the conductive layer 242b at the bottom portion of the second opening.

In this specification, the conductive layers 245a and 245b are sometimes collectively referred to as a conductive layer 245. In addition, the insulating layers 241a and 241b are sometimes collectively referred to as an insulating layer 241.

The semiconductor layer 230 includes a channel formation region of the transistor 200H. The conductive layer 260 includes a region that functions as a gate electrode of the transistor 200H. The insulating layer 250 includes a region that functions as a gate insulating layer of the transistor 200H. In the transistor 200H, a region of the semiconductor layer 230 that overlaps with the conductive layer 260 functions as the channel formation region. A region of the conductive layer 260 that overlaps with the semiconductor layer 230 functions as a gate electrode. A region of the insulating layer 250 that overlaps with the semiconductor layer 230 and the conductive layer 260 functions as a gate insulating layer.

The conductive layer 242a includes a region that functions as one of a source electrode and a drain electrode of the transistor 200H. The conductive layer 245a functions as a plug connected to the conductive layer 242a. The conductive layer 242b includes a region that functions as the other of the source electrode and the drain electrode of the transistor 200H. The conductive layer 245b functions as a plug connected to the conductive layer 242b.

The semiconductor layer 230 is formed over the insulating layer 292. As illustrated in FIG. 32B, the semiconductor layer 230 has a shape with a high aspect ratio in the cross-sectional view in the channel width direction. Thus, the semiconductor layer 230 can be regarded as having a fin shape. A transistor that includes a semiconductor layer having a fin shape is also referred to as a “fin-type transistor”, a “fin transistor”, or the like.

Specifically, a fin-type transistor has a shape in which a channel formation region in a semiconductor layer includes two regions (two surfaces) extending in the Z direction and a length H described later is larger than a length Lx described later in a cross-sectional view in the channel width direction (the Y direction). The length H is preferably larger than the length Lx in the cross-sectional view in the channel width direction, in which case the channel width per unit area can be increased.

In this specification, the maximum length of the semiconductor layer 230 in the Y direction in the channel formation region is the length Lx, and the maximum length of the semiconductor layer 230 in the direction perpendicular to the formation surface (e.g., the top surface of the insulating layer 292) in the channel formation region is the length H.

Note that the length Lx can also be referred to as the maximum width of the semiconductor layer 230 in the channel formation region. Thus, “length Lx” can be replaced with “width Lx”. The length H can also be referred to as the maximum height of the semiconductor layer 230 in the channel formation region. Thus, “length H” can be replaced with “height H”.

The ratio of the length H to the length Lx is referred to as the aspect ratio of the semiconductor layer 230. The aspect ratio of the semiconductor layer 230 is preferably as high as possible to an extent that the semiconductor layer 230 does not collapse in the fabrication process of the transistor 200H. The aspect ratio of the semiconductor layer 230 is preferably higher than 1 and lower than or equal to 400, further preferably higher than or equal to 2 and lower than or equal to 100, still further preferably higher than or equal to 5 and lower than or equal to 40, yet still further preferably higher than or equal to 10 and lower than or equal to 20. That is, in the channel formation region in the semiconductor layer 230, the height H of the semiconductor layer 230 is preferably larger than at least the length Lx of the semiconductor layer 230. The height H of the semiconductor layer 230 is preferably greater than 1 time and less than or equal to 400 times, further preferably greater than or equal to 2 times and less than or equal to 100 times, still further preferably greater than or equal to 5 times and less than or equal to 40 times, yet still further preferably greater than or equal to 10 times and less than or equal to 20 times the length Lx of the semiconductor layer 230. For example, the height H may be greater than or equal to 2 times and less than or equal to 10 times the length Lx. The length Lx is preferably, for example, greater than or equal to 5 nm and less than or equal to 100 nm, further preferably greater than or equal to 5 nm and less than or equal to 50 nm, still further preferably greater than or equal to 10 nm and less than or equal to 30 nm. The height H is preferably, for example, greater than or equal to 50 nm and less than or equal to 2000 nm, further preferably greater than or equal to 100 nm and less than or equal to 1000 nm. For another example, the height H can be greater than or equal to 50 nm and less than or equal to 100 nm.

As illustrated in FIG. 32B, it is preferable that an angle θ between the side surface of the semiconductor layer 230 and the surface of the insulating layer 292 on which the semiconductor layer 230 is formed be perpendicular or substantially perpendicular in a cross-sectional view in the channel width direction. For example, the angle θ is preferably greater than or equal to 80° and less than or equal to 100°, further preferably greater than or equal to 85° and less than or equal to 95°.

The insulating layer 250, the conductive layer 260, and the conductive layer 242 are provided to cover the semiconductor layer 230 having such an aspect ratio. The insulating layer 250 and the conductive layer 260 are provided in the transistor 200H such that part of each of the insulating layer 250 and the conductive layer 260 is folded in half to sandwich the semiconductor layer 230, as illustrated in FIG. 32B. Thus, in a cross-sectional view in the channel width direction, the semiconductor layer 230 and the conductive layer 260 face each other with the insulating layer 250 therebetween in the upper portion, the side surface on the A1 side, and the side surface on the A2 side of the semiconductor layer 230. That is, the upper portion, the side surface on the A1 side, and the side surface on the A2 side of the semiconductor layer 230 function as a channel formation region. Accordingly, the channel width of the transistor 200H is greater than that of the case where the semiconductor layer 230 has a planar shape by the side surface on the A1 side and the side surface on the A2 side of the semiconductor layer 230.

The transistor 200H having such a large channel width can have a high on-state current, high mutual conductance, excellent frequency characteristics, and the like. Thus, a semiconductor device that operates at high speed can be provided. In the above structure, providing the semiconductor layer 230 enables the channel width to be increased without an increase in the area occupied by the transistor 200H. Accordingly, scaling down or high integration of the semiconductor device can be achieved.

As illustrated in FIG. 32B and the like, the upper portion of the semiconductor layer 230 preferably has a curved shape. Such a curved shape can prevent formation of a defect such as a void in the insulating layer 250 and the conductive layer 242 in the vicinity of the upper portion of the semiconductor layer 230. Although the upper portion of the semiconductor layer 230 has a symmetrical structure with a curved shape on both the A1 side (A3 side) and the A2 side (A4 side) of the upper portion in FIG. 32B and the like, the present invention is not limited thereto. For example, the upper portion of the semiconductor layer 230 can have an asymmetrical structure with a curved shape on either the A1 side (A3 side) or the A2 side (A4 side) of the upper portion.

In the case where an oxide semiconductor is used for the semiconductor layer 230, a structure including semiconductor layers 230a, 230b, and 230c, which is disclosed in Embodiment 3, can be used as illustrated in FIGS. 32A and 32B.

In the case where an oxide semiconductor is used for the semiconductor layer 230, the insulating layer 250 preferably has a stacked-layer structure of an insulating layer 250a in contact with the semiconductor layer 230, an insulating layer 250b over the insulating layer 250a, an insulating layer 250c over the insulating layer 250b, and an insulating layer 250d over the insulating layer 250c, as illustrated in FIGS. 32A and 32B. In that case, the insulating layers 250a and 250c preferably have a function of capturing or fixing hydrogen.

An example of the insulating layer having a function of capturing or fixing hydrogen is a metal oxide having an amorphous structure. As the insulating layers 250a and 250c, for example, a metal oxide such as magnesium oxide or an oxide containing aluminum and/or hafnium is preferably used. In such a metal oxide having an amorphous structure, an oxygen atom has a dangling bond with which hydrogen is captured or fixed in some cases. That is, the metal oxide having an amorphous structure has high capability of capturing or fixing hydrogen.

Moreover, a high-permittivity (high-k) material is preferably used for the insulating layers 250a and 250c. An example of the high-k material is an oxide containing aluminum and/or hafnium. With the use of the high-k material for the insulating layers 250a and 250c, a gate potential applied during operation of the transistor can be reduced while the physical thickness of the gate insulating layer is being maintained. Furthermore, the equivalent oxide thickness (EOT) of the insulating layer functioning as the gate insulating layer can be reduced.

For the insulating layers 250a and 250c, an oxide containing aluminum and/or hafnium is preferably used, and an oxide containing aluminum and/or hafnium and having an amorphous structure is further preferably used.

In this embodiment, aluminum oxide is used as the insulating layer 250a. The aluminum oxide preferably has an amorphous structure. When the insulating layer 250a is provided in contact with the semiconductor layer 230 here, hydrogen contained in the semiconductor layer 230 or the like can be captured and fixed in the insulating layer 250a more effectively. In this embodiment, hafnium oxide is used as the insulating layer 250c. When the insulating layer 250c is provided between the insulating layers 250b and 250d here, hydrogen contained in the insulating layer 250b or the like can be captured and fixed more effectively. An insulating layer having thermal stability, such as silicon oxide or silicon oxynitride, is preferably used as the insulating layer 250b. A silicon oxide film used as the insulating layer 250b is preferably formed by a PEALD method.

In order to inhibit oxidation of the conductive layers 242a, 242b, and 260, a barrier insulating layer against oxygen is preferably provided in the vicinity of each of the conductive layers 242a, 242b, and 260. In the semiconductor device described in this embodiment, the insulating layer corresponds to, for example, the insulating layers 250a, 250d, 250c, and 235.

In this specification and the like, a barrier insulating layer refers to an insulating layer having a barrier property. In this specification and the like, “having a barrier property” means having a property of hindering transmission of a target substance (also referred to as having a low permeability). For example, an insulating layer having a barrier property hardly allows a target substance to diffuse into the insulating layer. For another example, an insulating layer having a barrier property has a function of capturing or fixing (also referred to as gettering) a target substance in the insulating layer.

Examples of a barrier insulating layer against oxygen include an oxide containing aluminum and/or hafnium, magnesium oxide, gallium oxide, silicon nitride, and silicon nitride oxide. Examples of the oxide containing aluminum and/or hafnium include aluminum oxide, hafnium oxide, an oxide containing aluminum and hafnium (hafnium aluminate), and an oxide containing hafnium and silicon (hafnium silicate). For example, each of the insulating layers 250a, 250c, 250d, and 235 preferably has a single-layer structure of the barrier insulating layer against oxygen or a stacked-layer structure of the barrier insulating layers against oxygen.

The insulating layer 250a preferably has a barrier property against oxygen. The insulating layer 250a is preferably less permeable to oxygen than at least the insulating layer 280 is. The insulating layer 250a includes a region in contact with the side surface of the conductive layer 242a and a region in contact with the side surface of the conductive layer 242b. When the insulating layer 250a has a barrier property against oxygen, oxidation of the side surfaces of the conductive layers 242a and 242b and formation of oxide films on the side surfaces can be inhibited. Accordingly, a reduction in on-state current or field-effect mobility of the transistor 200H can be inhibited.

The insulating layer 250a is provided in contact with the top and side surfaces of the semiconductor layer 230 and the top surface of the insulating layer 292. When the insulating layer 250a has a barrier property against oxygen, release of oxygen from the channel formation region in the semiconductor layer 230 caused by heat treatment or the like can be inhibited. This can inhibit formation of oxygen vacancies in the semiconductor layer 230.

By providing the insulating layer 250a, excessive supply of oxygen from the insulating layer 280 to the semiconductor layer 230 can be inhibited and an appropriate amount of oxygen can be supplied to the semiconductor layer 230. Thus, excessive oxidation of the source and drain regions can be inhibited, and a reduction in on-state current or field-effect mobility of the transistor 200H can be inhibited.

An oxide containing aluminum and/or hafnium has a barrier property against oxygen and thus is suitable for the insulating layer 250a.

The insulating layer 250d also preferably has a barrier property against oxygen. The insulating layer 250d is provided between the conductive layer 260 and the channel formation region in the semiconductor layer 230 and between the insulating layer 280 and the conductive layer 260. Such a structure can inhibit oxygen contained in the channel formation region in the semiconductor layer 230 from diffusing into the conductive layer 260 and thus can inhibit formation of oxygen vacancies in the channel formation region in the semiconductor layer 230. Oxygen contained in the semiconductor layer 230 and oxygen contained in the insulating layer 280 can be inhibited from diffusing into the conductive layer 260 and oxidizing the conductive layer 260. The insulating layer 250d is preferably less permeable to oxygen than at least the insulating layer 280 is. For example, a silicon nitride film is preferably used as the insulating layer 250d. In that case, the insulating layer 250d contains at least nitrogen and silicon. The insulating layer 250d preferably has a barrier property against hydrogen. This can prevent diffusion of impurities contained in the conductive layer 260, such as hydrogen, into the semiconductor layer 230.

The insulating layer 235 also preferably has a barrier property against oxygen. The insulating layer 235 is provided between the insulating layer 280 and each of the conductive layers 242a and 242b. The insulating layer 235 is provided in contact with the side surface of the conductive layer 242, the side surface of the semiconductor layer 230, and the top surface of the insulating layer 292. This structure can inhibit diffusion of oxygen contained in the insulating layer 280 into the conductive layer 242. Accordingly, oxidation of the conductive layer 242 by oxygen contained in the insulating layer 280 can be inhibited, so that an increase in resistivity due to the oxidation can be inhibited. The insulating layer 235 is preferably less permeable to oxygen than at least the insulating layer 280 is. For example, silicon nitride is preferably used for the insulating layer 235. In that case, the insulating layer 235 contains at least nitrogen and silicon.

In order to inhibit a reduction in hydrogen concentration in the source and drain regions in the semiconductor layer 230, a barrier insulating layer against hydrogen is preferably provided in the vicinity of each of the source and drain regions. In the semiconductor device described in this embodiment, the barrier insulating layer against hydrogen corresponds to, for example, the insulating layer 235.

Examples of the barrier insulating layer against hydrogen include oxides such as aluminum oxide, hafnium oxide, and tantalum oxide and nitrides such as silicon nitride. For example, the insulating layer 235 preferably has a single-layer structure of the barrier insulating layer against hydrogen or a stacked-layer structure of the barrier insulating layers against hydrogen.

Providing the insulating layer 235 described above can reduce the amount of hydrogen diffusing from the source and drain regions to the outside, so that a reduction in the hydrogen concentration in the source and drain regions can be inhibited. Thus, the source and drain regions can be n-type regions.

With the above structure, the i-type or substantially i-type channel formation region and the n-type source and drain regions can be formed; thus, a semiconductor device with excellent electrical characteristics can be provided. The semiconductor device with the above structure can have excellent electrical characteristics even when being scaled down or highly integrated. Furthermore, scaling down of the transistor 200H can improve the high-frequency characteristics. Specifically, the cutoff frequency can be improved.

The insulating layers 250a to 250d function as part of the gate insulating layer. The insulating layers 250a to 250d are provided together with the conductive layer 260 in the opening formed in the insulating layer 280. The thickness of each of the insulating layers 250a to 250d is preferably small for scaling down of the transistor 200H. The thickness of each of the insulating layers 250a to 250d is preferably greater than or equal to 0.1 nm and less than or equal to 10 nm, further preferably greater than or equal to 0.1 nm and less than or equal to 5.0 nm, still further preferably greater than or equal to 0.5 nm and less than or equal to 5.0 nm, yet further preferably greater than or equal to 1.0 nm and less than or equal to 5.0 nm, yet still further preferably greater than or equal to 1.0 nm and less than or equal to 3.0 nm. Note that each of the insulating layers 250a to 250d at least partly includes a region with the above-described thickness.

The thickness of the silicon oxide film used as the insulating layer 250 is preferably greater than or equal to 0.7 nm and less than or equal to 3 nm.

To reduce the thicknesses of the insulating layers 250a to 250d as described above, an ALD method is preferably used for film formation. Furthermore, to provide the insulating layers 250a to 250d in the opening in the insulating layer 280 and the like, an ALD method is preferably used. By an ALD method, the insulating layer 250 can be formed on the side surface of the first opening formed in the insulating layer 280, a side end portion of the conductive layer 242a, a side end portion of the conductive layer 242b, and the like with good coverage.

Although the case where the insulating layer 250 has a four-layer structure of the insulating layers 250a to 250d is described above, the present invention is not limited to this structure. The insulating layer 250 can have a structure including at least one of the insulating layers 250a to 250d. When the insulating layer 250 is formed of one, two, or three layers of the insulating layers 250a to 250d, the fabrication process of the transistor 200H can be simplified and the productivity of the semiconductor device including the transistor 200H can be improved.

As illustrated in FIG. 31A, the shape of the semiconductor layer 230 in the plan view is preferably an enclosing shape with no endpoints (also referred to as a frame shape, a ring shape, a doughnut shape, or a closed-curve shape). That is, the semiconductor layer 230 preferably includes a plurality of portions extending in the channel width direction (A1-A2 direction) and a plurality of portions extending in the channel length direction (A5-A6 direction). This can inhibit the semiconductor layer 230 formed to have a high aspect ratio from collapsing during the fabrication process of the transistor. Note that the semiconductor layer 230 illustrated in FIG. 31A can also be regarded as having an opening in the center portion. Although the shape of the semiconductor layer 230 in the plan view is a line-symmetrical shape with respect to the line A1-A2 in FIG. 31A, the present invention is not limited thereto. For example, the shape of the semiconductor layer 230 in the plan view may be an asymmetrical shape.

In the structure illustrated in FIG. 31A, two enclosing-shaped semiconductor layers 230 are formed in the Y direction. As illustrated in FIG. 31A, the semiconductor layer 230 preferably overlaps with the conductive layer 260 at two or more points in the plan view. Thus, the conductive layer 260 preferably includes two or more regions overlapping with the semiconductor layer 230. That is, two or more regions where the semiconductor layer 230 and the conductive layer 260 overlap with each other are preferably included.

With such a structure, the plurality of fin-shaped semiconductor layers 230 are formed in a cross-sectional view in the channel width direction as illustrated in FIG. 31B. The plurality of fin-shaped semiconductor layers 230 each include a channel formation region. That is, the transistor 200H functions as a multi-channel transistor. Thus, the channel width can be further increased in the transistor 200H, so that the amount of on-state current can be increased. Accordingly, the operation speed of the semiconductor device including the transistor 200H can be increased.

Although the structure in which the two enclosing-shaped semiconductor layers 230 are provided is described above, the present invention is not limited thereto. For example, one or three or more enclosing-shaped semiconductor layers 230 can be provided. Alternatively, the enclosing-shaped semiconductor layers 230 can be bonded to each other to form the semiconductor layer 230 having a plurality of openings. The semiconductor layer 230 having a lattice shape in the plan view can be used.

### <Structure Example 9 of Transistor>

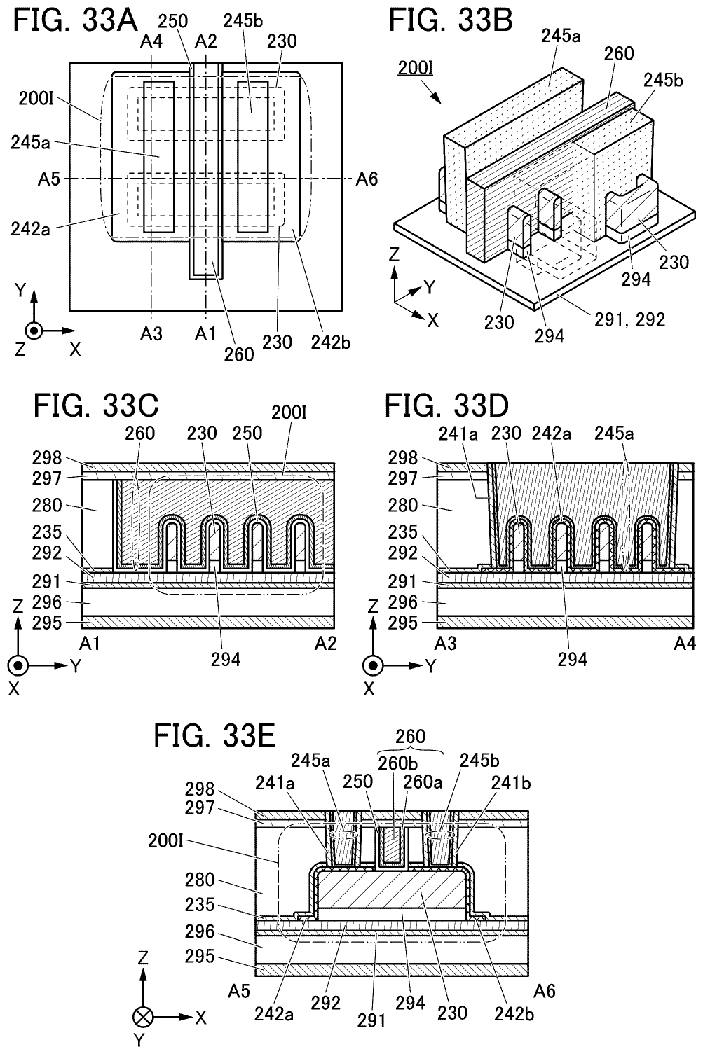

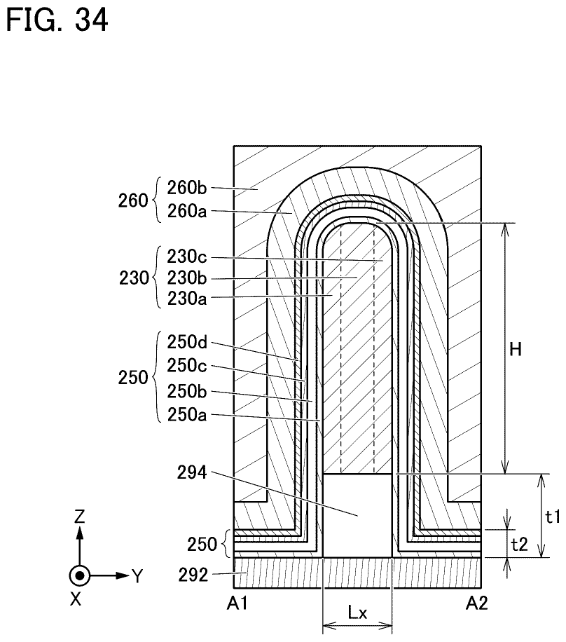

Next, a transistor 200I which is a modification example of the transistor 200H will be described. FIG. 33A is a plan view of the transistor 200I that can be used for the semiconductor device of one embodiment of the present invention. FIG. 33B is a schematic perspective view of the transistor 200I. FIGS. 33C to 33E are cross-sectional views of the transistor 200I. FIG. 33C is a cross-sectional view taken along the dashed-dotted line A1-A2 in FIG. 33A, which corresponds to a cross-sectional view of the transistor 200I in the channel width direction (the Y direction). FIG. 33D is a cross-sectional view taken along the dashed-dotted line A3-A4 in FIG. 33A, which corresponds to a cross-sectional view of the transistor 200I in the channel width direction. FIG. 33E is a cross-sectional view taken along the dashed-dotted line A5-A6 in FIG. 33A, which corresponds to a cross-sectional view of the transistor 200I in the channel length direction (the X direction). The dashed-dotted line A5-A6 is orthogonal to the dashed-dotted line A1-A2 and the dashed-dotted line A3-A4, and the dashed-dotted line A1-A2 is parallel to the dashed-dotted line A3-A4. Note that some components are not illustrated in the plan view of FIG. 33A and the schematic perspective view of FIG. 33B. FIG. 34 is an enlarged view of the semiconductor layer 230 in FIG. 33C.

As illustrated in FIGS. 33B to 33E, an insulating layer 294 can be provided under the semiconductor layer 230. The planar shape (the shape seen from the Z direction) of the insulating layer 294 is similar to that of the semiconductor layer 230. Thus, the insulating layer 294 overlaps with the semiconductor layer 230 in the plan view. The bottom surface of the insulating layer 294 is in contact with the insulating layer 292, the side surface of the insulating layer 294 is in contact with the insulating layer 250 and the conductive layer 242a, and the top surface of the insulating layer 294 is in contact with the bottom surface of the semiconductor layer 230. The insulating layer 294 is formed using an insulating material that can be used for the insulating layer 250b. For example, silicon oxide can be used for the insulating layer 294.

Note that FIGS. 33A to 33E correspond to FIGS. 31A to 31E. FIG. 34 corresponds to FIG. 32B. Thus, the structures that are illustrated in FIGS. 33A to 33E and FIG. 34 and are not described below can be understood with reference to the above description relating to FIGS. 31A to 31E and FIG. 32B, for example.

Here, as illustrated in FIG. 34, a thickness t2 of the insulating layer 250 at the bottom portion of the first opening is preferably smaller than a thickness t1 of the insulating layer 294 (the length of the insulating layer 294 in the direction perpendicular to the surface on which the insulating layer 294 is formed). With such a structure, the level of the bottom surface of the conductive layer 260 (the conductive layer 260a) positioned in the first opening can be lower than the level of the bottom surface of the semiconductor layer 230 by a difference between the thickness t1 and the thickness t2 (t1−t2).

When the level of the bottom surface of the conductive layer 260 is lower than the level of the bottom surface of the semiconductor layer 230, a gate electric field can be adequately applied to the semiconductor layer 230 from its upper end portion to its lower end portion. In other words, in the opening in the insulating layer 280 and the like, the semiconductor layer 230 can be wholly electrically surrounded by an electric field of the conductive layer 260 to function as a channel formation region. Such a structure can prevent the lower end portion of the semiconductor layer 230 from functioning as a parasitic channel, thereby reducing leakage current between the source electrode and the drain electrode. In addition, poor characteristics of the transistor due to the parasitic channel, such as normally-on characteristics, can be inhibited. That is, the transistor 200I can have excellent electrical characteristics.

When a region from the upper end portion to the lower end portion of the semiconductor layer 230 functions as a channel formation region as described above, the channel width can be increased. Thus, the transistor 200I can have a high on-state current, high mutual conductance, excellent frequency characteristics, and the like.

In this specification and the like, a transistor structure in which a channel formation region is electrically surrounded by an electric field of a gate electrode as in the above structure is referred to as a surrounded channel (S-channel) structure. In the S-channel structure, a gate electrode is provided to cover at least two surfaces (specifically, two surfaces, three surfaces, four surfaces, or the like) of a channel. With the use of the S-channel structure, a transistor with high resistance to a short-channel effect, i.e., a transistor in which a short-channel effect is unlikely to occur, can be obtained.

Since the S-channel structure is a structure in which the channel formation region is electrically surrounded, the S-channel structure is, in a sense, equivalent to a gate all around (GAA) structure or a lateral gate all around (LGAA) structure. In the transistor 200I having any of the S-channel structure, the GAA structure, and the LGAA structure, the channel formation region formed at the interface between the semiconductor layer 230 and the insulating layer 250 functioning as the gate insulating layer or in the vicinity of the interface can correspond to the entire bulk in the semiconductor layer 230. Consequently, the density of current flowing through the transistor can be improved, so that the on-state current or the field-effect mobility of the transistor can be increased. In one embodiment of the present invention, the semiconductor layer 230 has a CAAC structure and a fin-shaped structure. With such structures, the source-drain current path in the transistor and the a-b plane of the crystal axis can be parallel to each other. In other words, an oxide semiconductor having the CAAC structure and the fin-shaped structure seems to have a conduction path equivalent to that of a two-dimensional semiconductor material. Furthermore, with the use of such an oxide semiconductor, a device having two-dimensional conduction can be formed.

### <Structure Example 10 of Transistor>

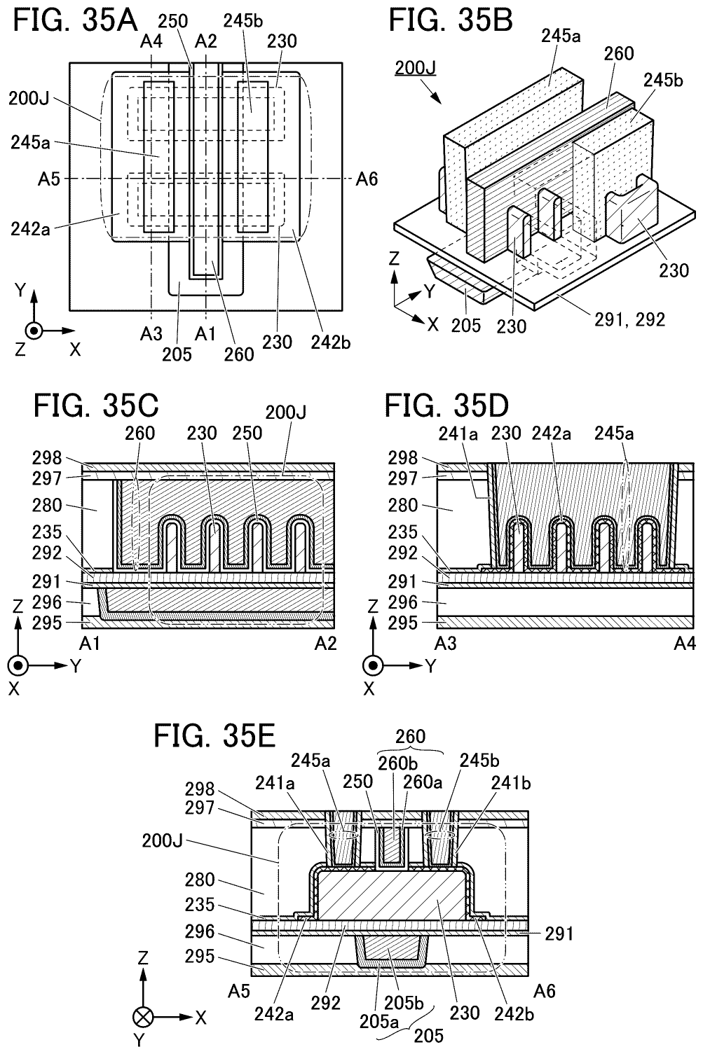

FIGS. 35A to 35E illustrate a transistor 200J, which is a modification example of the transistor 200H. The transistor 200J is different from the transistor 200H in that the conductive layer 205 is provided under the insulating layer 291. Note that FIGS. 35A to 35E correspond to FIGS. 31A to 31E. The structures that are illustrated in FIGS. 35A to 35E and are not described below can be understood with reference to the above description relating to FIGS. 31A to 31E, for example.

The conductive layer 205 includes a region overlapping with the channel formation region in the semiconductor layer 230. Thus, like the conductive layer 260, the conductive layer 205 includes a region functioning as a gate electrode. The conductive layer 260 may be referred to as a first gate electrode (an upper gate electrode) of the transistor 200J, and the conductive layer 205 may be referred to as a second gate electrode (a lower gate electrode) of the transistor 200J. In the case where the conductive layer 260 is referred to as a gate electrode of the transistor 200J, the conductive layer 205 is sometimes referred to as a back gate electrode of the transistor 200J.

In the case where the conductive layer 205 is provided under the insulating layer 291 as in the transistor 200J, each of the insulating layers 292 and 291 includes a region functioning as a gate insulating layer like the insulating layer 250. Specifically, a region of the insulating layer 292 that overlaps with the conductive layer 205 and a region of the insulating layer 291 that overlaps with the conductive layer 205 function as a gate insulating layer. The insulating layer 250 may be referred to as a first gate insulating layer (an upper gate insulating layer), and the insulating layers 292 and 291 may be referred to as a second gate insulating layer (a lower gate insulating layer).

In the transistor 200J, the conductive layer 205 is placed to overlap with the semiconductor layer 230 and the conductive layer 260. In FIGS. 35C and 35E, the conductive layer 205 is provided in a fourth opening that penetrates the insulating layer 296 and reaches the insulating layer 295. In the plan view, the fourth opening includes a region overlapping with the semiconductor layer 230 and a region extending along the Y direction beyond the end portion of the semiconductor layer 230. Thus, the conductive layer 205 provided in the fourth opening also includes, in the plan view, a region overlapping with the semiconductor layer 230 and a region extending along the Y direction beyond the end portion of the semiconductor layer 230. The conductive layer 205 also functions as a wiring.

As illustrated in FIGS. 35C and 35E, the conductive layer 205 preferably includes a conductive layer 205a and a conductive layer 205b. The conductive layer 205a is provided in contact with the bottom portion and the sidewall of the fourth opening. The conductive layer 205b is provided to fill a depressed portion of the conductive layer 205a formed along the bottom portion and the sidewall of the fourth opening. Here, it is preferable that the top surface of the conductive layer 205 be level or substantially level with the top surface of the insulating layer 296. That is, when seen from the Y direction, it is preferable that the shortest distance from the top surface of the substrate (not illustrated) to the top surface of the insulating layer 296 be equal or substantially equal to the shortest distance from the top surface of the substrate to the top surface of the conductive layer 205.

Note that the conductive layer 205a preferably contains a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, the conductive layer 205a preferably contains a conductive material having a function of inhibiting diffusion of oxygen.

When the conductive layer 205a is formed using a conductive material having a function of inhibiting diffusion of hydrogen, impurities such as hydrogen contained in the conductive layer 205b can be prevented from diffusing into the semiconductor layer 230 through the insulating layer 296 and the like. When the conductive layer 205a is formed using a conductive material having a function of inhibiting diffusion of oxygen, the conductivity of the conductive layer 205b can be inhibited from being lowered because of oxidation. Examples of the conductive material having a function of inhibiting diffusion of oxygen include titanium, titanium nitride, tantalum, tantalum nitride, ruthenium, and ruthenium oxide. The conductive layer 205a can have a single-layer structure or a stacked-layer structure of the above-described conductive materials. For example, the conductive layer 205a preferably contains titanium nitride.

The conductive layer 205b is preferably formed using a conductive material containing tungsten, copper, or aluminum as its main component. For example, the conductive layer 205b preferably contains tungsten.

As described above, the conductive layer 205 can function as a second gate electrode. In that case, by changing a potential applied to the conductive layer 205 independently of a potential applied to the conductive layer 260, the threshold voltage (Vth) of the transistor 200J can be controlled. Specifically, when a negative potential is applied to the conductive layer 205, the Vth of the transistor 200J can be further increased and the off-state current can be reduced. Thus, a drain current at the time when the potential applied to the conductive layer 260 is 0 V can be lower in the case where a negative potential is applied to the conductive layer 205 than in the case where the negative potential is not applied to the conductive layer 205.

The electrical resistivity of the conductive layer 205 is designed in consideration of the potential applied to the conductive layer 205, and the thickness of the conductive layer 205 is determined in accordance with the electrical resistivity. The thickness of the insulating layer 296 is substantially equal to that of the conductive layer 205. The conductive layer 205 and the insulating layer 296 are preferably as thin as possible in the allowable range of the design of the conductive layer 205. The insulating layer 296 with a reduced thickness contains a smaller absolute amount of impurities such as hydrogen, inhibiting diffusion of the impurities into the semiconductor layer 230.

Although the stacked-layer structure of the conductive layers 205a and 205b is described above, the present invention is not limited to this structure. The conductive layer 205 may have a single-layer structure or a stacked-layer structure of three or more layers. For example, in the case where the conductive layer 205 has a three-layer structure, a conductive layer that contains a material similar to that of the conductive layer 205a can be further provided over the conductive layer 205b of the above-described stacked-layer structure of the conductive layers 205a and 205b. In that case, the level of the top surface of the conductive layer 205b is lower than that of an uppermost portion of the conductive layer 205a, and the conductive layer can be formed to fill the depressed portion formed by the conductive layers 205a and 205b.

As materials used for the conductive layers 205, 242, 245, and 260, any of materials of conductive layers described in the other embodiments can be used in addition to the materials disclosed in this embodiment. As materials used for the insulating layers 295, 296, 291, 292, 241, 250, 235, 280, 297, and 298, any of materials of insulating layers described in the other embodiments can be used in addition to the materials disclosed in this embodiment.

The transistor 200J described in this embodiment can be used as any of the transistors included in the semiconductor device 10. The transistor 200J can have a high on-state current without an increase in the area occupied by the transistor 200J.

### <Constituent Materials for Transistor>

Next, constituent materials that can be used for the transistor 200 (the transistors 200A, 200B, 200C, 200D, 200E, 200F, 200G, 200H, 200I, and 200J) will be described.

### [Substrate]

In the case where the transistor is provided over a substrate, there is no particular limitation on a material used for the substrate. The material used for the substrate is determined in accordance with the purpose considering whether it has a light-transmitting property, heat resistance high enough to withstand heat treatment, and the like. As the substrate, an insulator substrate, a semiconductor substrate, or a conductor substrate can be used, for example. As the insulator substrate, a glass substrate of barium borosilicate glass, aluminoborosilicate glass, or the like, a ceramic substrate, a quartz substrate, a sapphire substrate, or a stabilized zirconia substrate (e.g., an yttria-stabilized zirconia substrate) can be used, for example. Alternatively, as the substrate, a semiconductor substrate, a flexible substrate, a resin substrate, or the like can be used.

Examples of the semiconductor substrate include a semiconductor substrate containing a material such as silicon or germanium and a compound semiconductor substrate containing a material such as silicon carbide, silicon germanium, gallium arsenide, indium phosphide, zinc oxide, or gallium oxide. Other examples include the above semiconductor substrates provided with an insulator region, such as a silicon on insulator (SOI) substrate. The semiconductor substrate may be a single crystal semiconductor or a polycrystalline semiconductor.

Examples of the conductor substrate include a graphite substrate, a metal substrate, an alloy substrate, and a conductive resin substrate. Other examples include a substrate including a nitride of a metal and a substrate including an oxide of a metal. Other examples include an insulator substrate provided with a conductive layer or a semiconductor layer, a semiconductor substrate provided with a conductive layer or an insulating layer, and a conductor substrate provided with a semiconductor layer or an insulating layer.

For the material of the flexible substrate, the resin substrate, or the like, polyester such as polyethylene terephthalate (PET) or polyethylene naphthalate (PEN), polyacrylonitrile, an acrylic resin, polyimide, polymethyl methacrylate, polycarbonate (PC), polyethersulfone (PES), polyamide (e.g., nylon or aramid), polysiloxane, a cycloolefin resin, polystyrene, polyamide-imide, polyurethane, polyvinyl chloride, polyvinylidene chloride, polypropylene, polytetrafluoroethylene (PTFE), an ABS resin, or cellulose nanofiber can be used, for example.

With the use of any of the materials described above for the substrate, a lightweight semiconductor device can be provided. Furthermore, with the use of any of the materials described above for the substrate, a shock-resistant semiconductor device can be provided.

Furthermore, with the use of any of the materials described above for the substrate, a semiconductor device that is less likely to be broken can be provided. Alternatively, these substrates provided with elements can be used. Examples of the element provided over the substrate include a capacitor, a resistor, a switching element, a light-emitting element, and a memory element.

### [Insulating Layer]

An inorganic insulating film is used as each of the insulating layers (e.g., the insulating layers 202, 204, 206, 209, 295, 296, 291, 292, 294, 241, 257, 250, 258, 258a, 258b, 259, 264, 266, 268, 516, 235, 280, 297, 298, 522, 524, 541, 554, 580, 574, and 581). Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film. An organic insulating film can also be used as the insulating layer included in the semiconductor device.

Note that in this specification and the like, an oxynitride refers to a material in which the oxygen content is higher than the nitrogen content, and a nitride oxide refers to a material in which the nitrogen content is higher than the oxygen content. For example, silicon oxynitride refers to a material in which the oxygen content is higher than the nitrogen content, and silicon nitride oxide refers to a material in which the nitrogen content is higher than the oxygen content.

As scaling down and high integration of transistors progress, for example, a problem such as generation of leakage current may arise because of a thinner gate insulating layer. When a high-k material is used for the insulating layer functioning as a gate insulating layer, such as the insulating layer 204 or the insulating layer 264, the voltage at the time of operation of the transistor can be reduced while the physical thickness is being maintained. In addition, the equivalent oxide thickness (EOT) of the gate insulating layer can be reduced. By contrast, when a material with a low dielectric constant is used for the insulating layer functioning as an interlayer film, parasitic capacitance generated between wirings can be reduced. Thus, it is important to select a material depending on the function of an insulating layer. Note that a material with a low dielectric constant is a material with high dielectric strength.

Examples of a material with a high dielectric constant (a high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with a low dielectric constant include inorganic insulating materials such as silicon oxide, silicon oxynitride, and silicon nitride oxide, and resins such as polyester, polyolefin, polyamide (e.g., nylon and aramid), polyimide, polycarbonate, and an acrylic resin. Other examples of an inorganic insulating material with a low dielectric constant include silicon oxide to which fluorine is added, silicon oxide to which carbon is added, and silicon oxide to which carbon and nitrogen are added. Another example is porous silicon oxide. Note that these silicon oxides may contain nitrogen.

### [Conductive Layer]

For each of the conductive layers (e.g., the conductive layers 205, 208, 219, 242, 245, 255, 260, 267, 261, 265, 505, 545, and 560) included in the transistor 200, it is preferable to use a metal element selected from aluminum, chromium, copper, silver, gold, platinum, zinc, tantalum, nickel, titanium, iron, cobalt, molybdenum, tungsten, hafnium, vanadium, niobium, manganese, magnesium, zirconium, beryllium, indium, ruthenium, iridium, strontium, lanthanum, and the like; an alloy containing any of the above metal elements as a component; an alloy containing a combination of the above metal elements; or the like. As an alloy containing any of the above metal elements as a component, a nitride of the alloy or an oxide of the alloy can be used. For example, tantalum nitride, titanium nitride, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. Alternatively, a semiconductor having high electric conductivity, typified by polycrystalline silicon containing an impurity element such as phosphorus, or silicide such as nickel silicide can also be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting diffusion of oxygen, or a material maintaining its conductivity even after absorbing oxygen. Examples of the conductive material containing oxygen include indium oxide containing tungsten oxide, indium oxide containing titanium oxide, indium tin oxide (also referred to as ITO), indium tin oxide containing titanium oxide, indium tin oxide to which silicon is added (also referred to as ITSO), indium zinc oxide (also referred to as IZO (registered trademark)), and indium zinc oxide containing tungsten oxide. In this specification and the like, a conductive layer formed using the conductive material containing oxygen may be referred to as an oxide conductive layer.

A conductive material containing tungsten, copper, or aluminum as its main component is preferable because it has high conductivity.

Conductive layers formed using any of the above materials can be stacked. For example, a stacked-layer structure combining a material containing any of the above metal elements and a conductive material containing oxygen can be employed. Alternatively, a stacked-layer structure combining a material containing any of the above metal elements and a conductive material containing nitrogen can be employed. Further alternatively, a stacked-layer structure combining a material containing any of the above metal elements, a conductive material containing oxygen, and a conductive material containing nitrogen can be employed.

For example, in the case where the semiconductor layer 203 of the transistor 200A or 200B is formed using an oxide semiconductor, which is a kind of metal oxide, the conductive layers functioning as the gate electrodes such as the conductive layers 205 and 219 each preferably have a stacked-layer structure combining a material containing any of the above metal elements and a conductive material containing oxygen. In that case, the conductive material containing oxygen is preferably provided on the semiconductor layer 203 side. By providing the conductive material containing oxygen on the semiconductor layer 203 side, oxygen released from the conductive material is easily supplied to the channel formation region in the semiconductor layer 203.

In the case where the semiconductor layers 203, 263, and 520 are formed using an oxide semiconductor, which is a kind of metal oxide, the conductive layers 208a, 208b, 255, 261, 542a, and 542b, which are in contact with the semiconductor layers 203, 263, and 520, are preferably formed using a conductive material that is not easily oxidized, a conductive material that maintains its low electrical resistance even after being oxidized, a metal oxide that has conductivity (also referred to as an oxide conductor), or a conductive material that has a function of inhibiting diffusion of oxygen. Examples of the conductive materials include a conductive material containing nitrogen and a conductive material containing oxygen. This can inhibit a decrease in the conductivity of the conductive layers 208a, 208b, 255, 261, 542a, and 542b.

The conductive layers 208a, 208b, 255, 261, 542a, and 542b formed using a conductive material containing oxygen can maintain their conductivity even after absorbing oxygen. This is preferable because the conductive layers 208a, 208b, 255, 261, 542a, and 542b can maintain their conductivity even in the case where they are in contact with an insulating layer containing excess oxygen, for example. The conductive layers 208a, 208b, 255, 261, 542a, and 542b can be formed using ITO, ITSO, IZO (registered trademark), or the like, for example.

### [Semiconductor Layer]

For each of the semiconductor layers (e.g., the semiconductor layers 203, 230, 263, and 520), a single crystal semiconductor, a polycrystalline semiconductor, a microcrystalline semiconductor, an amorphous semiconductor, or the like can be used alone or in combination. As a semiconductor material, silicon and germanium can be used, for example. Alternatively, a compound semiconductor such as silicon germanium, silicon carbide, gallium arsenide, or a nitride semiconductor can be used. As the compound semiconductor, an organic substance having semiconductor characteristics or a metal oxide having semiconductor characteristics (also referred to as an oxide semiconductor) can be used. These semiconductor materials can contain an impurity as a dopant.

Note that a single-element semiconductor or a compound semiconductor can be used for the semiconductor layers. Examples of the single-element semiconductor include silicon and germanium. Examples of the compound semiconductor include gallium arsenide and silicon germanium. Other examples of the compound semiconductor include an organic semiconductor and a nitride semiconductor. Note that an oxide semiconductor is also a kind of compound semiconductor. These semiconductor materials can contain an impurity as a dopant.

In the case where silicon is used for the semiconductor layers, examples of silicon that can be used for the semiconductor layers include single crystal silicon, polycrystalline silicon, microcrystalline silicon, and amorphous silicon. An example of polycrystalline silicon is low-temperature polysilicon (LTPS).

When silicon is used for the semiconductor layer 203 and phosphorus or arsenic is included as an n-type dopant in the regions 203a and 203c of the semiconductor layer 203 in the transistor 200A or 200B, for example, the transistor can function as an n-channel transistor. When boron is included as a p-type dopant in the regions 203a and 203c of the semiconductor layer 203, the transistor can function as a p-channel transistor. Note that in the case where both an n-type dopant and a p-type dopant are included in the regions 203a and 203c of the semiconductor layer 203, the conductivity type of the dopant having a higher concentration is likely to be exhibited.

For the semiconductor layers of the transistor, a two-dimensional material functioning as a semiconductor can also be used. The two-dimensional material is also referred to as a layered material, and generally refers to a group of materials having a layered crystal structure. In the layered crystal structure, layers formed by covalent bonding or ionic bonding are stacked with bonding such as the van der Waals bonding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for the semiconductor layers, the transistor can have a high on-state current.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide that can be used for the semiconductor layers of the transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

In the case where an oxide semiconductor, which is a kind of metal oxide, is used for the semiconductor layers, the band gap of the metal oxide is preferably greater than or equal to 2.0 eV, further preferably greater than or equal to 2.5 eV. The use of such a metal oxide having a wide band gap for the semiconductor layers can significantly reduce the amount of off-state current of the transistor. The off-state current of an OS transistor is low, so that power consumption of the semiconductor device can be reduced. Note that an oxide semiconductor will be described in detail in Embodiment 3.

The structure described in this embodiment can be used in appropriate combination with any of the structures described in the other embodiments and example.

### Embodiment 3

In this embodiment, an oxide semiconductor layer that can be used as a semiconductor layer of a transistor will be described.

### [Oxide Semiconductor Layer]

An oxide semiconductor layer used as a semiconductor layer of a transistor preferably includes a metal oxide having crystallinity. Examples of the structure of a metal oxide having crystallinity include a c-axis aligned crystalline (CAAC) structure, a polycrystalline structure, and a nano-crystalline (nc) structure. By using a metal oxide having crystallinity for the oxide semiconductor layer, the density of defect states in the oxide semiconductor layer can be reduced. Thus, the reliability of a transistor including the oxide semiconductor layer can be increased, and the reliability of a memory device including the transistor can be increased.

It is particularly preferable that the oxide semiconductor layer used as the semiconductor layer of the transistor include a metal oxide having a CAAC structure. The CAAC structure is a crystal structure in which a plurality of microcrystals (typically, a plurality of microcrystals each having a hexagonal crystal structure) have c-axis alignment and are connected on the a-b plane without alignment. In cross-sectional observation of an oxide semiconductor layer having the CAAC structure with use of a high-resolution transmission electron microscope (TEM) image, metal atoms are observed to be arranged in a layered manner in a crystal part. Thus, the oxide semiconductor layer having the CAAC structure can also be referred to as a structure including the layered crystal parts.

The crystallinity of the oxide semiconductor layer can be analyzed by X-ray diffraction (XRD), TEM, or electron diffraction (ED), for example. Alternatively, two or more of these methods may be combined for the analysis.

Note that there is no particular limitation on the crystallinity of a semiconductor material included in the oxide semiconductor layer. The oxide semiconductor layer sometimes includes, for example, at least one of an amorphous semiconductor (a semiconductor having an amorphous structure), a single crystal semiconductor (a semiconductor having a single crystal structure), and a semiconductor having crystallinity other than single crystal (a microcrystalline semiconductor, a polycrystalline semiconductor, or a semiconductor partly including crystal regions). The oxide semiconductor layer having crystallinity can inhibit deterioration of the transistor characteristics in some cases.

Examples of the metal oxide used for the oxide semiconductor layer include indium oxide (InOₓ, x is a given number), gallium oxide (GaOₓ, x is a given number), and zinc oxide (ZnOₓ, x is a given number). The metal oxide of one embodiment of the present invention preferably contains at least indium (In) or zinc (Zn). The metal oxide preferably contains two or three selected from indium, the element M, and zinc. The element M is a metal element or a metalloid element that has a high binding energy with oxygen and is, for example, a metal element or a metalloid element whose binding energy with oxygen is higher than that of indium. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably one or more of the above elements, further preferably one or more selected from aluminum, gallium, tin, and yttrium, and still further preferably gallium. When the element M included in the metal oxide is gallium, the metal oxide of one embodiment of the present invention preferably includes one or more selected from indium, gallium, and zinc. In this specification and the like, a metal element and a metalloid element may be collectively referred to as a “metal element”, and a “metal element” in this specification and the like may refer to a metalloid element.

As the metal oxide of one embodiment of the present invention, for example, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide, also referred to as IGTO), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (also referred to as In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), or indium gallium aluminum zinc oxide (In—Ga—Al—Zn oxide, also referred to as IGAZO or IAGZO) can be used. Alternatively, indium tin oxide containing silicon (also referred to as ITSO), gallium tin oxide (Ga—Sn oxide), aluminum tin oxide (Al—Sn oxide), or the like can be used.

By increasing the proportion of the number of indium atoms in the total number of atoms of all the metal elements included in the metal oxide, a high on-state current and excellent frequency characteristics of the transistor can be achieved. Also in the case where indium oxide is used as the metal oxide, the transistor can have a high on-state current and excellent frequency characteristics.

Instead of indium, the metal oxide can contain one or more of metal elements whose period number in the periodic table is large. Alternatively, in addition to indium, the metal oxide can contain one or more of metal elements whose period number in the periodic table is large. The larger the overlap between orbits of metal elements is, the more likely it is that the metal oxide will have high carrier conductivity. Thus, when a metal element with a large period number in the periodic table is contained in the metal oxide, the field-effect mobility of the transistor can be increased in some cases. Examples of the metal element with a large period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide can contain one or more selected from nonmetallic elements. A transistor including the metal oxide including a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor is suppressed and the transistor can have high reliability.

By increasing the proportion of the number of element M atoms in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor is suppressed and the transistor can have high reliability.

In the description of this embodiment, In—Ga—Zn oxide is sometimes taken as an example of the metal oxide.

The oxide semiconductor layer used as the semiconductor layer of the transistor preferably has crystallinity. It is particularly preferable that the oxide semiconductor layer used as the semiconductor layer of the transistor have the CAAC structure.

The oxide semiconductor layer can be formed by forming a metal oxide using at least two kinds of film formation methods. For example, the oxide semiconductor layer can be formed by forming a metal oxide using a first film formation method and a second film formation method. Note that the oxide semiconductor layer formed by using at least two kinds of film formation methods may be referred to as a hybrid OS.

The oxide semiconductor layer can be formed in the following manner: a metal oxide is formed as a first layer by a first film formation method, and then a metal oxide is formed as a second layer over the first layer by a second film formation method. In that case, as the first film formation method, a film formation method that causes less damage to the formation surface than the second film formation method is preferably used. When a film formation method that causes less damage to the formation surface is used as the first film formation method, formation of a mixed layer at an interface between the oxide semiconductor layer and a layer serving as the formation surface of the oxide semiconductor layer can be inhibited. Moreover, entry of impurities such as silicon into the second layer can be inhibited, so that the crystallinity of the oxide semiconductor layer can be increased.

Examples of the first film formation method include an atomic layer deposition (ALD) method, a chemical vapor deposition (CVD) method, a molecular beam epitaxy (MBE) method, and a wet process. Examples of the CVD method include a plasma enhanced CVD (PECVD) method, a thermal CVD method, a photo CVD method, and a metal organic CVD (MOCVD) method. Examples of the wet process include a spray coating method. An ALD method and a CVD method are suitable as the first film formation method because they cause less damage to the formation surface than a sputtering method described later.

Examples of the ALD method include a thermal ALD method, in which a precursor and a reactant react with each other only by thermal energy, and a plasma-enhanced ALD (PEALD) method, in which a reactant excited by plasma is used.

An ALD method enables atomic layers to be deposited one by one, and has advantages such as formation of an extremely thin film, formation of a film on a component with a high aspect ratio, formation of a film on a surface with a large step, formation of a film with few defects such as pinholes, formation of a film with excellent coverage, and low-temperature film formation. In a PEALD method, the use of plasma is sometimes preferable for lower-temperature film formation. Note that some precursors used in an ALD method contain an element such as carbon or chlorine. Thus, a film formed by the ALD method sometimes includes an element such as carbon or chlorine in a larger quantity than a film formed by another film formation method. Note that these elements can be quantified by X-ray photoelectron spectroscopy (XPS) or secondary ion mass spectrometry (SIMS). The film formation method of the metal oxide of one embodiment of the present invention, which employs an ALD method and one or both of a film formation condition with a high substrate temperature and impurity removal treatment, might form a film with smaller amounts of carbon and chlorine than a method employing an ALD method and neither the condition nor the treatment.

Unlike in a film formation method in which particles ejected from a target or the like are deposited, a film is formed by reaction at a surface of an object to be processed in an ALD method. Thus, an ALD method can provide good step coverage, almost regardless of the shape of an object to be processed. In particular, an ALD method allows excellent step coverage and excellent thickness uniformity and can be suitably used to cover a surface of an opening portion with a high aspect ratio, for example.

A high-quality film can be obtained at a relatively low temperature through a plasma CVD method. A thermal CVD method does not use plasma and thus causes less plasma damage to an object to be processed. A thermal CVD method does not cause plasma damage during film formation, so that a film with few defects can be obtained.

Examples of the second film formation method include a sputtering method and a pulsed laser deposition (PLD) method. The metal oxide formed by the second film formation method is likely to have the CAAC structure.

Note that as the first layer, for example, a metal oxide with a microcrystalline structure or an amorphous structure that has lower crystallinity than the CAAC structure is sometimes formed. Formation of the second layer having high crystallinity over the first layer having low crystallinity or formation of the first and second layers followed by heat treatment can increase the crystallinity of the first layer using the second layer as a nucleus. Accordingly, the crystallinity can be increased in the whole oxide semiconductor layer including the vicinity of the interface with the formation surface.

Furthermore, a third layer can be formed over the second layer. Since the second layer has high crystallinity, the crystal growth of the third layer can be achieved with the use of the crystal of the second layer as a nucleus or a seed. Thus, the third layer can be crystallized even when a film formation method that easily gives crystallinity is not used as the film formation method of the third layer. Here, for example, when a film formation method that gives higher coverage than that of the second layer is employed for formation of the third layer, the whole oxide semiconductor layer can have both high crystallinity and high coverage.

For example, the oxide semiconductor layer used as the semiconductor layer of the transistor can be formed in the following manner: a metal oxide is formed as the first layer by the first film formation method, a metal oxide is formed as the second layer by the second film formation method, and a metal oxide is formed as the third layer by the first film formation method. Specifically, an ALD method can be used as the first film formation method, and a sputtering method can be used as the second film formation method. An ALD method is a film formation method that achieves higher coverage than a sputtering method, and when an ALD method is used as the film formation method of the first layer and the third layer, the coverage with the oxide semiconductor layer can be improved. Thus, the oxide semiconductor layer can suitably cover a step, an opening portion, or the like with a high aspect ratio.

### [Formation Method of Oxide Semiconductor Layer]

The semiconductor layer 230 that is an oxide semiconductor layer can be formed in the following manner, for example: a semiconductor layer 230a is formed by an ALD method over a layer 229 serving as the formation surface, a semiconductor layer 230b that is an oxide semiconductor layer is formed by a sputtering method over the semiconductor layer 230a that is the oxide semiconductor layer, and a semiconductor layer 230c that is an oxide semiconductor layer is formed by an ALD method over the semiconductor layer 230b. Furthermore, heat treatment is preferably performed after the formation of the semiconductor layer 230 that is the oxide semiconductor layer. By performing the heat treatment, the crystallinity of the semiconductor layer 230 can be increased. The heat treatment here is not limited to treatment with application of heat. For example, heat applied during the formation process may be regarded as the heat treatment.

The layer 229 corresponds to the insulating layer 202, the insulating layer 256, the insulating layer 258, or the like described in the above embodiment. The layer 229 does not need to have crystallinity. In the case where the layer 229 has crystallinity, the layer 229 may have a crystal structure with low lattice matching with the metal oxide included in the semiconductor layer 230.

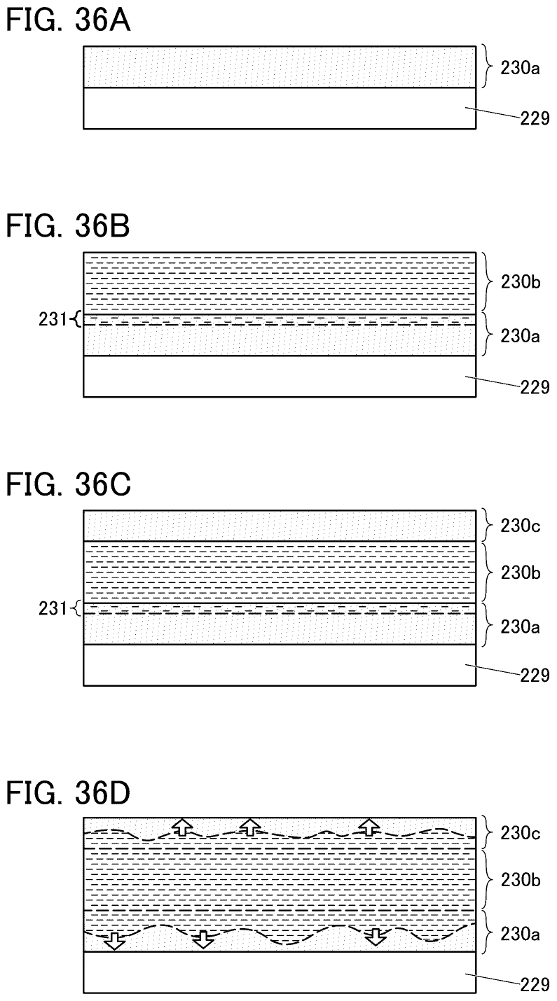

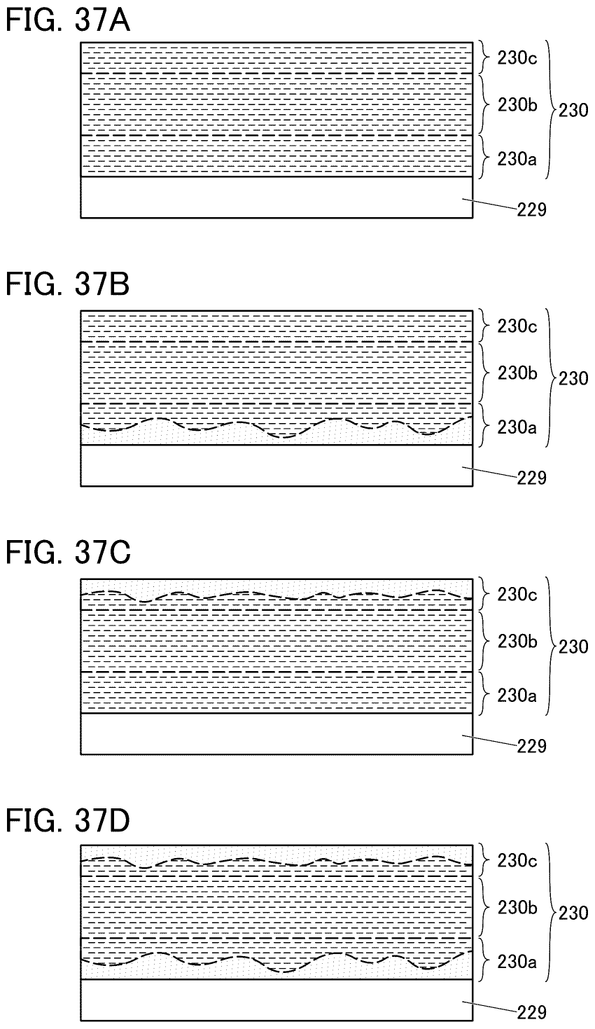

An example of a method for forming the semiconductor layer 230 is described with reference to FIGS. 36A to 36D and FIGS. 37A to 37D.

In the case where a metal oxide film is formed by a sputtering method, damage to the formation surface due to, for example, sputtered particles or energy applied to the substrate side by sputtered particles or the like might cause alloying of a component included in the metal oxide film with a component included in the layer serving as the formation surface. In the case where the alloying occurs, it is difficult to increase the crystallinity of the alloyed region even when heat treatment described later is performed. When an oxide semiconductor layer including the alloyed region is used for a transistor, the initial characteristics or reliability of the transistor might be adversely affected. Therefore, it is preferable to inhibit the alloying of the component included in the metal oxide film with the component included in the layer serving as the formation surface. Thus, first, the semiconductor layer 230a is formed over the layer 229 by an ALD method (FIG. 36A). Next, the semiconductor layer 230b is formed over the semiconductor layer 230a by a sputtering method (FIG. 36B).

In the formation method of the oxide semiconductor layer described above, the semiconductor layer 230a is formed between the semiconductor layer 230b and the layer 229 by a film formation method that causes less damage to the formation surface; thus, the alloying of the component included in the semiconductor layer 230 with the component included in the layer 229 can be inhibited, and the crystallinity of the semiconductor layer 230 can be further increased.

With the above structure, the thickness of the alloyed region can be reduced or reduced to have a thickness that is small enough to make the alloyed region difficult to observe. For example, the thickness of the alloyed region can be greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm. Note that FIGS. 36A and 36B illustrate an example in which the alloyed region is not formed between the layer 229 and the semiconductor layer 230a.

Note that the thickness of the alloyed region can sometimes be calculated by performing SIMS analysis or energy dispersive X-ray spectroscopy (EDX) composition line analysis on the region and its vicinity.

For example, EDX line analysis is performed on the region and its vicinity with the direction perpendicular to the formation surface of the semiconductor layer 230a regarded as the depth direction. Next, in profiles of quantitative values of elements in the depth direction obtained by the analysis, the depth at which the quantitative value of a metal that is the main component of the semiconductor layer 230a and is not the main component of the layer (here, the layer 229) serving as the formation surface (the metal is In when the semiconductor layer 230a includes In) becomes half is defined as the depth (position) of the interface between the region and the semiconductor layer 230a. The depth at which the quantitative value of an element (e.g., Si) that is the main component of the layer serving as the formation surface and that is not the main component of the semiconductor layer 230a becomes half is defined as the depth (position) of the interface between the region and the layer serving as the formation surface. In the above manner, the thickness of the alloyed region can be calculated.

When the thickness of the alloyed region in the oxide semiconductor layer is observed by EDX analysis, the thickness is greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm, for example.

For example, in the case where SIMS analysis of the semiconductor layer 230 formed over the layer 229 that is formed using a silicon oxide layer is performed, the depth at which the silicon concentration is 50% of the maximum value of the silicon concentration of the layer 229 is defined as an interface, and the distance between the interface and the depth at which the silicon concentration decreases to 1.0×10²¹ atoms/cm³, preferably 5.0× 10²⁰ atoms/cm³, further preferably 1.0×10²⁰ atoms/cm³ is defined as a thickness t_s2. The thickness t_s2 is preferably less than or equal to 3 nm, further preferably less than or equal to 2 nm.

When the thickness of the alloyed region is reduced, the thickness t_s2 can be a value within the above range.

Note that when the thickness of the alloyed region is reduced, the CAAC structure can be formed in the vicinity of the formation surface. Here, the vicinity of the formation surface refers to, for example, a region extending greater than 0 nm and less than or equal to 3 nm, preferably greater than 0 nm and less than or equal to 2 nm, further preferably greater than or equal to 1 nm and less than or equal to 2 nm from the formation surface of the semiconductor layer 230 in a direction substantially perpendicular to the formation surface.

Note that the CAAC structure in the vicinity of the formation surface can be confirmed in TEM observation in some cases. For example, in high-resolution TEM cross-sectional observation of the semiconductor layer 230, bright spots arranged in a layered manner in a direction parallel to the formation surface are observed in the vicinity of the formation surface.

Note that when the semiconductor layer 230a is formed by an ALD method, an oxide semiconductor layer having a microcrystalline structure or an amorphous structure that has lower crystallinity than the CAAC structure may be formed. That is, in the formation step illustrated in FIG. 36A, the semiconductor layer 230a sometimes includes a region having lower crystallinity than the semiconductor layer 230b.

The semiconductor layer 230b preferably has a composition suitable for forming the CAAC structure.

When the semiconductor layer 230b is formed by a sputtering method, a mixed layer 231 is formed on the surface of the semiconductor layer 230a or in the vicinity of the surface. A fine crystal region is sometimes formed in the mixed layer 231 by, for example, sputtered particles or energy applied to the substrate side by sputtered particles or the like at the time of forming the semiconductor layer 230b. In the subsequent heat treatment step, the mixed layer 231 or the fine crystal region formed in the mixed layer 231 serves as a nucleus, and at least part of the semiconductor layer 230a is crystallized in some cases.

In the formation of the semiconductor layer 230b by a sputtering method, substrate heating is preferably performed. When the substrate temperature (stage temperature) at the time of forming the metal oxide is increased, a metal oxide with high crystallinity can be formed in some cases.

Next, the semiconductor layer 230c is formed over the semiconductor layer 230b by an ALD method (FIG. 36C). For the formation of the semiconductor layer 230c by an ALD method, the method for forming the semiconductor layer 230a can be referred to.

When the semiconductor layer 230c is formed over the semiconductor layer 230b having the CAAC structure by an ALD method, the semiconductor layer 230c may epitaxially grow with the semiconductor layer 230b as a nucleus. Thus, at the time of forming the semiconductor layer 230c, the semiconductor layer 230c may include a region having the CAAC structure. The region having the CAAC structure is preferably formed throughout the semiconductor layer 230c.

Next, a heat treatment step may be performed. By the heat treatment step, the crystallinity of the region having the CAAC structure in the semiconductor layer 230c is increased in some cases. In the case where the region is formed only in the lower portion of the semiconductor layer 230c after film formation by an ALD method, the region may extend upward by the heat treatment step (FIG. 36D). That is, by the heat treatment, the region having the CAAC structure is sometimes formed in the whole semiconductor layer 230c.

At least part of the semiconductor layer 230a preferably has the CAAC structure by the heat treatment step (FIG. 36D). The CAAC structure is expected to be easily generated when the mixed layer 231 formed in the semiconductor layer 230a in the formation of the semiconductor layer 230b serves as a nucleus or a seed. The semiconductor layer 230a preferably has a large CAAC region, and the CAAC region preferably extends to the vicinity of the layer 229.

Since the CAAC region extends from the upper portion to the lower portion of the semiconductor layer 230a, the CAAC region can extend to the vicinity of the layer 229, regardless of the material and crystallinity of the layer 229. For example, even when the layer 229 has an amorphous structure, the semiconductor layer 230a having high crystallinity can be formed. Thus, the formation method of the oxide semiconductor layer disclosed in this embodiment is particularly suitable for the case where the layer serving as the formation surface has an amorphous structure.

FIGS. 36A to 36D are cross-sectional views illustrating the method for forming a film of the metal oxide of one embodiment of the present invention. FIGS. 36A to 36D can also be regarded as conceptual diagrams illustrating a film formation model of the metal oxide of one embodiment of the present invention. As illustrated in FIGS. 36A to 36D, the crystallinity of each of the semiconductor layers 230a and 230c is increased with the semiconductor layer 230b having high crystallinity as a nucleus or a seed. Specifically, the crystallinity of the semiconductor layer 230a may be increased at the time of forming the semiconductor layer 230b or by heat treatment after the formation of the semiconductor layer 230c. The crystallinity of the semiconductor layer 230c may be increased at the time of forming the semiconductor layer 230c or by heat treatment after the formation of the semiconductor layer 230c. Note that the heat treatment has an assisting function of increasing the crystallinity.

As described above, in the method for forming a film of the metal oxide of one embodiment of the present invention, the crystallinity of the oxide semiconductors (here, the semiconductor layers 230a and 230c) above and below the semiconductor layer 230b can be increased by using the semiconductor layer 230b (i.e., CAAC) having high crystallinity as a nucleus or a seed. This can increase the crystallinity of the whole oxide semiconductor. In other words, the semiconductor layer 230b serves as a nucleus or a seed to cause solid-phase growths of the oxide semiconductors above and below the semiconductor layer 230b, so that the oxide semiconductor with high crystallinity can be formed. An oxide semiconductor formed by such a film formation method, here, a CAAC film, may be referred to as an axial growth CAAC (AG CAAC). Although FIGS. 37A to 37D illustrate a structure example including the semiconductor layers 230a, 230b, and 230c, one embodiment of the present invention is not limited thereto. For example, a structure including the semiconductor layers 230a and 230b can also be referred to as an AG CAAC.

The region having the CAAC structure preferably spreads in the whole semiconductor layer 230. FIG. 37A illustrates a state where the semiconductor layers 230a, 230b, and 230c are each crystallized. In that case, a boundary between the semiconductor layer 230a and the semiconductor layer 230b is not observed in some cases. In addition, a boundary between the semiconductor layer 230b and the semiconductor layer 230c is not observed in some cases. The semiconductor layer 230 may be expressed as one layer where the interfaces are not clearly observed. The semiconductor layer 230 may be expressed as a single layer in some cases.

Part of the semiconductor layer 230a or part of the semiconductor layer 230c is not crystallized in some cases. FIG. 37B illustrates an example state where the vicinity of the interface between the semiconductor layer 230a and the layer 229 is not crystallized. FIG. 37C illustrates a state where the vicinity of the surface of the semiconductor layer 230c is not crystallized. FIG. 37D illustrates a state where the vicinity of the interface between the semiconductor layer 230a and the layer 229 and the vicinity of the surface of the semiconductor layer 230c are not crystallized.

Increasing the crystallinity of the oxide semiconductor layer can inhibit an increase in the electrical resistance of the semiconductor layer of a transistor including the oxide semiconductor layer or increase the initial characteristics (in particular, the on-state current) of the transistor, and thus a transistor suitable for high-speed operation can be expected. In addition, the reliability and on-state current of the transistor can be increased.

The oxide semiconductor layer formed by the formation method disclosed in this embodiment has high crystallinity throughout the layer. Thus, in the semiconductor layer 230 where the semiconductor layers 230a, 230b, and 230c are stacked, boundaries between the stacked films are not observed in some cases. In particular, after heat treatment is performed, the boundaries between the stacked films are difficult to observe in some cases. The presence or absence of the boundaries between the stacked films can be confirmed with a TEM, for example.

As described above, when a metal oxide with a high In content percentage is used for a transistor, the field-effect mobility of the transistor can be increased. On the other hand, an oxide semiconductor with a high In content percentage tends to be polycrystallized. The use of a metal oxide having a polycrystalline structure for a transistor adversely affects the initial characteristics or reliability of the transistor. Thus, when an oxide semiconductor with a high In content percentage is used for one or both of the semiconductor layers 230a and 230c, crystals reflecting orientations of crystals included in the semiconductor layer 230b are formed, so that one or both of the semiconductor layers 230a and 230c can be inhibited from being polycrystallized.

It is preferable that crystals included in the semiconductor layer 230b and crystals included in the semiconductor layer 230a or 230c have a small lattice mismatch. Thus, the semiconductor layer 230a or 230c can form crystals reflecting the orientation of crystals included in the semiconductor layer 230b. In that case, for example, in high-resolution TEM cross-sectional observation of the semiconductor layer 230, bright spots arranged in a layered manner in a direction parallel to the formation surface are observed in the semiconductor layer 230a or 230c.

As long as crystals included in the semiconductor layer 230b and crystals included in the semiconductor layer 230a or 230c have a small lattice mismatch, there is no particular limitation on the crystal structure of the semiconductor layer 230a or 230c. The crystal structure of the semiconductor layer 230a or 230c may be any of a cubic crystal structure, a tetragonal crystal structure, an orthorhombic crystal structure, a hexagonal crystal structure, a monoclinic crystal structure, and a trigonal crystal structure.

### [Composition of Oxide Semiconductor Layer]

As described above, the semiconductor layer 230b preferably has a composition suitable for forming the CAAC structure. The semiconductor layer 230b can be formed by a sputtering method, for example. The semiconductor layer 230b preferably contains zinc, for example. The semiconductor layer 230b containing zinc is a metal oxide with high crystallinity. The semiconductor layer 230b preferably contains the element M in addition to zinc. When the semiconductor layer 230b contains the element M, formation of oxygen vacancies in the metal oxide can be inhibited, for example. Thus, the reliability of the transistor including the oxide semiconductor layer can be improved. For the semiconductor layer 230b, a metal oxide with an atomic ratio of In:M:Zn=1:1:1 or in the neighborhood thereof, a metal oxide with an atomic ratio of In:M:Zn=1:1:1.2 or in the neighborhood thereof, a metal oxide with an atomic ratio of In:M:Zn=1:1:0.5 or in the neighborhood thereof, a metal oxide with an atomic ratio of In:M:Zn=1:1:2 or in the neighborhood thereof, a metal oxide with an atomic ratio of In:M:Zn=4:2:3 or in the neighborhood thereof, a metal oxide with an atomic ratio of In:M:Zn=1:3:2 or in the neighborhood thereof, or a metal oxide with an atomic ratio of In:M:Zn=1:3:4 or in the neighborhood thereof may be specifically used. Note that the neighborhood of the atomic ratio includes ±30% of an intended atomic ratio. It is preferable to use one or more of gallium, aluminum, and tin as the element M.

The semiconductor layer 230b does not necessarily contain the element M. For example, In—Zn oxide can be used. Specifically, an atomic ratio of In:Zn=1:1 or in the neighborhood thereof, an atomic ratio of In:Zn=2:1 or in the neighborhood thereof, or an atomic ratio of In:Zn=4:1 or in the neighborhood thereof can be employed. Alternatively, indium oxide can be used. A structure containing a slight amount of the element M can be employed. For example, an atomic ratio of In:Ga:Zn=4:0.1:1 or in the neighborhood thereof or an atomic ratio of In:Ga:Zn=2:0.1:1 or in the neighborhood thereof can be employed. For another example, an atomic ratio of In:Sn:Zn=4:0.1:1 or in the neighborhood thereof or an atomic ratio of In:Sn:Zn=2:0.1:1 or in the neighborhood thereof can be employed.

The semiconductor layers 230a and 230c can be metal oxides with a high proportion of In. The semiconductor layers 230a and 230c can each be formed by an ALD method, for example. In particular, a metal oxide in which the proportion of In is higher than that of the element M is preferably used. With the use of a metal oxide having a high proportion of In, the on-state current can be increased and the frequency characteristics can be enhanced in a transistor including an oxide semiconductor layer.

The semiconductor layers 230a and 230c do not necessarily contain the element M. For example, In—Zn oxide can be used. Specifically, an atomic ratio of In:Zn=1:1 or in the neighborhood thereof, an atomic ratio of In:Zn=2:1 or in the neighborhood thereof, or an atomic ratio of In:Zn=4:1 or in the neighborhood thereof can be employed. Alternatively, indium oxide can be used. The semiconductor layers 230a and 230c can each contain a slight amount of the element M. Specifically, an atomic ratio of In:Ga:Zn=4:0.1:1 or in the neighborhood thereof, an atomic ratio of In:Ga:Zn=2:0.1:1 or in the neighborhood thereof, an atomic ratio of In:Sn:Zn=4:0.1:1 or in the neighborhood thereof, or an atomic ratio of In:Sn:Zn=2:0.1:1 or in the neighborhood thereof can be employed.

Note that when a proportion of zinc in the oxide semiconductor is increased, the crystallinity of the oxide semiconductor can be increased. In particular, the semiconductor layer 230a preferably contains zinc. For example, in the case where the semiconductor layer 230a is formed by an ALD method and the semiconductor layer 230b is formed by a sputtering method, zinc contained in the semiconductor layer 230a diffuses into the semiconductor layer 230b in some cases. Note that the diffusion can occur at the time of sputtering or later heat treatment. The diffusion of zinc from the semiconductor layer 230a to the semiconductor layer 230b is expected to improve the crystallinity. Alternatively, the diffusion of zinc from the semiconductor layer 230a into the semiconductor layer 230b is expected to induce lateral growth of a crystal part having c-axis alignment to promote extension of the CAAC structure.

The semiconductor layers 230a and 230c can each be a metal oxide having a higher proportion of In than the semiconductor layer 230b.

For example, a metal oxide having a higher proportion of Ga than the semiconductor layer 230b can also be used for the semiconductor layers 230a and 230c. For each of the semiconductor layers 230a and 230c, a metal oxide with an atomic ratio of In:Ga:Zn=1:1:1 or in the neighborhood thereof, a metal oxide with an atomic ratio of In:Ga:Zn=1:3:2 or in the neighborhood thereof, or a metal oxide with an atomic ratio of In:Ga:Zn=1:3:4 or in the neighborhood thereof is preferably used, for example. When the proportion of Ga is increased, the band gap of each of the semiconductor layers 230a and 230c can be larger than that of the semiconductor layer 230b in some cases, for example. Thus, the semiconductor layer 230b is sandwiched between the semiconductor layers 230a and 230c each having a wide band gap, and the semiconductor layer 230b mainly functions as a current path (channel). When the semiconductor layer 230b is sandwiched between the semiconductor layers 230a and 230c, the trap states at the interfaces with the semiconductor layer 230b and the vicinity thereof can be reduced. Accordingly, a buried-channel transistor where a channel is away from the interface with an insulating layer can be achieved, whereby the field-effect mobility can be increased.

Even when each of the semiconductor layers 230a and 230c as a single layer in the oxide semiconductor layer has a composition that does not easily form the CAAC structure, the whole oxide semiconductor layer, including the semiconductor layers 230a and 230c, can have the CAAC structure owing to crystal growth caused with the semiconductor layer 230b as a nucleus. Alternatively, the CAAC structure can be formed in a region including the whole semiconductor layer 230b and at least part of each of the semiconductor layers 230a and 230c.

In particular, even when the semiconductor layers 230a and 230c have a composition with a high In proportion, crystallinity suitable for a semiconductor layer of a transistor can be obtained. The oxide semiconductor layer used as the semiconductor layer of the transistor enables both high on-state characteristics and high reliability of a transistor, respectively by having a high proportion of In and by having the CAAC structure with high crystallinity.

Note that the semiconductor layers 230a and 230c may have different compositions.

The semiconductor layers 230a and 230c can be formed using a metal oxide having the same composition as the semiconductor layer 230b.

With the use of the oxide semiconductor layer with the CAAC structure formed by the above-described two kinds of film formation methods for a channel formation region of a transistor, the transistor can have excellent characteristics (e.g., a high on-state current, high field-effect mobility, a low S value, excellent frequency characteristics (also referred to as f characteristics), or high reliability).

Analysis of the composition of the metal oxide used for the semiconductor layer 230 can be performed by EDX, XPS, inductively coupled plasma-mass spectrometry (ICP-MS), or inductively coupled plasma-atomic emission spectrometry (ICP-AES), for example. Alternatively, two or more of these methods may be combined for the analysis. As for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

### [C-Axis Alignment Proportion]

The degree of the crystallinity of the oxide semiconductor layer having the CAAC structure can be evaluated with the use of crystal orientation, for example.

The crystal orientation can be obtained from a fast Fourier transform (FFT) pattern obtained by performing FFT processing on a TEM image. Specifically, the directions of the crystal axes can be obtained using an FFT pattern. The FFT pattern obtained by the FFT processing reflects reciprocal lattice space information like an electron diffraction pattern.

When FFT processing is performed on each region in the TEM image of the oxide semiconductor layer, crystal orientation in each region can be obtained. For example, crystal orientation is obtained in each region in a certain area range, so that a map indicating crystal orientation can be formed. Specifically, two spots with high intensity are observed in the FFT pattern of the region including the layered crystal part. The direction of the crystal axis of the region can be obtained from the angle of the line segment connecting the two spots.

In the map indicating crystal orientation, the proportion of regions having c-axis alignment is calculated to obtain a c-axis alignment proportion. Here, the region having c-axis alignment represents a region where the orientation is aligned with the c-axis and a region where the orientation is deviated from the c-axis by less than or equal to 20°.

In the oxide semiconductor layer, the c-axis alignment proportion can be calculated by, for example, cross-sectional or plan-view TEM observation of the oxide semiconductor layer. The region where the FFT is performed (also referred to as an FFT window) can be a circle with a diameter of 1.0 nm, for example. Note that the region where the FFT is performed is not limited to a circle.

In the oxide semiconductor layer having the CAAC structure, the c-axis alignment proportion is preferably higher than or equal to 60%, further preferably higher than or equal to 70%, still further preferably higher than or equal to 80%, yet further preferably higher than or equal to 90%, most preferably higher than or equal to 95%.

Furthermore, the c-axis alignment proportions of the region formed as the semiconductor layer 230a, the region formed as the semiconductor layer 230b, and the region formed as the semiconductor layer 230c are Rc1, Rc2, and Rc3, respectively. Each of Rc2 and Rc3 is higher than or equal to 60%, preferably higher than or equal to 70%, further preferably higher than or equal to 80%, still further preferably higher than or equal to 90%, yet still further preferably higher than or equal to 95%. Rc3/Rc1 is preferably greater than 1. Furthermore, Rc2/Rc1 is preferably greater than 1.

Note that after the formation of the semiconductor layer 230, the boundaries between the semiconductor layers 230a, 230b, and 230c are not clearly observed in some cases.

The semiconductor layer 230 of one embodiment of the present invention can be divided into three regions: a first region, a second region, and a third region in this order from the top of the layer 229. Each of the regions is a layered region.

The first, second, and third regions each have the CAAC structure. In addition, the c-axis alignment proportion in the third region is preferably higher than that in the first region. The c-axis alignment proportion in the second region is preferably higher than that in the first region. The c-axis alignment proportions in the second and third regions are each higher than or equal to 80%, preferably higher than or equal to 90%, further preferably higher than or equal to 95%.

The first region extends greater than or equal to 0 nm and less than or equal to 3 nm from the top surface of the layer 229, and the third region extends greater than or equal to 0 nm and less than or equal to 3 nm from the top surface of the semiconductor layer 230.

The thicknesses of the layers in the regions are substantially the same, for example.

The structure described in this embodiment can be used in appropriate combination with any of the structures described in the other embodiments and example.

### Embodiment 4

In this embodiment, examples of a planar layout and examples of a cross-sectional structure of the semiconductor device 10 of one embodiment of the present invention will be described. One embodiment of the present invention describes planar layouts and cross-sectional structures of the transistors included in the semiconductor device 10. For easy understanding of the arrangement of the transistors included in the semiconductor device 10, the insulating layers, the capacitors, the light-emitting element, and the like are not illustrated. In order to avoid repeated description, matters not described in the other embodiments are mainly described. The description in the other embodiments can be referred to for the matters not described in this embodiment.

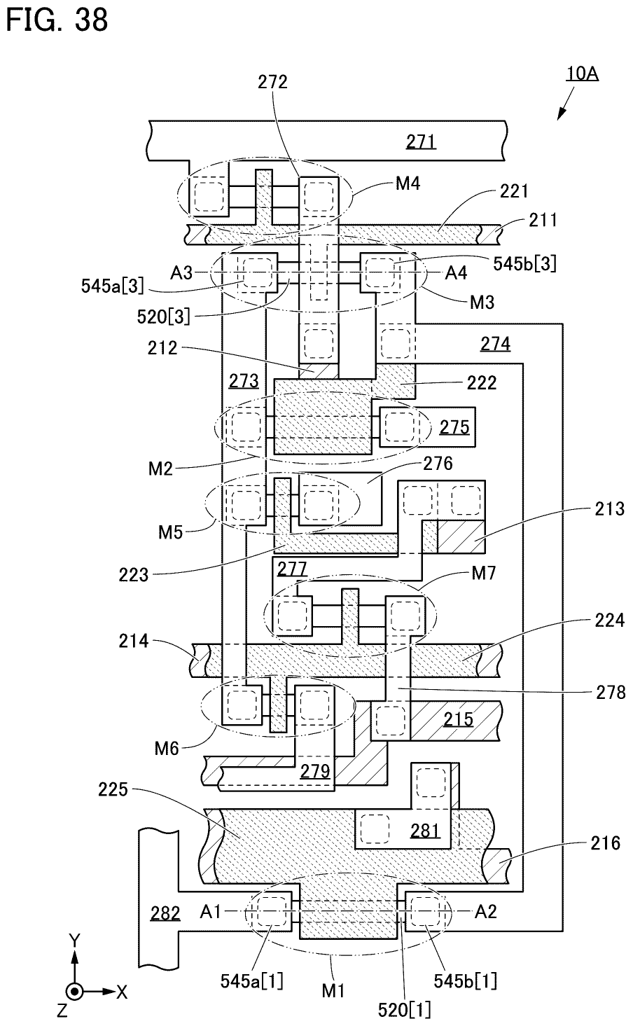

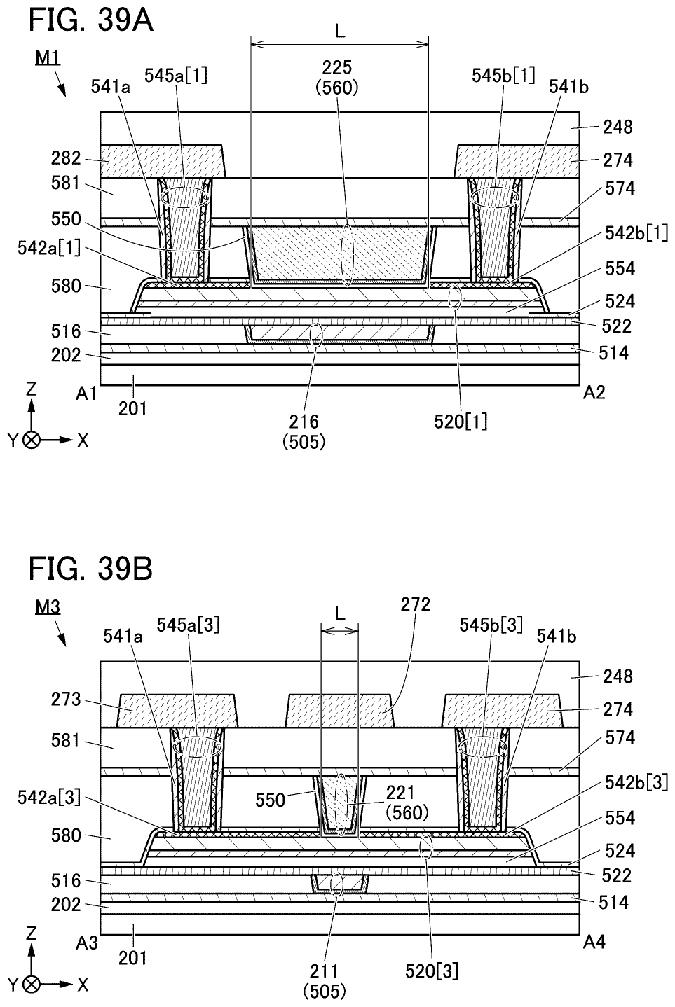

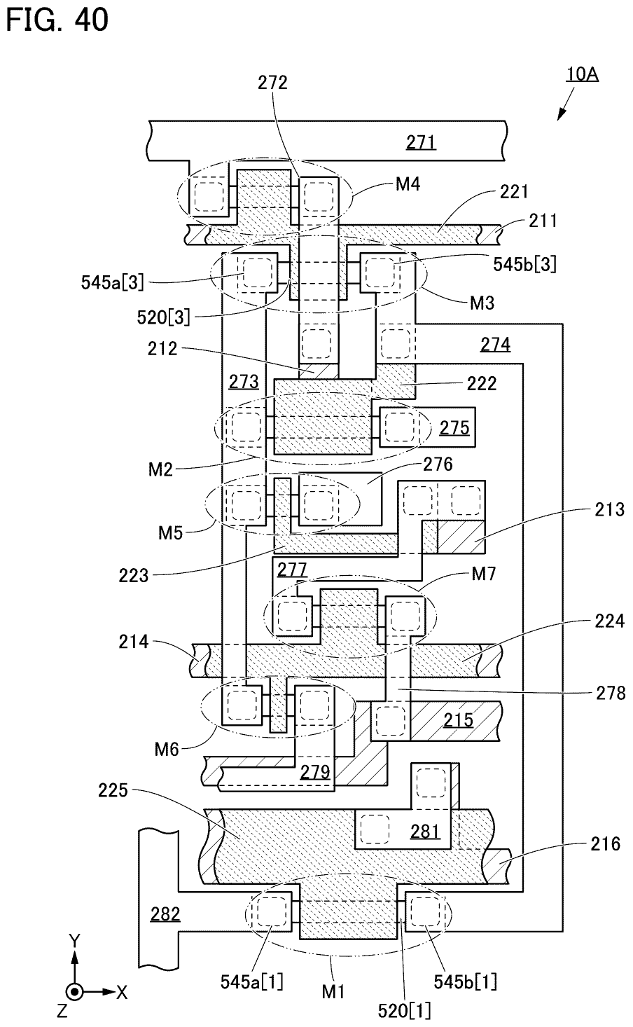

FIG. 38 and FIG. 40 illustrate examples of a planar layout of the semiconductor device 10A illustrated in FIG. 1. FIG. 39A is a cross-sectional view taken along the dashed-dotted line A1-A2 in FIG. 38. FIG. 39B is a cross-sectional view taken along the dashed-dotted line A3-A4 in FIG. 38. In this embodiment, the transistor 200F illustrated in FIGS. 29A to 29C is used as each of the transistors included in the semiconductor device 10.

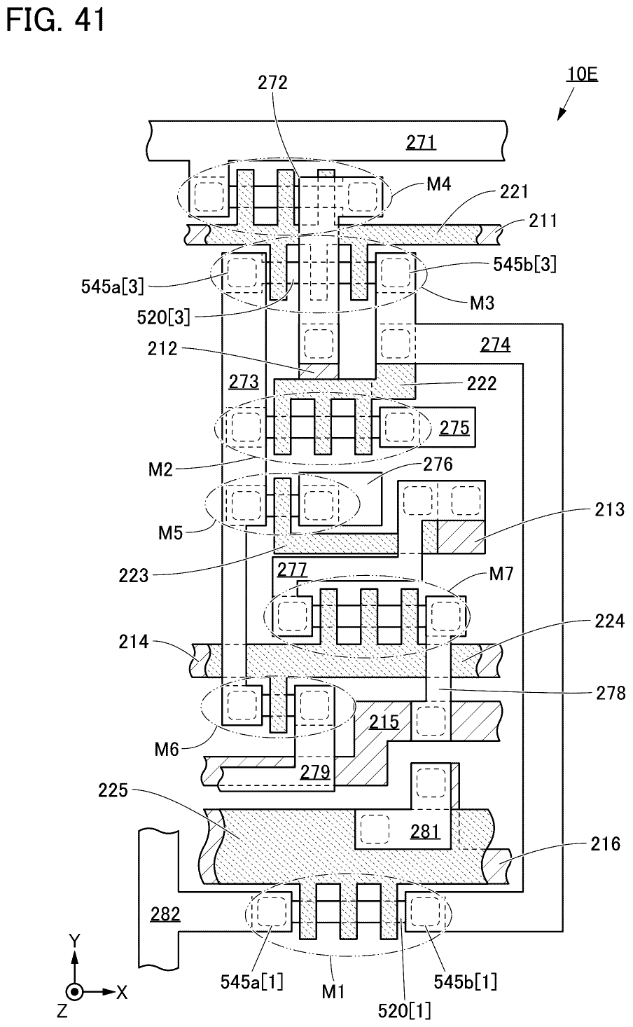

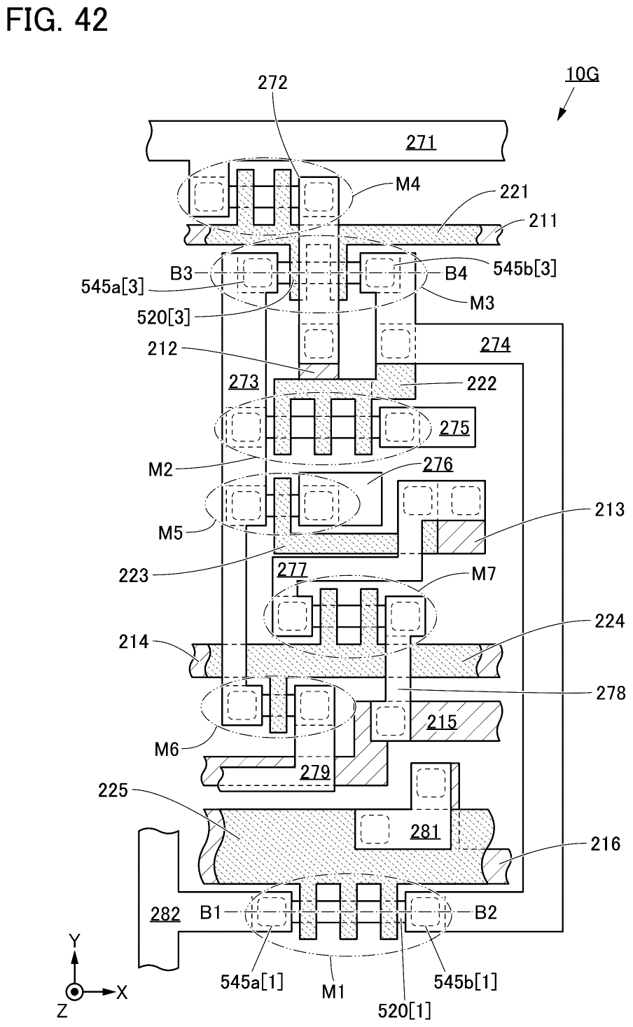

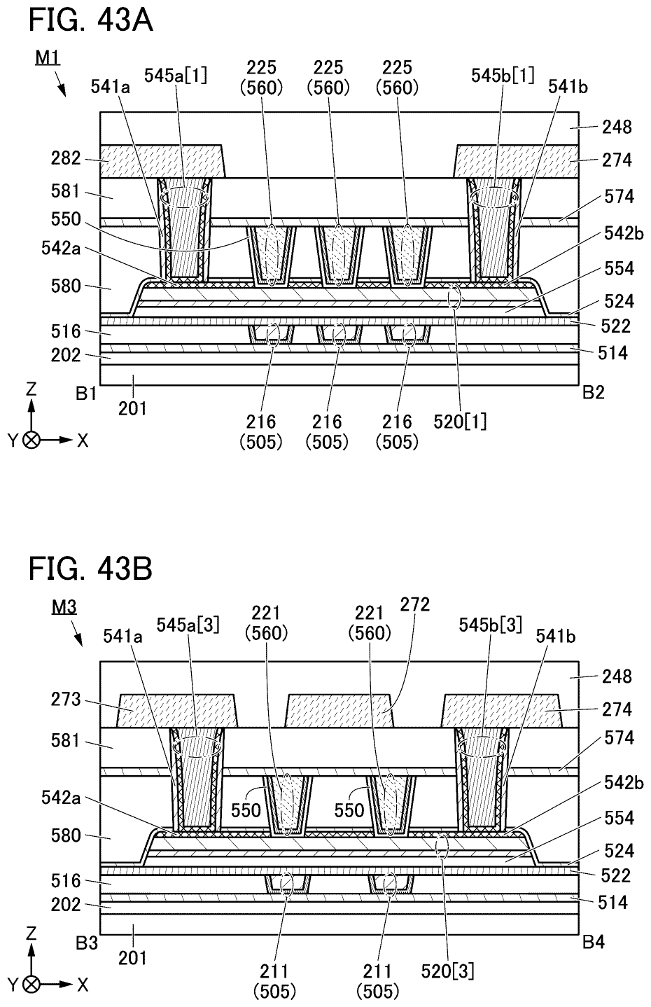

FIG. 41 illustrates an example of a planar layout of the semiconductor device 10E illustrated in FIG. 9. FIG. 42 illustrates an example of a planar layout of the semiconductor device 10G illustrated in FIG. 11. FIG. 43A is a cross-sectional view taken along the dashed-dotted line B1-B2 in FIG. 42. FIG. 43B is a cross-sectional view taken along the dashed-dotted line B3-B4 in FIG. 42.

FIG. 38 and FIGS. 39A and 39B illustrate an example of a planar layout and examples of a cross-sectional structure of the semiconductor device 10A in which the channel length L of each of the transistors M1 and M2 is longer than that of each of the transistors M3 to M7.

FIG. 40 illustrates an example of a planar layout of the semiconductor device 10A in which the channel length L of each of the transistors M3, M4, and M7 is set longer than that of each of the transistors M5 and M6, and the channel length L of each of the transistors M1 and M2 is set longer than that of each of the transistors M3, M4, and M7.

FIG. 41 illustrates a planar layout of the semiconductor device 10E in which a multi-gate transistor with a series number of 3 is used as each of the transistors M1, M2, M3, M4, and M7 and a single-gate transistor is used as each of the transistors M5 and M6.

FIG. 42 and FIGS. 43A and 43B illustrate a planar layout of the semiconductor device 10G in which a multi-gate transistor with a series number of 3 is used as each of the transistors M1 and M2, a multi-gate transistor with a series number of 2 is used as each of the transistors M3, M4, and M7, and a single-gate transistor is used as each of the transistors M5 and M6.

The channel length L of the transistor or the series number of the multi-gate transistor is different between the planar layouts and between the cross-sectional structure examples described in this embodiment; however, the same connection structure of wirings and the like is employed in the planar layouts and the cross-sectional structure examples. Thus, description with reference to FIG. 38 and FIGS. 39A and 39B is made as typical examples in this embodiment.

The semiconductor device 10A illustrated in FIG. 38 includes a conductive layer 211, a conductive layer 212, a conductive layer 213, a conductive layer 214, a conductive layer 215, and a conductive layer 216 over the insulating layer 514. The semiconductor device 10A also includes a conductive layer 221, a conductive layer 222, a conductive layer 223, a conductive layer 224, and a conductive layer 225 over the insulating layer 550. The semiconductor device 10A also includes a conductive layer 271, a conductive layer 272, a conductive layer 273, a conductive layer 274, a conductive layer 275, a conductive layer 276, a conductive layer 277, a conductive layer 278, a conductive layer 279, a conductive layer 281, and a conductive layer 282 over the insulating layer 581. These conductive layers can be formed using any of the materials described in Embodiment 2.

An insulating layer 248 is provided over the conductive layers 271, 272, 273, 274, 275, 276, 277, 278, 279, 281, and 282 (see FIGS. 39A and 39B).

FIG. 39A illustrates a cross-sectional structure example of the transistor M1. Part of the conductive layer 216 functions as the conductive layer 505, i.e., the back gate of the transistor M1. Part of the conductive layer 225 functions as the conductive layer 560, i.e., the gate of the transistor M1. The conductive layer 216 and the conductive layer 225 are connected to each other through the conductive layer 281.

The conductive layers 216 and 225 are connected to the wiring GLa (not illustrated in FIG. 38). Note that the conductive layers 216 and 225 can also function as the wiring GLa. The conductive layer 282 is connected to one of the source and the drain of the transistor M1. Specifically, the conductive layer 282 is connected to a semiconductor layer 520 [1] through a conductive layer 545a[1] and a conductive layer 542a[1] (see FIG. 39A). The conductive layer 282 is connected to the wiring DL. Note that the conductive layer 282 can also function as the wiring DL.

The conductive layer 274 is connected to the other of the source and the drain of the transistor M1. Specifically, the conductive layer 274 is connected to the semiconductor layer 520 [1] through a conductive layer 545b[1] and a conductive layer 542b[1] (see FIG. 39A).

The conductive layer 274 is connected to the conductive layer 222. Part of the conductive layer 222 functions as the gate of the transistor M2. The conductive layer 275 is connected to one of the source and the drain of the transistor M2. The conductive layer 275 is connected also to the wiring 101 (not illustrated in FIG. 38). The conductive layer 273 is connected to the other of the source and the drain of the transistor M2.

Part of the conductive layer 211 functions as the back gate of the transistor M4, and another part of the conductive layer 211 functions as the back gate of the transistor M3. Part of the conductive layer 221 functions as the gate of the transistor M4, and another part of the conductive layer 221 functions as the gate of the transistor M3. The conductive layers 211 and 221 are connected to the wiring GLb (not illustrated in FIG. 38). Note that the conductive layers 211 and 221 can also function as the wiring GLb.

FIG. 39B illustrates a cross-sectional structure example of the transistor M3. Part of the conductive layer 211 functions as the conductive layer 505. Part of the conductive layer 221 functions as the conductive layer 560. The conductive layer 274 is connected to one of the source and the drain of the transistor M3. Specifically, the conductive layer 274 is connected to a semiconductor layer 520 [3] through a conductive layer 545b[3] and a conductive layer 542b[3] (see FIG. 39B).

The conductive layer 273 is connected to the other of the source and the drain of the transistor M3. Specifically, the conductive layer 273 is connected to the semiconductor layer 520 [3] through a conductive layer 545a[3] and a conductive layer 542a[3] (see FIG. 39B). The conductive layer 271 is connected to one of the source and the drain of the transistor M4. The conductive layer 271 is connected to the wiring 102 (not illustrated in FIG. 38). Note that the conductive layer 271 can also function as the wiring 102.

The conductive layer 272 is connected to the other of the source and the drain of the transistor M4. The conductive layer 272 is also connected to the conductive layer 212. Part of the conductive layer 212 functions as the back gate of the transistor M2.

The conductive layer 273 is connected to one of the source and the drain of the transistor M5. The conductive layer 276 is connected to the other of the source and the drain of the transistor M5. The conductive layer 276 is connected to the first terminal of the light-emitting element 61. Note that the conductive layer 276 can also function as the first terminal of the light-emitting element 61.

The conductive layer 273 is connected to one of the source and the drain of the transistor M6. The conductive layer 279 is connected to the other of the source and the drain of the transistor M6. The conductive layer 279 is connected to the wiring 103 (not illustrated in FIG. 38). Note that the conductive layer 279 can also function as the wiring 103.

Part of the conductive layer 214 functions as the back gate of the transistor M6, and another part of the conductive layer 214 functions as the back gate of the transistor M7. Part of the conductive layer 224 functions as the gate of the transistor M6, and another part of the conductive layer 224 functions as the gate of the transistor M7. The conductive layers 214 and 224 are connected to the wiring GLd (not illustrated in FIG. 38). Note that the conductive layers 214 and 224 can also function as the wiring GLd.

The conductive layer 215 is connected to one of the source and the drain of the transistor M7 through the conductive layer 278. The conductive layer 215 is connected to the wiring GLc (not illustrated in FIG. 38). Note that the conductive layer 215 can also function as the wiring GLc.

The conductive layer 277 is connected to the other of the source and the drain of the transistor M7. The conductive layer 277 is also connected to the conductive layers 213 and 223. Part of the conductive layer 213 functions as the back gate of the transistor M5. Part of the conductive layer 223 functions as the gate of the transistor M5.

Although not described in this embodiment, the capacitor C1 is provided between the conductive layer 273 and the conductive layer 274. The capacitor C2 is provided between the conductive layer 272 and the conductive layer 273. The capacitor C3 is provided between the conductive layer 276 and the conductive layer 277.

The structure described in this embodiment can be used in appropriate combination with any of the structures described in the other embodiments and example.

### Embodiment 5

The semiconductor device of one embodiment of the present invention can be used for a display device or the like. The semiconductor device of one embodiment of the present invention can be used for a module including the display device (also referred to as a “display module”), for example. In this embodiment, a display device including the semiconductor device of one embodiment of the present invention is described.

Examples of the display module include a module in which a connector such as a flexible printed circuit board (FPC) or a tape carrier package (TCP) is attached to the display device and a module in which the display device is mounted with an integrated circuit (IC) chip by a chip on glass (COG) method, a chip on film (COF) method, or the like.

### <Structure Example of Display Device>

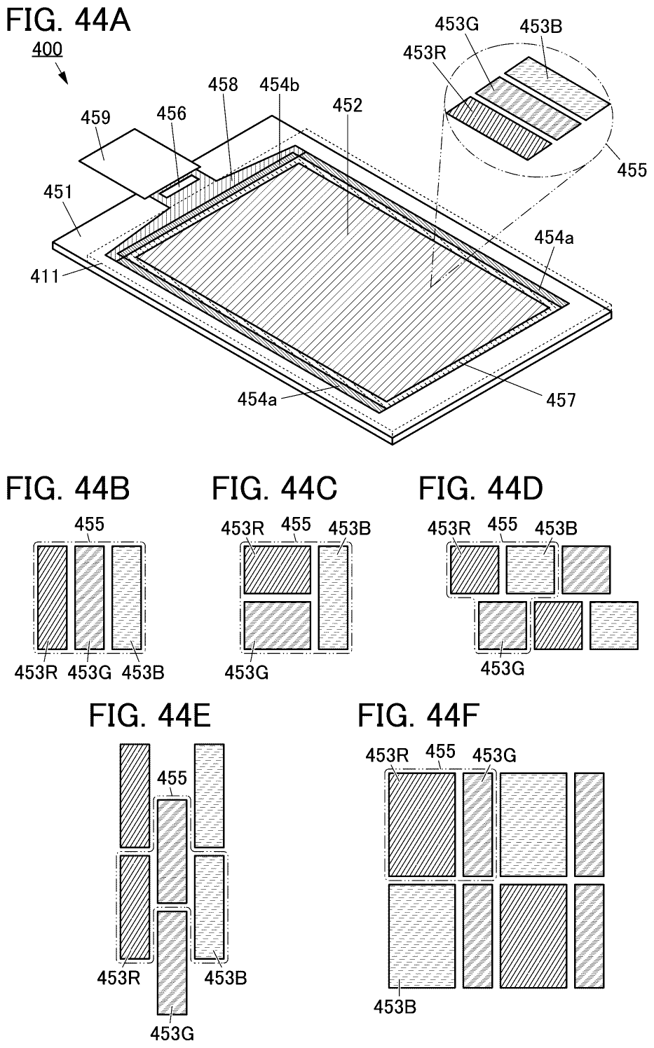

FIG. 44A is a perspective view illustrating a structure example of a display device 400 of one embodiment of the present invention.

In the display device 400, a substrate 411 and a substrate 451 are bonded to each other. In FIG. 44A, the substrate 411 is denoted by a dashed line.

The display device 400 includes a display portion 452, a circuit portion 454a, a circuit portion 454b, a connection portion 457, and a wiring portion 458. FIG. 44A illustrates an example in which an IC 456 and an FPC 459 are mounted on the display device 400. Thus, the structure illustrated in FIG. 44A can be regarded as a display module including the display device 400, the IC, and the FPC.

The circuit portion 454a includes a scan line driver circuit (also referred to as a gate driver or a scan driver), for example. The circuit portion 454b includes a signal line driver circuit (also referred to as a source driver or a data driver), for example.

The wiring portion 458 has a function of supplying a signal and power to the display portion 452 and the circuit portions 454a and 454b. The signal and power are input to the wiring portion 458 from the outside of the display device 400 through the FPC 459 or from the IC 456.

FIG. 44A illustrates an example in which the IC 456 is provided on the substrate 451 by a COG method, a COF method, or the like. An IC including one or both of a scan line driver circuit and a signal line driver circuit can be used as the IC 456, for example. Note that the display device 400 and the display module are not necessarily provided with an IC. The IC 456 can be mounted on the FPC by a COF method or the like.

One or both of the IC 456 and the circuit portion 454a can construct the scan line driver circuit, in which case the IC 456 may be referred to as a gate driver IC. One or both of the IC 456 and the circuit portion 454b can construct the signal line driver circuit, in which case the IC 456 may be referred to as a source driver IC.

The display portion 452 of the display device 400 is a region where an image is to be displayed, and includes a plurality of pixels 455 that are periodically arranged. An enlarged view of one of the pixels 455 is shown in FIG. 44A.

The pixel 455 illustrated in FIG. 44A includes a pixel 453R that emits red (R) light, a pixel 453G that emits green (G) light, and a pixel 453B that emits blue (B) light. The pixels 453R, 453G, and 453B form one pixel 455, which achieves full-color display. The pixels 453R, 453G, and 453B each function as a subpixel. In the display device 400 illustrated in FIG. 44A, the pixels 453R, 453B, and 453G functioning as subpixels are arranged in a stripe pattern, for example. The number of subpixels forming one pixel 455 is not limited to three, and can be four or more. For example, one pixel 455 can include four subpixels which emit light of four colors of R, G, B, and white (W). Alternatively, one pixel 455 can include four subpixels which emit light of four colors of R, G, B, and yellow (Y).

In the description in this specification, identification signs such as “R”, “G”, and “B” are sometimes used to indicate the components related to red light, green light, and blue light, respectively. Such identification signs are sometimes omitted in the description common to the components. For example, a plurality of pixels 453 are sometimes shown individually as the pixel 453R, the pixel 453G, and the pixel 453B when they need to be distinguished from each other. For example, the pixels 453R, 453G, and 453B are sometimes shown simply as the pixels 453 when they do not need to be distinguished from each other.

The pixels 453R, 453G, and 453B each include a light-emitting element and a circuit (pixel circuit) controlling the emission luminance of the light-emitting element. The semiconductor device 10 of one embodiment of the present invention can be used as each of the pixels 453.

The connection portion 457 is provided outside the display portion 452. The connection portion 457 can be provided along one or more sides of the display portion 452. The number of connection portions 457 may be one or more. FIG. 44A illustrates an example in which the connection portion 457 is provided to surround the four sides of the display portion. In the connection portion 457, a common electrode of a display element is connected to the wiring portion 458 so that a potential can be supplied to the common electrode.

Here, any of the transistors described in the above embodiments can be used for at least one of the display portion 452, the circuit portion 454a, and the circuit portion 454b of the display device 400, for example.

With the use of a vertical transistor like the transistor 200C described above for one or both of the circuit portion 454a and the circuit portion 454b, for example, the area occupied by the circuit portions 454a and 454b can be reduced so that the display device can have a narrow bezel.

With the use of a vertical transistor like the transistor 200C or the transistor 200D described above for a pixel circuit of the display portion 452, for example, the area occupied by the pixel circuit can be reduced so that the display device can have high resolution. For example, the resolution of the display device can be higher than or equal to 300 ppi, higher than or equal to 500 ppi, higher than or equal to 1000 ppi, higher than or equal to 2000 ppi, or higher than or equal to 3000 ppi.

The display device of one embodiment of the present invention can have a touch panel function. The display device can employ any of various sensor elements that can sense proximity or touch of a sensing target such as a finger, for example.

Examples of a sensor type include a capacitive type, a resistive type, a surface acoustic wave type, an infrared type, an optical type, and a pressure-sensitive type.

Examples of a capacitive type include a surface capacitive type and a projected capacitive type. Examples of a projected capacitive type include a self-capacitive type and a mutual capacitive type. The use of a mutual capacitive type is preferable because multiple points can be sensed simultaneously.

Examples of a touch panel include an out-cell touch panel, an on-cell touch panel, and an in-cell touch panel. An in-cell touch panel has a structure in which an electrode included in a sensor element is provided on one or both of a substrate supporting a display element (also referred to as a display device) and a counter substrate.

### [Pixel Arrangement]

FIGS. 44B to 44F are plan views each illustrating pixel arrangement. In the display device of one embodiment of the present invention, there is no particular limitation on the pixel arrangement and various arrangements can be employed. Examples of the pixel arrangement include stripe arrangement (see FIG. 44B), S-stripe arrangement (see FIG. 44C), delta arrangement (see FIG. 44D), zigzag arrangement (see FIG. 44E), and PenTile arrangement (see FIG. 44F). Other examples include mosaic arrangement, diamond arrangement, and Bayer arrangement.

Furthermore, examples of the top surface shape of each of the subpixels (the pixels 453R, 453G, and 453B) in FIGS. 44B to 44F include polygons such as a triangle, a tetragon (including a rectangle and a square), and a pentagon, polygons with rounded corners, an ellipse, and a circle. Here, the top surface shape of the subpixel corresponds to a top surface shape of a display region of the display element included in the subpixel. The top surface shapes and sizes of the subpixels can be determined independently. Note that the positions of the pixels 453R, 453G, and 453B may be interchanged with each other as appropriate. The arrangement of the display elements can be the same as or different from the arrangement of the pixel circuits.

Here, PenTile arrangement is a unique pixel arrangement that increases resolution in a pseudo manner. Thus, stripe arrangement or the like can be employed for the display device, for example. According to one embodiment of the present invention, with the use of a vertical transistor like the transistor 200C or the transistor 200D described above as some or all of the transistors included in the pixel circuit, for example, the area occupied by the pixel circuit can be reduced. This allows PenTile arrangement to be replaced with stripe arrangement or the like as the pixel arrangement without a reduction in the resolution of the display device, for example.

### [Light-Emitting Element]

As the light-emitting element, for example, a self-luminous light-emitting element such as an LED, an organic EL element (also referred to as an organic LED (OLED)), or a semiconductor laser can be used. Examples of an LED include a mini LED and a micro LED.

Examples of a light-emitting substance contained in the light-emitting element include a substance that emits fluorescent light (a fluorescent material), a substance that emits phosphorescent light (a phosphorescent material), a substance that exhibits thermally activated delayed fluorescence (a thermally activated delayed fluorescent (TADF) material), and an inorganic compound (e.g., a quantum dot material).

The light-emitting element can emit infrared, red, green, blue, cyan, magenta, yellow, or white light, for example. When the light-emitting element has a microcavity structure, higher color purity can be achieved.

One of a pair of electrodes or terminals of the light-emitting element functions as an anode (also referred to as an anode electrode), and the other functions as a cathode (also referred to as a cathode electrode).

In this embodiment, the case where an organic EL element is used as the light-emitting element is described as an example. Thus, the display device 400 of one embodiment of the present invention is a display device including an organic EL element.

Any of the following structures is suitable for the display device 400 of one embodiment of the present invention: a top-emission structure in which light is emitted in a direction opposite to the substrate where the light-emitting element is formed, a bottom-emission structure in which light is emitted toward the substrate where the light-emitting element is formed, and a dual-emission structure in which light is emitted toward both surfaces.

Since the area occupied by the pixel circuit can be reduced with the use of a vertical transistor like the transistor 200C or the transistor 200D described above, for example, the aperture ratio of a pixel can be increased particularly in a display device having a bottom-emission structure and a display device having a dual-emission structure. For example, the aperture ratio can be higher than or equal to 50%, higher than or equal to 55%, or higher than or equal to 60% in the display device.

In this specification and the like, the aperture ratio refers to a proportion of the area of a light-emitting region per pixel in the area occupied by one pixel.

### <Structure Example of Light-Emitting Element>

The light-emitting element 61 that can be used in the display device of one embodiment of the present invention will be described.

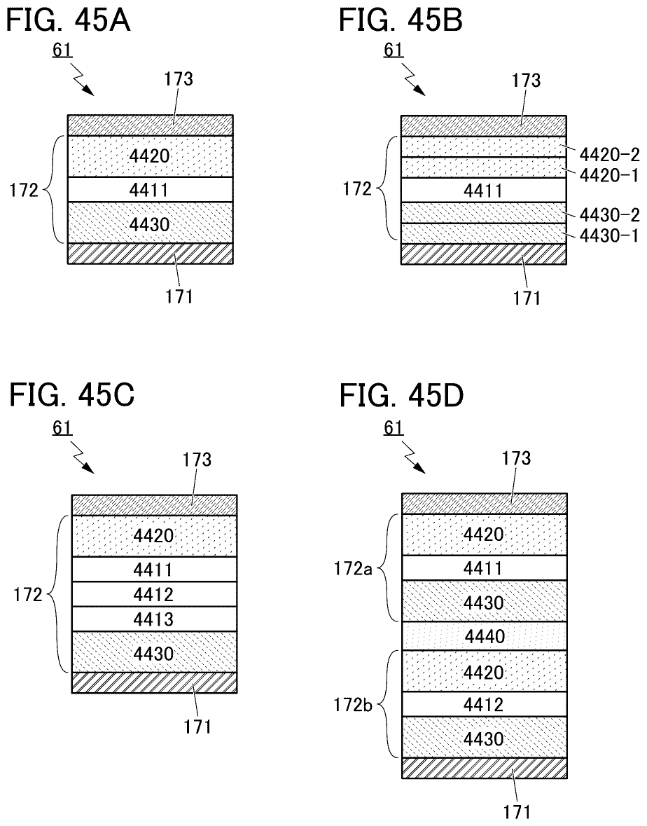

As illustrated in FIG. 45A, the light-emitting element 61 includes an EL layer 172 between a conductive layer 171 and a conductive layer 173. The EL layer 172 can be formed of a plurality of layers such as a layer 4420, a light-emitting layer 4411, and a layer 4430. The layer 4420 can include, for example, a layer containing a substance with a high electron-injection property (an electron-injection layer) and a layer containing a substance with a high electron-transport property (an electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430, which is provided between the conductive layers 171 and 173 functioning as electrodes, can function as a single light-emitting unit, and the structure in FIG. 45A is referred to as a single structure in this specification and the like.

FIG. 45B is a modification example of the EL layer 172 included in the light-emitting element 61 illustrated in FIG. 45A. Specifically, the light-emitting element 61 illustrated in FIG. 45B includes a layer 4430-1 over the conductive layer 171, a layer 4430-2 over the layer 4430-1, the light-emitting layer 4411 over the layer 4430-2, a layer 4420-1 over the light-emitting layer 4411, a layer 4420-2 over the layer 4420-1, and the conductive layer 173 over the layer 4420-2. For example, in the case where the conductive layer 171 functions as an anode and the conductive layer 173 functions as a cathode, the layer 4430-1 functions as a hole-injection layer, the layer 4430-2 functions as a hole-transport layer, the layer 4420-1 functions as an electron-transport layer, and the layer 4420-2 functions as an electron-injection layer. Alternatively, in the case where the conductive layer 171 functions as a cathode and the conductive layer 173 functions as an anode, the layer 4430-1 functions as an electron-injection layer, the layer 4430-2 functions as an electron-transport layer, the layer 4420-1 functions as a hole-transport layer, and the layer 4420-2 functions as a hole-injection layer. With such a layer structure, carriers can be efficiently injected to the light-emitting layer 4411, and the efficiency of the recombination of carriers in the light-emitting layer 4411 can be enhanced.

The structure in which a plurality of light-emitting layers (the light-emitting layer 4411, a light-emitting layer 4412, and a light-emitting layer 4413) are provided between the layer 4420 and the layer 4430 as illustrated in FIG. 45C is another example of the single structure.

The structure in which a plurality of light-emitting units (an EL layer 172a and an EL layer 172b) are connected in series with an intermediate layer (charge-generation layer) 4440 therebetween as illustrated in FIG. 45D is referred to as a tandem structure or a stack structure in this specification and the like. The tandem structure enables a light-emitting element to emit light with high luminance.

In the case where the light-emitting element 61 has the tandem structure illustrated in FIG. 45D, the EL layers 172a and 172b preferably emit light of the same color. For example, the EL layers 172a and 172b preferably both emit green light.

Note that full color display can be achieved by forming one pixel with three subpixels of the light-emitting element 61 emitting red light (R), the light-emitting element 61 emitting green light (G), and the light-emitting element 61 emitting blue light (B). In the case where one pixel includes three kinds of subpixels of R, G, and B, the light-emitting elements 61 each preferably have a tandem structure. Specifically, the EL layers 172a and 172b in the subpixel of R each contain a material capable of emitting red light, the EL layers 172a and 172b in the subpixel of G each contain a material capable of emitting green light, and the EL layers 172a and 172b in the subpixel of B each contain a material capable of emitting blue light. In other words, the light-emitting layers 4411 and 4412 can contain the same material. When the EL layers 172a and 172b emit light of the same color, the current density per unit emission luminance can be reduced. Thus, the reliability of the light-emitting element 61 can be improved.

The emission color of the light-emitting element can be changed to red, green, blue, cyan, magenta, yellow, white, or the like depending on the material of the EL layer 172. When the light-emitting element has a microcavity structure, the color purity can be further increased.

The light-emitting layer can contain two or more substances selected from light-emitting substances emitting light of red (R), green (G), blue (B), yellow (Y), orange (O), and the like. For example, in a light-emitting element emitting white light, a light-emitting layer preferably contains two or more kinds of light-emitting substances. In order to obtain white light, light-emitting substances are selected such that colors of light emitted from the two light-emitting substances are complementary colors, or light-emitting substances are selected such that colors of light emitted from the two or more light-emitting substances are combined to be white. For example, in the case where two light-emitting layers are used to obtain white light, the emission colors of the two light-emitting layers are made complementary, so that the light-emitting element can emit white light as a whole. In the case where three or more light-emitting layers are used to obtain white light, the light-emitting element can be configured to emit white light as a whole by combining emission colors of the three or more light-emitting layers.

The light-emitting layer preferably contains two or more light-emitting substances emitting light of red (R), green (G), blue (B), yellow (Y), orange (O), and the like. Alternatively, the light-emitting layer preferably contains two or more light-emitting substances emitting light containing two or more of spectral components of R, G, and B. As the light-emitting substance, a substance that emits near-infrared light can also be used.

Examples of a light-emitting substance include a substance that emits fluorescent light (a fluorescent material), a substance that emits phosphorescent light (a phosphorescent material), and a substance that exhibits thermally activated delayed fluorescence (a thermally activated delayed fluorescent (TADF) material). Examples of the light-emitting substance contained in the EL element include not only organic compounds but also inorganic compounds (e.g., quantum dot materials).

### <Method for Forming Light-Emitting Element>

An example of a method for forming the light-emitting element 61 is described below.

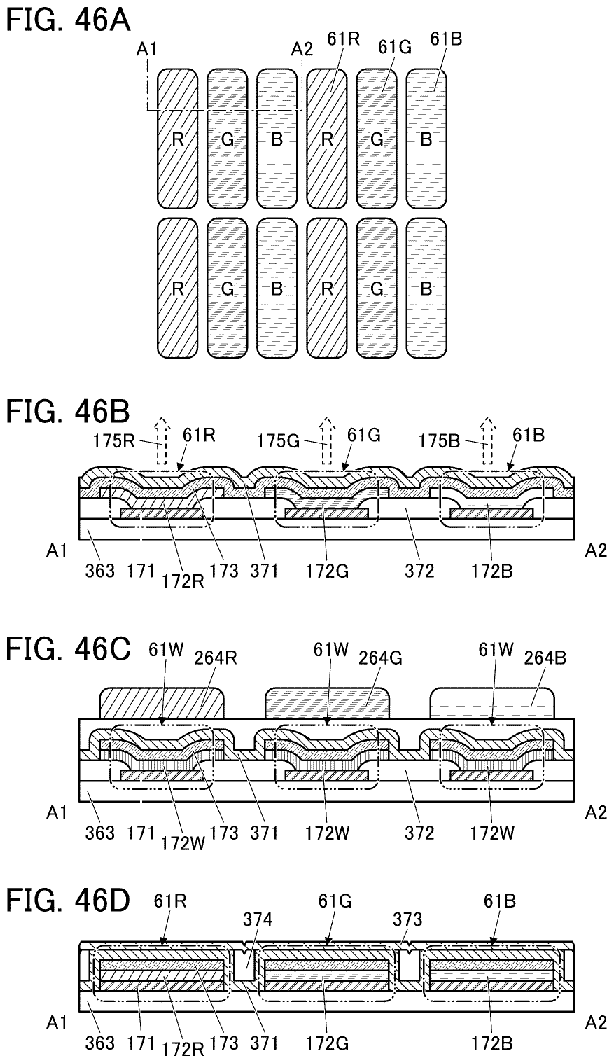

FIG. 46A is a schematic top view of the light-emitting element 61. The light-emitting element 61 includes a plurality of light-emitting elements 61R emitting red light, a plurality of light-emitting elements 61G emitting green light, and a plurality of light-emitting elements 61B emitting blue light. In FIG. 46A, light-emitting regions of the light-emitting elements are denoted by R, G, and B to easily differentiate the light-emitting elements. Although the structure exemplified in FIG. 46A has three emission colors of red (R), green (G), and blue (B), one embodiment of the present invention is not limited thereto. For example, the structure can have four or more colors.

The light-emitting elements 61R, the light-emitting elements 61G, and the light-emitting elements 61B are arranged in a matrix. Although FIG. 46A illustrates what is called stripe arrangement in which the light-emitting elements of the same color are arranged in one direction, the arrangement of the light-emitting elements is not limited thereto.

As the light-emitting elements 61R, 61G, and 61B, an organic EL device such as an OLED or a QLED is preferably used. Examples of a light-emitting substance contained in the EL element include a substance that emits fluorescent light (a fluorescent material), a substance that emits phosphorescent light (a phosphorescent material), and a substance that exhibits thermally activated delayed fluorescence (a thermally activated delayed fluorescent (TADF) material). Examples of the light-emitting substance contained in the EL element include not only organic compounds but also inorganic compounds (e.g., quantum dot materials).

FIG. 46B is a schematic cross-sectional view taken along the dashed-dotted line A1-A2 in FIG. 46A. FIG. 46B illustrates cross sections of the light-emitting elements 61R, 61G, and 61B. The light-emitting elements 61R, 61G, and 61B are provided over an insulating layer 363, and include the conductive layer 171 functioning as a pixel electrode and the conductive layer 173 functioning as a common electrode. For the insulating layer 363, one or both of an inorganic insulating film and an organic insulating film can be used. An inorganic insulating film is preferably used for the insulating layer 363. Examples of the inorganic insulating film include oxide insulating films and nitride insulating films, such as a silicon oxide film, a silicon oxynitride film, a silicon nitride oxide film, a silicon nitride film, an aluminum oxide film, an aluminum oxynitride film, and a hafnium oxide film.

The light-emitting element 61R includes an EL layer 172R between the conductive layer 171 functioning as a pixel electrode and the conductive layer 173 functioning as a common electrode. The EL layer 172R contains at least a light-emitting organic compound that emits light with a peak in a red wavelength range. An EL layer 172G included in the light-emitting element 61G contains at least a light-emitting organic compound that emits light with a peak in a green wavelength range. An EL layer 172B included in the light-emitting element 61B contains at least a light-emitting organic compound that emits light with a peak in a blue wavelength range.

The EL layers 172R, 172G, and 172B can each include one or more of an electron-injection layer, an electron-transport layer, a hole-injection layer, and a hole-transport layer in addition to the layer containing a light-emitting substance (the light-emitting layer).

The conductive layer 171 functioning as a pixel electrode is provided for each of the light-emitting elements. The conductive layer 173 functioning as a common electrode is provided as a continuous layer shared by the light-emitting elements. A conductive film that has a property of transmitting visible light is used for one of the conductive layer 171 functioning as a pixel electrode and the conductive layer 173 functioning as a common electrode, and a reflective conductive film is used for the other. When the conductive layer 171 functioning as a pixel electrode has a light-transmitting property and the conductive layer 173 functioning as a common electrode has a reflective property, a bottom-emission display device can be obtained. When the conductive layer 171 functioning as a pixel electrode has a reflective property and the conductive layer 173 functioning as a common electrode has a light-transmitting property, a top-emission display device can be obtained. Note that when both the conductive layer 171 functioning as a pixel electrode and the conductive layer 173 functioning as a common electrode have light-transmitting properties, a dual-emission display device can be obtained.

For example, in the case where the light-emitting element 61R has a top-emission structure, light 175R is emitted from the light-emitting element 61R to the conductive layer 173 side. In the case where the light-emitting element 61G has a top-emission structure, light 175G is emitted from the light-emitting element 61G to the conductive layer 173 side. In the case where the light-emitting element 61B has a top-emission structure, light 175B is emitted from the light-emitting element 61B to the conductive layer 173 side.

An insulator 372 is provided to cover an end portion of the conductive layer 171 functioning as a pixel electrode. An end portion of the insulator 372 is preferably tapered. For the insulator 372, a material similar to the material that can be used for the insulating layer 363 can be used.

The insulator 372 is provided to prevent an unintentional electric short-circuit between adjacent light-emitting elements 61 and unintended light emission therefrom. The insulator 372 also has a function of preventing the contact of a metal mask with the conductive layer 171 in the case where the metal mask is used to form the EL layer 172.

The EL layers 172R, 172G, and 172B each include a region in contact with the top surface of the conductive layer 171 functioning as a pixel electrode and a region in contact with a surface of the insulator 372. End portions of the EL layers 172R, 172G, and 172B are positioned over the insulator 372.

As illustrated in FIG. 46B, there is a gap between the EL layers of two light-emitting elements with different emission colors. The EL layers 172R, 172G, and 172B are thus preferably provided not to be in contact with each other. This suitably prevents unintentional light emission (also referred to as crosstalk) from being caused by current flowing through two adjacent EL layers. As a result, the contrast can be increased to achieve a display device with high display quality.

The EL layers 172R, 172G, and 172B can be formed separately by a vacuum evaporation method or the like using a shadow mask such as a metal mask. These layers can also be formed separately by a photolithography method. The use of a photolithography method achieves a display device with high resolution, which is difficult to obtain in the case of using a metal mask.

In this specification and the like, a device formed using a metal mask or a fine metal mask (FMM) may be referred to as a device having a metal mask (MM) structure. In this specification and the like, a device formed without using a metal mask or an FMM may be referred to as a device having a metal maskless (MML) structure. A display device having an MML structure is fabricated without using a metal mask and thus has higher flexibility in designing the pixel arrangement, the pixel shape, and the like than a display device having an MM structure.

A protective layer 371 is provided over the conductive layer 173 functioning as a common electrode to cover the light-emitting elements 61R, 61G, and 61B. The protective layer 371 has a function of preventing diffusion of impurities such as water into the light-emitting elements from the above.

The protective layer 371 can have, for example, a single-layer structure or a stacked-layer structure at least including an inorganic insulating film. Examples of the inorganic insulating film include oxide films and nitride films, such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as indium gallium oxide or indium gallium zinc oxide (IGZO) can be used for the protective layer 371. The protective layer 371 can be formed by an atomic layer deposition (ALD) method, a chemical vapor deposition (CVD) method, or a sputtering method. Although the protective layer 371 includes an inorganic insulating film in this example, one embodiment of the present invention is not limited thereto. For example, the protective layer 371 can have a stacked-layer structure of an inorganic insulating film and an organic insulating film.

Note that in this specification, a nitride oxide refers to a compound in which the nitrogen content is higher than the oxygen content. An oxynitride refers to a compound in which the oxygen content is higher than the nitrogen content. The content of each element can be measured by Rutherford backscattering spectrometry (RBS), for example.

In the case where indium gallium zinc oxide is used for the protective layer 371, processing can be performed by a wet etching method or a dry etching method. For example, in the case where IGZO is used for the protective layer 371, a chemical solution of oxalic acid, phosphoric acid, a mixed chemical solution (e.g., a mixed chemical solution of phosphoric acid, acetic acid, nitric acid, and water, which is also referred to as a mixed acid aluminum etchant), or the like can be used. Note that the volume ratio between phosphoric acid, acetic acid, nitric acid, and water mixed in the mixed acid aluminum etchant can be 53.3:6.7:3.3:36.7 or in the neighborhood thereof.

Note that the structure illustrated in FIG. 46B may be referred to as an SBS structure described later.

FIG. 46C illustrates an example different from the above example. Specifically, in FIG. 46C, a light-emitting element 61W emitting white light is provided. The light-emitting element 61W includes an EL layer 172W emitting white light between the conductive layer 171 functioning as a pixel electrode and the conductive layer 173 functioning as a common electrode.

The EL layer 172W can have, for example, a stacked-layer structure of two or more light-emitting layers that are selected so as to emit light of complementary colors. It is also possible to use a stacked EL layer in which a charge-generation layer is provided between light-emitting layers.

FIG. 46C illustrates three light-emitting elements 61W side by side. A coloring layer 264R is provided above the left light-emitting element 61W. The coloring layer 264R functions as a band pass filter transmitting red light. Similarly, a coloring layer 264G transmitting green light is provided above the middle light-emitting element 61W, and a coloring layer 264B transmitting blue light is provided above the right light-emitting element 61W. This enables the display device to display color images.

The EL layer 172W and the conductive layer 173 functioning as a common electrode are each separated between two adjacent light-emitting elements 61W. This can prevent unintentional light emission from being caused by current flowing through the EL layers 172W in the two adjacent light-emitting elements 61W. Particularly when the EL layer 172W is a stacked EL layer in which a charge-generation layer is provided between two light-emitting layers, the effect of crosstalk is more significant as the resolution increases, i.e., as the distance between adjacent pixels decreases, leading to lower contrast. Thus, the above structure can achieve a display device having both high resolution and high contrast.

The EL layer 172W and the conductive layer 173 functioning as a common electrode are each preferably separated by a photolithography method. This can reduce the distance between light-emitting elements, achieving a display device with a higher aperture ratio than that formed using, for example, a shadow mask such as a metal mask.

Note that in the case of a bottom-emission light-emitting element, coloring layers are provided between the conductive layer 171 functioning as a pixel electrode and the insulating layer 363.

FIG. 46D illustrates an example different from the above example. Specifically, in FIG. 46D, the insulators 372 are not provided between the light-emitting elements 61R, 61G, and 61B. With such a structure, a display device with a high aperture ratio can be obtained. When the insulator 372 is not provided, unevenness formed by the light-emitting elements 61 can be reduced, thereby improving the viewing angle of the display device. Specifically, the viewing angle can be greater than or equal to 150° and less than 180°, preferably greater than or equal to 160° and less than 180°.

The protective layer 371 covers the side surfaces of the EL layers 172R, 172G, and 172B. With this structure, impurities (typically, water or the like) can be inhibited from entering the EL layers 172R, 172G, and 172B through their side surfaces. In addition, leakage current between adjacent light-emitting elements 61 is reduced, so that color saturation and contrast ratio are improved and power consumption is reduced.

In the structure illustrated in FIG. 46D, the conductive layer 171, the EL layer 172R, and the conductive layer 173 have substantially the same planar shapes. This structure can be formed in the following manner: the conductive layer 171, the EL layer 172R, and the conductive layer 173 are formed, and collectively processed using a resist mask or the like. In this process, the EL layer 172R and the conductive layer 171 are processed using the conductive layer 173 as a mask, and thus this process can be called self-alignment patterning. Although the EL layer 172R is described here, the EL layer 172G and the EL layer 172B can each have a similar structure.

In FIG. 46D, a protective layer 373 is further provided over the protective layer 371. For example, the protective layer 371 is formed with an apparatus that can form a film with excellent coverage (typically, an ALD apparatus or the like), and the protective layer 373 is formed with an apparatus that can form a film with coverage inferior to that of the protective layer 371 (typically, a sputtering apparatus or the like), whereby a region 374 can be provided between the protective layer 371 and the protective layer 373. In other words, the regions 374 are positioned between the EL layer 172R and the EL layer 172G and between the EL layer 172G and the EL layer 172B.

Note that the region 374 contains, for example, one or more selected from air, nitrogen, oxygen, carbon dioxide, and Group 18 elements (typically, helium, neon, argon, xenon, and krypton). Furthermore, a gas used during the formation of the protective layer 373 is sometimes contained in the region 374. For example, in the case where the protective layer 373 is formed by a sputtering method, one or more of the above-described Group 18 elements may be contained in the region 374. In the case where a gas is contained in the region 374, the gas can be identified with a gas chromatography method or the like. Alternatively, in the case where the protective layer 373 is formed by a sputtering method, a gas used in the sputtering is sometimes contained also in the protective layer 373. In that case, an element such as argon may be detected when the protective layer 373 is analyzed by energy dispersive X-ray analysis (EDX analysis) or the like.

In the case where the refractive index of the region 374 is lower than that of the protective layer 371, light emitted from the EL layer 172R, the EL layer 172G, or the EL layer 172B is reflected at the interface between the protective layer 371 and the region 374. Thus, light emitted from the EL layer 172R, the EL layer 172G, or the EL layer 172B can be inhibited from entering an adjacent pixel in some cases. This can inhibit color mixture of light emitted from adjacent pixels and thus can improve the display quality of the display device.

In the structure illustrated in FIG. 46D, a region between the light-emitting elements 61R and 61G or a region between the light-emitting elements 61G and 61B (hereinafter, simply referred to as a distance between the light-emitting elements) can be shortened. Specifically, the distance between the light-emitting elements can be 1 μm or shorter, preferably 500 nm or shorter, further preferably 200 nm or shorter, 100 nm or shorter, 90 nm or shorter, 70 nm or shorter, 50 nm or shorter, 30 nm or shorter, 20 nm or shorter, 15 nm or shorter, or 10 nm or shorter. In other words, the display device includes a region in which an interval between the side surface of the EL layer 172R and the side surface of the EL layer 172G or an interval between the side surface of the EL layer 172G and the side surface of the EL layer 172B is 1 μm or shorter, preferably 0.5 μm (500 nm) or shorter, further preferably 100 nm or shorter.

In the case where the region 374 contains a gas, for example, the light-emitting elements can be isolated from each other and color mixture of light from the light-emitting elements, crosstalk, or the like can be inhibited.

The region 374 may be a space or may be filled with a filler. Examples of the filler include an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin. Alternatively, a photoresist can be used as the filler. The photoresist used as the filler may be either a positive photoresist or a negative photoresist.

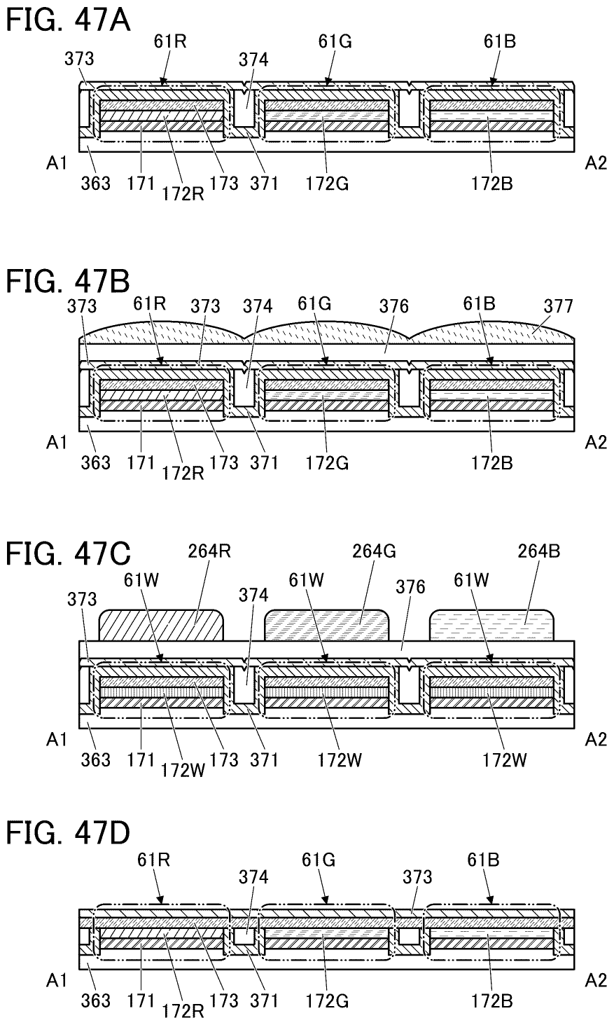

FIG. 47A illustrates an example different from the above example. Specifically, the structure illustrated in FIG. 47A is different from that in FIG. 46D in the structure of the insulating layer 363. The insulating layer 363 has a depressed portion in its top surface that is formed by being partially etched when the light-emitting elements 61R, 61G, and 61B are processed. In addition, the protective layer 371 is formed in the depressed portion. In other words, in the cross-sectional view, there is a region in which the bottom surface of the protective layer 371 is positioned below the bottom surface of the conductive layer 171. With the region, impurities (typically, water or the like) can be suitably inhibited from entering the light-emitting elements 61R, 61G, and 61B from the bottom. It is likely that the depressed portion can be formed when impurities (also referred to as residue) that could be attached to the side surfaces of the light-emitting elements 61R, 61G, and 61B in processing of the light-emitting elements are removed by wet etching or the like. After the residue is removed, the side surfaces of the light-emitting elements are covered with the protective layer 371, whereby a highly reliable display device can be provided.

FIG. 47B illustrates an example different from the above example. Specifically, the structure illustrated in FIG. 47B includes an insulator 376 and a microlens array 377 in addition to the structure illustrated in FIG. 47A. The insulator 376 has a function of an adhesive layer. Note that when the refractive index of the insulator 376 is lower than that of the microlens array 377, the microlens array 377 can condense light emitted from the light-emitting elements 61R, 61G, and 61B. This can increase the light extraction efficiency of the display device. This is particularly suitable when a user sees a display surface from the front of the display surface of the display device because the user can see bright images. As the insulator 376, various curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin. In particular, a material with low moisture permeability, such as an epoxy resin, is preferable. A two-component-mixture-type resin can be used. An adhesive sheet or the like can be used.

FIG. 47C illustrates an example different from the above example. Specifically, the structure illustrated in FIG. 47C includes three light-emitting elements 61W instead of the light-emitting elements 61R, 61G, and 61B in the structure illustrated in FIG. 47A. In addition, the insulator 376 is provided over the three light-emitting elements 61W, and the coloring layers 264R, 264G, and 264B are provided over the insulator 376. Specifically, the coloring layer 264R transmitting red light is provided at a position overlapping with the left light-emitting element 61W, the coloring layer 264G transmitting green light is provided at a position overlapping with the middle light-emitting element 61W, and the coloring layer 264B transmitting blue light is provided at a position overlapping with the right light-emitting element 61W. This enables the display device to display color images. The structure illustrated in FIG. 47C is also a modification example of the structure illustrated in FIG. 46C.

FIG. 47D illustrates an example different from the above example. Specifically, in the structure illustrated in FIG. 47D, the protective layer 371 is provided adjacent to the side surfaces of the conductive layer 171 and the EL layer 172. The conductive layer 173 is provided as a continuous layer shared by the light-emitting elements. In the structure illustrated in FIG. 47D, the region 374 is preferably filled with a filler.

When the light-emitting element 61 has a micro-optical resonator (microcavity) structure, the color purity of each emission color can be increased. In order that the light-emitting element 61 can have a microcavity structure, a product of a distance d between the conductive layers 171 and 173 and a refractive index n of the EL layer 172 (optical path length) is preferably set to m times greater than the half of a wavelength λ (m is an integer of 1 or more). The distance d can be obtained by Formula 1.

$$d = m \times λ / ( 2 \times n ) \qquad Formula 1$$

According to Formula 1, in the light-emitting element 61 having the microcavity structure, the distance d depends on the wavelength (color) of emitted light. The distance d corresponds to the thickness of the EL layer 172. Thus, the EL layer 172G is provided to have a larger thickness than the EL layer 172B, and the EL layer 172R is provided to have a larger thickness than the EL layer 172G, in some cases.

To be exact, the distance d is a distance from a reflection region in the conductive layer 171 functioning as a reflective electrode to a reflection region in the conductive layer 173 functioning as an electrode having properties of transmitting and reflecting emitted light (a transflective electrode). For example, in the case where the conductive layer 171 is a stack of silver and indium tin oxide (ITO) that is a transparent conductive film and the ITO is positioned on the EL layer 172 side, the distance d suitable for the emission color can be set by adjusting the thickness of the ITO. That is, even when the EL layers 172R, 172G, and 172B have the same thickness, the distance d suitable for the emission color can be obtained by adjusting the thickness of the ITO.

However, it is sometimes difficult to determine the exact position of the reflection region in each of the conductive layers 171 and 173. In that case, it is assumed that the effect of the microcavity structure can be obtained sufficiently with a certain position in each of the conductive layers 171 and 173 being supposed as the reflection region.

The light-emitting element 61 includes a hole-injection layer, a hole-transport layer, a light-emitting layer, an electron-transport layer, an electron-injection layer, and the like. A specific structure example of the light-emitting element 61 is described in another embodiment. In order to increase the light extraction efficiency in the microcavity structure, the optical path length from the conductive layer 171 functioning as a reflective electrode to the light-emitting layer is preferably set to an odd multiple of λ/4. In order to achieve this optical path length, the thicknesses of the layers in the light-emitting element 61 are preferably adjusted as appropriate. In the case where light is emitted from the conductive layer 173 side, the reflectance of the conductive layer 173 is preferably higher than the transmittance thereof. The light transmittance of the conductive layer 173 is preferably higher than or equal to 2% and lower than or equal to 50%, further preferably higher than or equal to 2% and lower than or equal to 30%, still further preferably higher than or equal to 2% and lower than or equal to 10%. When the transmittance of the conductive layer 173 is set low (the reflectance is set high), the effect of the microcavity structure can be enhanced.

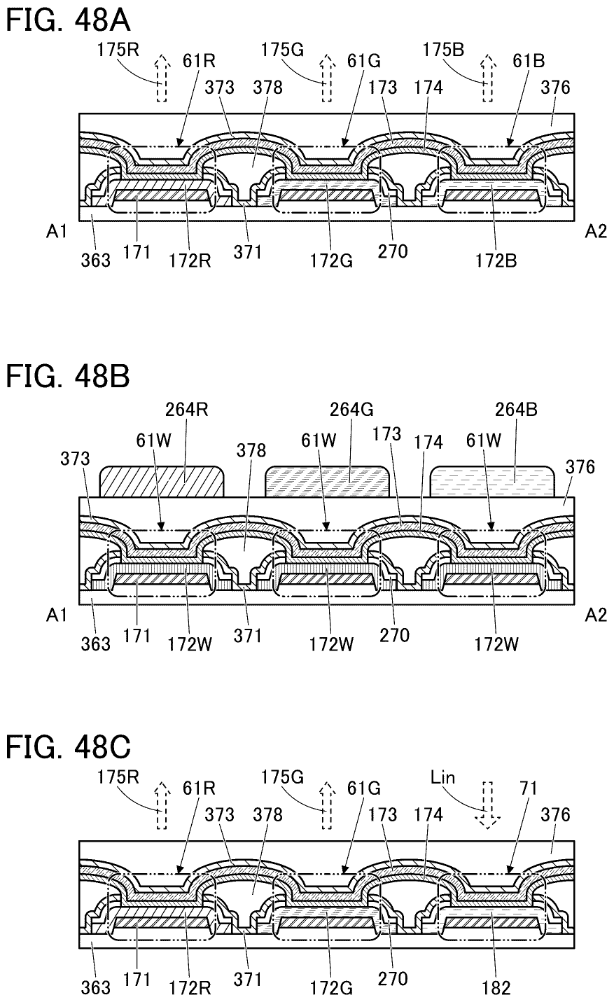

FIG. 48A illustrates an example different from the above example. Specifically, in the structure illustrated in FIG. 48A, the EL layer 172 extends beyond an end portion of the conductive layer 171 in each of the light-emitting elements 61R, 61G, and 61B. For example, in the light-emitting element 61R, the EL layer 172R extends beyond the end portion of the conductive layer 171. In the light-emitting element 61G, the EL layer 172G extends beyond the end portion of the conductive layer 171. In the light-emitting element 61B, the EL layer 172B extends beyond the end portion of the conductive layer 171.

The light-emitting elements 61R, 61G, and 61B each include a region where the EL layer 172 and the protective layer 371 overlap with each other with an insulating layer 270 therebetween. In a region between adjacent light-emitting elements 61, an insulator 378 is provided over the protective layer 371.

For the insulator 378, an epoxy resin, an acrylic resin, a silicone resin, a phenol resin, a polyimide resin, an imide resin, a polyvinyl chloride (PVC) resin, a polyvinyl butyral (PVB) resin, an ethylene vinyl acetate (EVA) resin, and the like can be used. Alternatively, a photoresist can be used as the insulator 378. The photoresist used as the insulator 378 may be either a positive photoresist or a negative photoresist.

A common layer 174 is provided over the light-emitting elements 61R, 61G, and 61B and the insulator 378, and the conductive layer 173 is provided over the common layer 174. The common layer 174 includes a region in contact with the EL layer 172R, a region in contact with the EL layer 172G, and a region in contact with the EL layer 172B. The common layer 174 is shared by the light-emitting elements 61R, 61G, and 61B.

One or more of a hole-injection layer, a hole-transport layer, a hole-blocking layer, an electron-blocking layer, an electron-transport layer, and an electron-injection layer can be used as the common layer 174. For example, the common layer 174 may be a carrier-injection layer (a hole-injection layer or an electron-injection layer). The common layer 174 can also be regarded as part of the EL layer 172. Note that the common layer 174 is provided as necessary. In the case where the common layer 174 is provided, a layer having the same function as the common layer 174 is not necessarily provided in the EL layer 172.

In addition, the protective layer 373 is provided over the conductive layer 173, and the insulator 376 is provided over the protective layer 373.

FIG. 48B illustrates an example different from the above example. Specifically, the structure illustrated in FIG. 48B includes three light-emitting elements 61W instead of the light-emitting elements 61R, 61G, and 61B in the structure illustrated in FIG. 48A. In addition, the insulator 376 is provided over the three light-emitting elements 61W, and the coloring layers 264R, 264G, and 264B are provided over the insulator 376. Specifically, the coloring layer 264R transmitting red light is provided at a position overlapping with the left light-emitting element 61W, the coloring layer 264G transmitting green light is provided at a position overlapping with the middle light-emitting element 61W, and the coloring layer 264B transmitting blue light is provided at a position overlapping with the right light-emitting element 61W. This enables the display device to display color images. The structure illustrated in FIG. 48B is also a modification example of the structure illustrated in FIG. 47C.

As illustrated in FIG. 48C, the light-emitting element 61R, the light-emitting element 61G, and a light-receiving element 71 can be provided over the insulating layer 363. The light-receiving element 71 illustrated in FIG. 48C is achieved by replacing the EL layer 172 of the light-emitting element 61 with an active layer 182 (also referred to as a “light-receiving layer”) functioning as a photoelectric conversion layer. The active layer 182 has a feature of changing a resistance value depending on the wavelength and intensity of the incident light. Like the EL layer 172, the active layer 182 can be formed using an organic compound. Note that an inorganic material such as silicon can also be used for the active layer 182.

The light-receiving element 71 has a function of sensing light Lin entering from the outside of the display device and passing through the protective layer 373, the conductive layer 173, and the common layer 174. A coloring layer transmitting light in a given wavelength range is preferably provided on the incident side of the light Lin so as to overlap with the light-receiving element 71.

<Materials that can be Used for Light-Emitting Element>

Materials that can be used for the light-emitting element will be described.

A hole-injection layer injects holes from an anode to a hole-transport layer and contains a material with a high hole-injection property. Examples of the material with a high hole-injection property include an aromatic amine compound and a composite material containing a hole-transport material and an acceptor material (electron-accepting material).

A hole-transport layer transports holes injected from an anode by a hole-injection layer to a light-emitting layer. The hole-transport layer contains a hole-transport material. The hole-transport material preferably has a hole mobility higher than or equal to 1×10⁻⁶ cm²/Vs. Note that other substances can also be used as long as the substances have a hole-transport property higher than an electron-transport property. As the hole-transport material, materials having a high hole-transport property, such as a π-electron rich heteroaromatic compound (e.g., a carbazole derivative, a thiophene derivative, and a furan derivative) and an aromatic amine (a compound having an aromatic amine skeleton), are preferable.

An electron-transport layer transports electrons injected from a cathode by an electron-injection layer to a light-emitting layer. The electron-transport layer contains an electron-transport material. The electron-transport material preferably has an electron mobility higher than or equal to 1×10⁻⁶ cm²/Vs. Note that other substances can also be used as long as the substances have an electron-transport property higher than a hole-transport property. As the electron-transport material, any of the following materials having a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a π-electron deficient heteroaromatic compound such as a nitrogen-containing heteroaromatic compound.

An electron-injection layer injects electrons from a cathode to an electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, x is a given number), 8-(quinolinolato) lithium (abbreviation: Liq), 2-(2-pyridyl) phenolatolithium (abbreviation: LiPP), 2-(2-pyridyl)-3-pyridinolatolithium (abbreviation: LiPPy), 4-phenyl-2-(2-pyridyl) phenolatolithium (abbreviation: LiPPP), lithium oxide (LiOₓ), or cesium carbonate, for example. The electron-injection layer can have a stacked-layer structure of two or more layers. In the stacked-layer structure, for example, lithium fluoride can be used for the first layer and ytterbium can be used for the second layer.

Alternatively, the electron-injection layer can be formed using an electron-transport material. For example, a compound having an unshared electron pair and an electron deficient heteroaromatic ring can be used as the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) of the organic compound having an unshared electron pair is preferably greater than or equal to −3.6 eV and less than or equal to −2.3 eV. In general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), diquinoxalino[2,3-a: 2′,3′-c]phenazine (abbreviation: HATNA), or 2,4,6-tris[3′-(pyridin-3-yl) biphenyl-3-yl]-1,3,5-triazine (abbreviation: TmPPPyTz) can be used as the organic compound having an unshared electron pair. Note that NBPhen has a higher glass transition point (Tg) than BPhen and thus has high heat resistance.

### <Example of Circuit Configuration of Display Device>

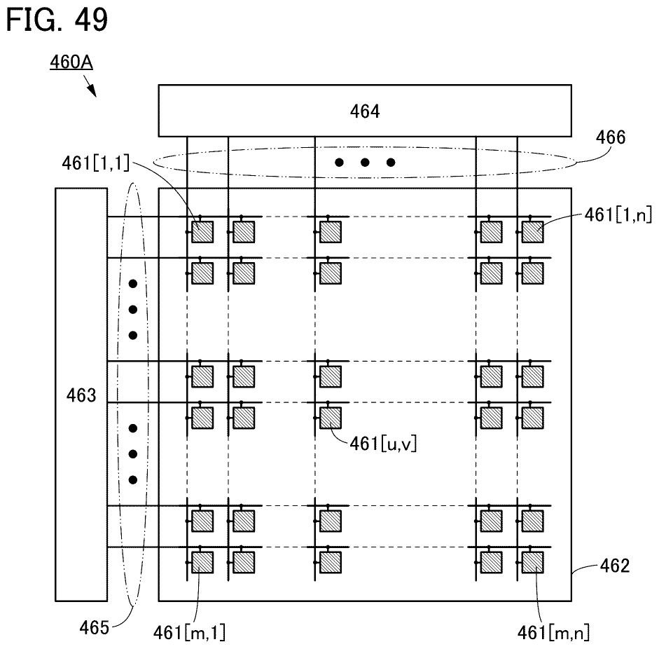

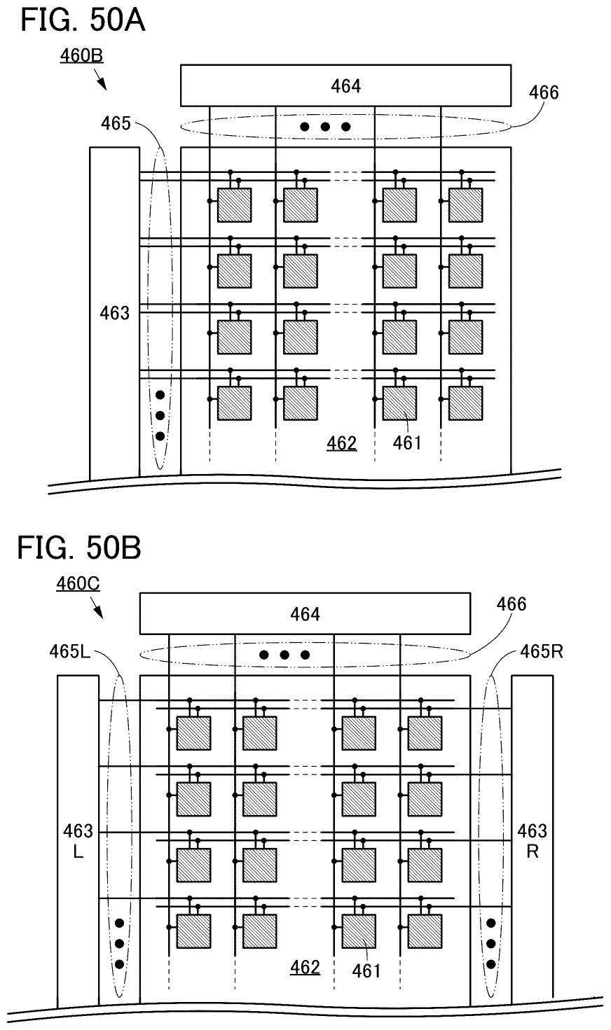

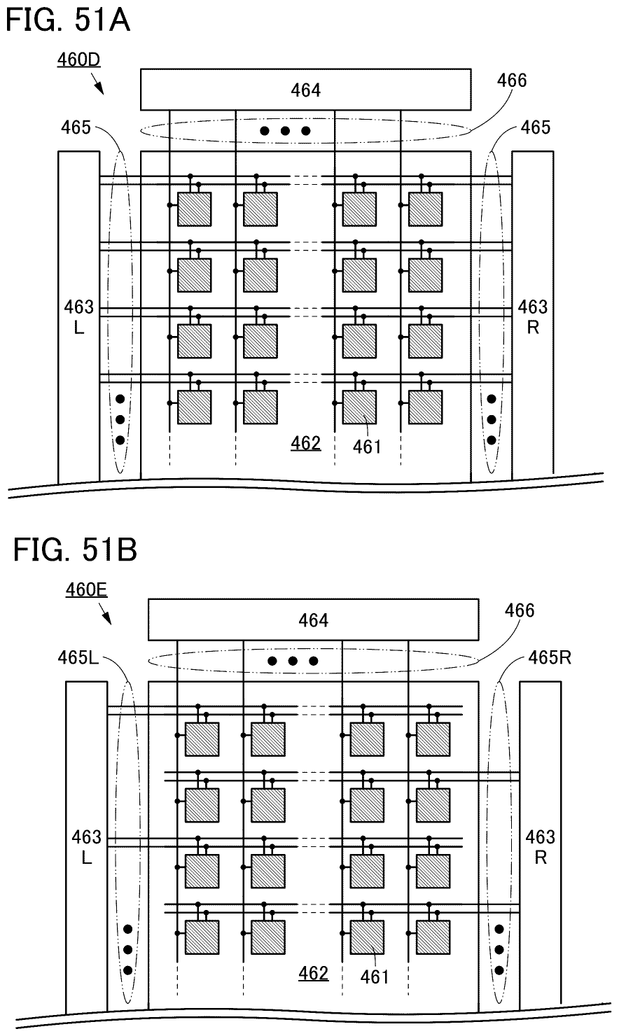

FIG. 49, FIGS. 50A and 50B, and FIGS. 51A and 51B are block diagrams illustrating examples of a circuit configuration of a display device 460 (display devices 460A to 460E) that can be used as the display device 400 of one embodiment of the present invention.

As illustrated in FIG. 49, the display device 460A includes a display portion 462, a first driver circuit portion 463, and a second driver circuit portion 464. For example, the display portion 462 includes a plurality of pixels 461 arranged in a matrix of m rows and n columns (m and n are each an integer greater than or equal to 2).

In the case where at least part of the display device 460A is used for the display device 400 described above, the pixels 461 correspond to the pixels 453, the display portion 462 corresponds to the display portion 452, the first driver circuit portion 463 corresponds to the circuit portion 454a, and the second driver circuit portion 464 corresponds to the circuit portion 454b. Thus, the semiconductor device 10 of one embodiment of the present invention can be used as each of the pixels 461. Note that the first driver circuit portion 463 and the second driver circuit portion 464 each include at least part of the IC 456 in some cases.

In FIG. 49, the pixel 461 placed in the first row and the first column is denoted as a pixel 461[1,1], the pixel 461 placed in the first row and the n-th column is denoted as a pixel 461[1,n], the pixel 461 placed in the m-th row and the first column is denoted as a pixel 461[m,1], and the pixel 461 placed in the m-th row and the n-th column is denoted as a pixel 461[m,n]. Note that the pixel 461 placed in the u-th row and the v-th column is denoted as a pixel 461[u,v] (u is an integer greater than or equal to 1 and less than or equal to m and v is an integer greater than or equal to 1 and less than or equal to n) in some cases.

The display device 460 includes m wirings 465 which are arranged parallel or substantially parallel to each other and whose potentials are controlled by a circuit included in the first driver circuit portion 463. The potential of one wiring 465 is supplied to n pixels 461 arranged in the row direction. Note that a plurality of wirings can form one wiring 465 depending on the structures of the pixels 461. In the structure example of the display device 460B illustrated in FIG. 50A, two wirings form one wiring 465.

The display device 460 includes n wirings 466 which are arranged parallel or substantially parallel to each other and whose potentials are controlled by a circuit included in the second driver circuit portion 464. The potential of one wiring 466 is supplied to m pixels 461 arranged in the column direction. Note that a plurality of wirings can form one wiring 466 depending on the structures of the pixels 461.

The pixels 461 each have a function of making a light-emitting element emit light with emission intensity corresponding to a video signal that is written through the wiring 466 to a pixel circuit selected by the potential of the wiring 465, for example.

The circuit included in the first driver circuit portion 463 functions as, for example, a scan line driver circuit (sometimes referred to as a gate line driver circuit, a gate driver, a scan driver, or a row driver).

The circuit included in the second driver circuit portion 464 functions as, for example, a signal line driver circuit (sometimes referred to as a source line driver circuit, a source driver, a data driver, or a column driver). For example, the circuit can have a function of converting data of an image to be displayed on the display device 460 into a video signal to be supplied to each pixel (i.e., a function of performing digital-to-analog conversion).

In each of the pixels 461, current flowing through the light-emitting element can be output to a monitor line (not illustrated), for example. The current output to the monitor line can be output to the outside of the display device 460 after being subjected to conversion into an analog voltage (current-to-voltage conversion) or into a digital signal (analog-to-digital conversion) in the second driver circuit portion 464, for example. The analog voltage or the digital signal can be used for video signal correction outside the display device (also referred to as external correction), for example.

In one embodiment of the present invention, any of various structures can be employed for modification examples of the display device 460. For example, as illustrated in FIG. 50B and FIGS. 51A and 51B, a first driver circuit portion 463L and a first driver circuit portion 463R can be arranged to face each other across the display portion 462.

The display device 460C illustrated in FIG. 50B includes m wirings 465L whose potentials are controlled by a circuit included in the first driver circuit portion 463L and m wirings 465R whose potentials are controlled by a circuit included in the first driver circuit portion 463R. The potentials of one wiring 465L and one wiring 465R are supplied to n pixels 461 arranged in the row direction.

The display device 460D illustrated in FIG. 51A includes m wirings 465 whose potentials are controlled by both the circuit included in the first driver circuit portion 463L and the circuit included in the first driver circuit portion 463R. The potential of one wiring 465 is supplied to n pixels 461 arranged in the row direction. With such a structure, substantial loads on the wiring (parasitic capacitance and parasitic resistance) can be reduced to one-quarter, for example. Accordingly, the display device can achieve higher speed, higher resolution, higher definition, a narrower bezel, and a larger screen, for example.

The display device 460E illustrated in FIG. 51B includes m wirings 465L whose potentials are controlled by the circuit included in the first driver circuit portion 463L and m wirings 465R whose potentials are controlled by the circuit included in the first driver circuit portion 463R. The potential of one wiring 465L is supplied to n pixels 461 arranged in odd-numbered rows in the row direction. The potential of one wiring 465R is supplied to n pixels 461 arranged in even-numbered rows in the row direction. Such a structure can halve the number of stages of a shift register, for example. Accordingly, the display device can achieve higher speed, higher resolution, higher definition, a narrower bezel, and a larger screen, for example.

Although not illustrated, for example, two second driver circuit portions 464 can be arranged to face each other across the display portion 462.

According to one embodiment of the present invention, for example, the display device 460 can not only have any of various structures described above but also include a sensor portion provided to overlap with the display portion 462 in a top view. The sensor portion can function as, for example, a touch sensor, a near touch sensor, or a fingerprint sensor. Such a sensor can be a capacitive touch sensor or an optical touch sensor, for example.

In the display device 460 provided with the sensor portion, the first driver circuit portion 463 (or the first driver circuit portions 463L and 463R) can include a circuit having a function of driving the sensor portion, for example. The second driver circuit portion 464 can include a circuit having a function of outputting a signal sensed by the sensor portion to the outside of the display device, for example.

### [Peripheral Driver Circuit]

Next, configuration examples of constituent circuits that can be used for a peripheral driver circuit included in the display device 460 will be described.

In this specification and the like, the circuits included in the first driver circuit portion 463 and the second driver circuit portion 464 in the display device 460 are sometimes collectively referred to as a “peripheral driver circuit”.

The peripheral driver circuit can be formed using various constituent circuits. Examples of the constituent circuits include a shift register circuit, a flip-flop circuit, a latch circuit, a buffer circuit, an inverter circuit, and a level shifter circuit. Other examples include a multiplexer circuit, a demultiplexer circuit, a source follower circuit, a source-grounded amplifier circuit, a sample-and-hold circuit, and a switch circuit (e.g., a transmission gate and an analog switch). Other examples include a current-to-voltage converter circuit, an analog-to-digital converter circuit, a digital-to-analog converter circuit, an operational amplifier circuit, a comparator circuit, a pass transistor logic circuit, an encoder circuit, a decoder circuit, and a gate circuit (e.g., an AND circuit, an OR circuit, and a NOT circuit). Other examples include circuits combining these circuits. Note that these constituent circuits can be formed using, for example, a transistor, a capacitor, and the like.

In one embodiment of the present invention, various transistors can be used as transistors included in the peripheral driver circuit. For example, a vertical transistor like the transistor 200C or the transistor 200D described above can be used as some or all of the transistors included in the peripheral driver circuit.

The use of a vertical transistor as some or all of the transistors included in the peripheral driver circuit can reduce the area occupied by a buffer circuit or the like included in the circuit included in the first driver circuit portion 463, for example. Accordingly, the display device can have a narrower bezel, for example. In addition, the area occupied by a demultiplexer, a source follower, and the like included in the circuit included in the second driver circuit portion 464 can be reduced, for example. This leads to higher definition and higher resolution of the display device.

As some or all of the transistors included in the peripheral driver circuit, an OS transistor can be used, for example. For another example, both an OS transistor and a Si transistor can be used.

As described above, an OS transistor has a feature of an extremely low off-state current. In addition, the off-state current of an OS transistor hardly increases and the on-state current thereof is unlikely to decrease even in a high-temperature environment. A Si transistor has higher operation speed than an OS transistor. A gate of an n-channel Si transistor and a gate of a p-channel Si transistor can be connected to each other, for example, to form a CMOS circuit (e.g., a circuit where the transistors operate complementarily, a CMOS logic gate, or a CMOS logic circuit).

A CMOS circuit can also be formed using an OS transistor as an n-channel transistor and a Si transistor as a p-channel transistor. The combination of an OS transistor and a Si transistor enables a semiconductor device to have low power consumption and high operation speed. Thus, an OS transistor and a Si transistor are used as the transistors included in the peripheral driver circuit as appropriate depending on the specifications of the display device.

### [Shift Register]

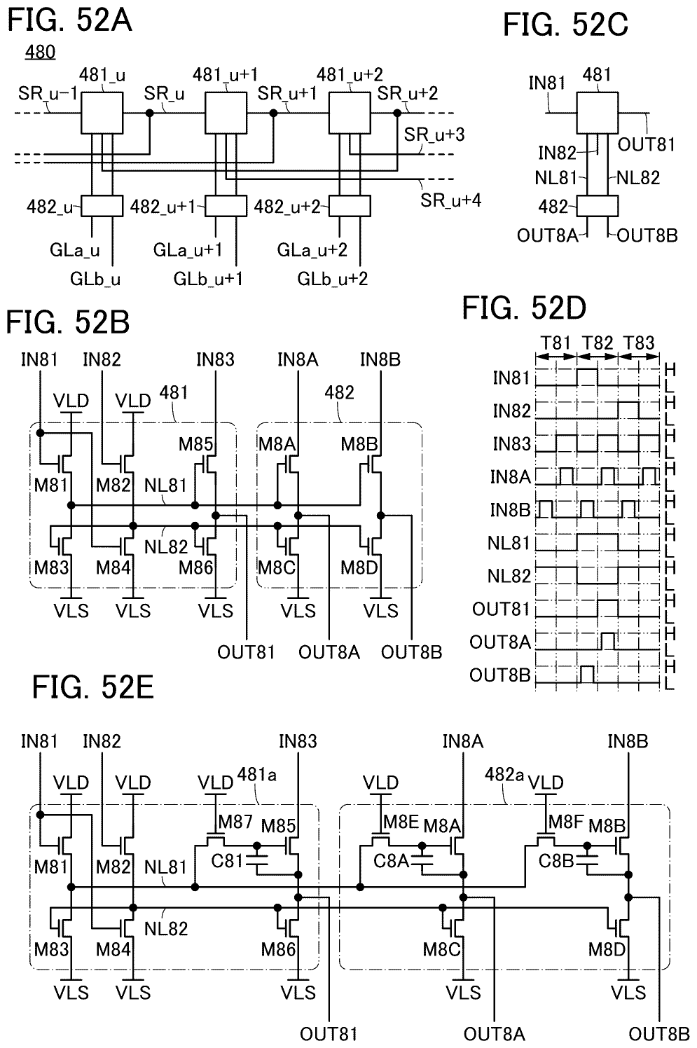

FIGS. 52A to 52E are circuit diagrams illustrating configuration examples of a semiconductor device that can be used for the peripheral driver circuit. The semiconductor device can be used as part of the scan line driver circuit (e.g., the circuit included in the first driver circuit portion 463) or as part of a shift register, for example.

A semiconductor device 480 illustrated in FIG. 52A includes m register portions 481 and m buffer portions 482. The semiconductor device 480 is connected to m wirings GLa and m wirings GLb. The m register portions 481 are connected to each other through m wirings SR. FIG. 52A illustrates register portions 481_u to 481_u+2, buffer portions 482_u to 482_u+2, wirings SR_u−1 to SR_u+4, wirings GLa_u to GLa_u+2, and wirings GLb_u to GLb_u+2, which are components of the semiconductor device 480. Note that m is an integer greater than or equal to 2. In addition, u is an integer greater than or equal to 1 and less than or equal to m. Note that u+α (α is an integer greater than or equal to 1) does not exceed m. In addition, u−α is not below 1.

FIG. 52B is a circuit diagram illustrating a configuration example of the register portion 481 and the buffer portion 482. FIG. 52C is a circuit block corresponding to the register portion 481 and the buffer portion 482. The register portion 481 can be used as each of register portions 481_1 to 481_m. The buffer portion 482 can be used as each of buffer portions 482_1 to 482_m. That is, in the register portion 481_u, a wiring IN81 is connected to the wiring SR_u−1, a wiring IN82 is connected to the wiring SR_u+2, and a wiring OUT81 is connected to the wiring SR_u, for example. In the buffer portion 482_u, for example, a wiring OUT8A is connected to the wiring GLa_u and a wiring OUT8B is connected to the wiring GLb_u. Note that the wiring IN81, a wiring IN8A, a wiring IN8B, a wiring VLD, and a wiring VLS are not illustrated in FIGS. 52A and 52C. The same applies to the register portions 481_1 to 481_u−1, the register portions 481_u+1 to 481_m, the buffer portions 482_1 to 482_u−1, and the buffer portions 482_u+1 to 482_m.

That is, in the semiconductor device 480, the wiring OUT81 in the register portion 481_u−1 is connected to the wiring IN81 in the register portion 481_u through the wiring SR_u−1, and the wiring OUT81 in the register portion 481_u is connected to the wiring IN81 in the register portion 481_u+1 through the wiring SR_u. In such a configuration, the register portions 481_1 to 481_m are selected sequentially, and a desired potential can be supplied to each of the wirings GLa_u and GLb_u in the buffer portion 482_u connected to the selected register portion 481_u. Note that the potential of the wiring VLS is supplied to each of the wirings GLa_u and GLb_u in the buffer portion 482_u connected to the register portion 481_u that is not selected in the semiconductor device 480.

The register portion 481 illustrated in FIG. 52B includes a transistor M81, a transistor M82, a transistor M83, a transistor M84, a transistor M85, and a transistor M86. The transistor M81 has a function of establishing or breaking electrical continuity between the wiring VLD and a wiring NL81 in accordance with the potential of the wiring IN81. The transistor M82 has a function of establishing or breaking electrical continuity between the wiring VLD and a wiring NL82 in accordance with the potential of the wiring IN82. The transistor M83 has a function of establishing or breaking electrical continuity between the wiring VLS and the wiring NL81 in accordance with the potential of the wiring NL82. The transistor M84 has a function of establishing or breaking electrical continuity between the wiring VLS and the wiring NL82 in accordance with the potential of the wiring IN81. The transistor M85 has a function of establishing or breaking electrical continuity between the wiring IN83 and the wiring OUT81 in accordance with the potential of the wiring NL81. The transistor M86 has a function of establishing or breaking electrical continuity between the wiring VLS and the wiring OUT81 in accordance with the potential of the wiring NL82.

The buffer portion 482 illustrated in FIG. 52B includes a transistor M8A, a transistor M8B, a transistor M8C, and a transistor M8D. The transistor M8A has a function of establishing or breaking electrical continuity between the wiring IN8A and the wiring OUT8A in accordance with the potential of the wiring NL81. The transistor M8B has a function of establishing or breaking electrical continuity between the wiring IN8B and the wiring OUT8B in accordance with the potential of the wiring NL81. The transistor M8C has a function of establishing or breaking electrical continuity between the wiring VLS and the wiring OUT8A in accordance with the potential of the wiring NL82. The transistor M8D has a function of establishing or breaking electrical continuity between the wiring VLS and the wiring OUT8B in accordance with the potential of the wiring NL82.

FIG. 52D is a timing chart showing operation examples of the register portion 481 and the buffer portion 482 illustrated in FIG. 52B.

In the following description of the operation, a potential H is supplied to the wiring VLD and a potential L is supplied to the wiring VLS. The potential H or the potential L is supplied to each of the wirings IN81, IN82, IN83, IN8A, and IN8B. Note that the potential H is higher than the potential L. For example, the potential H is higher than the potential L by at least the threshold voltage of a transistor.

The timing chart in FIG. 52D shows the potentials (H and L) supplied to the wirings IN81, IN82, IN83, IN8A, and IN8B in the operation periods (Periods T81 to T83). In addition, changes in the potentials of the wirings NL81, NL82, OUT81, OUT8A, and OUT8B are shown.

In Period T81, the potential L is supplied to each of the wirings IN81 and IN82. The potential of the wiring NL82 is the potential H. Accordingly, the potential L is supplied to the wiring NL81. Here, the transistors M85, M8A, and M8B are in the off state (non-conduction state) and the transistors M86, M8C, and M8D are in the on state (conduction state). Accordingly, the potential L is supplied to each of the wirings OUT81, OUT8A, and OUT8B regardless of the potential (H or L) of each of the wirings IN83, IN8A, and IN8B. Note that in the following description of the operation, unless otherwise specified, the potentials of the wirings supplied in the immediately preceding period are maintained.

In Period T82, the potential His supplied to the wiring IN81, so that the potential of the wiring NL82 becomes the potential L and the potential of the wiring NL81 becomes the potential H. Thus, the transistors M85, M8A, and M8B are turned on and the transistors M86, M8C, and M8D are turned off. Accordingly, the potentials (H or L) of the wirings IN83, IN8A, and IN8B are supplied to the wirings OUT81, OUT8A, and OUT8B through the transistors M85, M8A, and M8B, respectively. After that, even when the potential L is supplied to the wiring IN81, the potentials of the wirings NL82 and NL81 are maintained.

In Period T83, the potential His supplied to the wiring IN82, so that the potential of the wiring NL82 becomes the potential H and the potential of the wiring NL81 becomes the potential L. Thus, the transistors M85, M8A, and M8B are turned off and the transistors M86, M8C, and M8D are turned on. Accordingly, the potential L is supplied to each of the wirings OUT81, OUT8A, and OUT8B regardless of the potential (H or L) of each of the wirings IN83, IN8A, and IN8B. After that, even when the potential L is supplied to the wiring IN82, the potentials of the wirings NL82 and NL81 are maintained.

FIG. 52E is a circuit diagram illustrating modification examples of the register portion 481 and the buffer portion 482. A register portion 481a and a buffer portion 482a illustrated in FIG. 52E are different from the register portion 481 and the buffer portion 482 in including bootstrap circuits. That is, the register portion 481a includes a transistor M87 and a capacitor C81 in addition to the components of the register portion 481, and the buffer portion 482a includes a transistor M8E, a transistor M8F, a capacitor C8A, and a capacitor C8B in addition to the components of the buffer portion 482. Note that the capacitors C81, C8A, and C8B are sometimes referred to as bootstrap capacitors.

A gate of the transistor M87 is connected to the wiring VLD. A gate of the transistor M85 is connected to the wiring NL81 through a source and a drain of the transistor M87. The gate of the transistor M85 is also connected to the wiring OUT81 through the capacitor C81.

A gate of the transistor M8E is connected to the wiring VLD. A gate of the transistor M8A is connected to the wiring NL81 through a source and a drain of the transistor M8E. The gate of the transistor M8A is also connected to the wiring OUT8A through the capacitor C8A.

A gate of the transistor M8F is connected to the wiring VLD. A gate of the transistor M8B is connected to the wiring NL81 through a source and a drain of the transistor M8F. The gate of the transistor M8B is also connected to the wiring OUT8B through the capacitor C8B.

In the register portion 481, transmission of the potential H from the wiring IN83 to the wiring OUT81 causes a potential decrease depending on the threshold voltage in the transistor M85. Hence, with the use of the bootstrap circuit as in the register portion 481a, capacitive coupling between the bootstrap capacitors can maintain the on state of the transistor M85. In this manner, the potential H can be transmitted to the wiring OUT81 without causing the potential decrease depending on the threshold voltage.

Similarly, in the buffer portion 482, transmission of the potential H from the wiring IN8A to the wiring OUT8A causes a potential decrease depending on the threshold voltage in the transistor M8A and transmission of the potential H from the wiring IN8B to the wiring OUT8B causes a potential decrease depending on the threshold voltage in the transistor M8B. Hence, with the use of the bootstrap circuit as in the buffer portion 482a, capacitive coupling between the bootstrap capacitors can maintain the on state of the transistors M8A and M8B. In this manner, the potential H can be transmitted to each of the wirings OUT8A and OUT8B without causing the potential decrease depending on the threshold voltage.

The structure described in this embodiment can be used in appropriate combination with any of the structures described in the other embodiments and example.

### Embodiment 6

This embodiment will describe a structure example of a display device 500, which is a modification example of the display device 400 disclosed in the above embodiment.

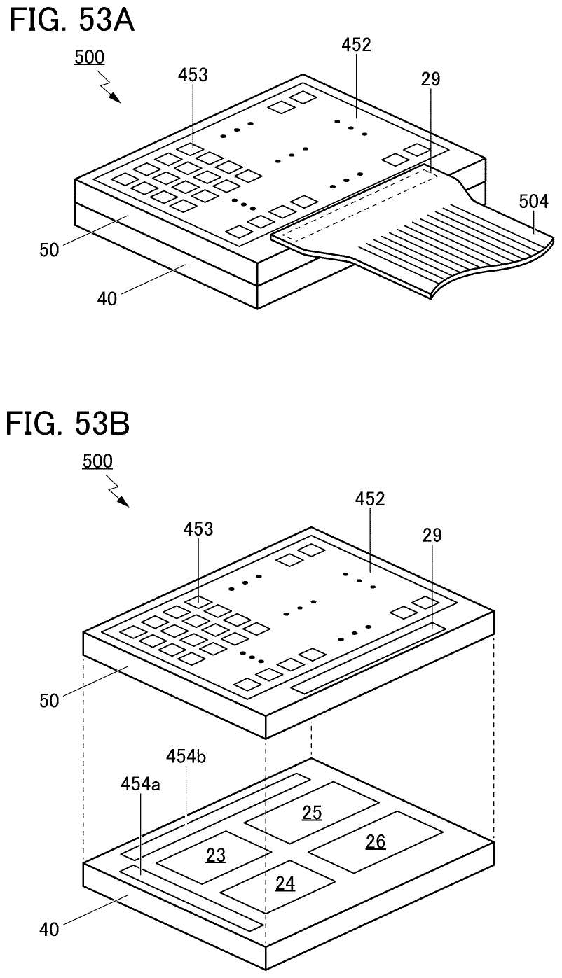

FIG. 53A is a perspective view of the display device 500. FIG. 53A illustrates a state where an FPC 504 is connected to an input terminal portion 29 of the display device 500. The display device 500 includes an element layer 40 and an element layer 50 overlapping with the element layer 40. FIG. 53B is a perspective view illustrating the element layer 40 and the element layer 50 separated from each other.

The element layer 50 includes the input terminal portion 29 and the display portion 452. The display portion 452 includes the plurality of pixels 453 arranged in a matrix. As disclosed in the above embodiment, the semiconductor device 10 can be used as each of the pixels 453. Power, a signal, and the like necessary for the operation of the display device 500 are supplied through the input terminal portion 29.

In the display device 500, the circuit portions 454a and 454b are provided in the element layer 40. By providing the circuit portions 454a and 454b in a layer different from the layer where the display portion 452 is provided, the width of the bezel around the display portion 452 can be small; thus, the area of the display portion 452 can be increased.

The definition of the display portion 452 can be increased with increasing area of the display portion 452. Under a fixed definition of the display portion 452, the area occupied by one pixel can be increased. Thus, the emission luminance of the display portion 452 can be increased. In addition, the aperture ratio of the pixels can be increased. For example, the aperture ratio of the pixels can be greater than or equal to 40% and less than 100%, preferably greater than or equal to 50% and less than or equal to 95%, further preferably greater than or equal to 60% and less than or equal to 95%. The density of current supplied to the light-emitting element 61 can be reduced with increasing area of one pixel. Thus, the load on the light-emitting element 61 can be reduced, leading to higher reliability of the display device 500.

When the display portion 452 and the circuit portions 454a and 454b are stacked, the wirings for electrical connection between them can be shortened. Thus, the wiring resistance and the parasitic capacitance can be reduced, and the operation speed of the display device 500 can be increased. Furthermore, the power consumption of the display device 500 is reduced.

The element layer 40 may include a central processing unit (CPU) 23, a graphics processing unit (GPU) 24, a memory circuit portion 25, a neural processing unit (NPU) 26, and the like in addition to the peripheral driver circuit. In this embodiment and the like, the peripheral driver circuit, the CPU 23, the GPU 24, the memory circuit portion 25, and the NPU 26 are sometimes collectively referred to as a “functional circuit”.

The CPU 23 has a function of controlling the operations of the circuits provided in the element layer 40, such as the GPU 24 and the NPU 26, in accordance with a program stored in the memory circuit portion 25, for example. The GPU 24 has a function of performing arithmetic processing for producing image data. Furthermore, the GPU 24 can perform a large number of matrix operations (product-sum operations) in parallel. The GPU 24 has a function of correcting image data using correction data stored in the memory circuit portion 25, for example. The GPU 24 has a function of generating image data in which brightness, hue, contrast, or the like is corrected, for example. Moreover, the NPU 26 can perform arithmetic processing for artificial intelligence (AI) at high speed. Each of the GPU 24 and the NPU 26 can perform arithmetic processing using a neural network at high speed, for example.

Upconversion or downconversion of image data can be performed using the GPU 24. A super-definition circuit can be provided in the element layer 40, for example. The super-definition circuit has a function of determining a potential of any pixel included in the display portion 452 by a product-sum operation of weights and potentials of pixels in the periphery of the pixel. The super-definition circuit has a function of upconverting image data with a definition lower than that of the display portion 452 to image data with a definition equivalent to that of the display portion 452. The super-definition circuit has a function of downconverting image data with a definition higher than that of the display portion 452 to image data with a definition equivalent to that of the display portion 452.

Providing the super-definition circuit can reduce the load on the GPU 24. For example, the GPU 24 executes processing up to 2K definition (or 4K definition) and the super-definition circuit performs upconversion to 4K definition (or 8K definition), whereby the load on the GPU 24 can be reduced. Downconversion can be performed in a similar manner.

Note that the functional circuit included in the element layer 40 does not necessarily include all of these components, and may include another component. For example, a potential generating circuit that generates a plurality of different potentials, a power management circuit that controls supply and stop of power for each circuit included in the display device 500, or the like may be provided. As the functional circuit, a digital signal processing (DSP) circuit, a sensor circuit, a communication circuit, a field programmable gate array (FPGA), or the like may be provided.

The supply and stop of power may be performed for each circuit included in the CPU 23. For example, power consumption can be reduced by stopping supply of power to a circuit, which is determined not to be used for a while, of the circuits included in the CPU 23, and restarting the supply of power to the circuit as needed. Data necessary for restarting supply of power is stored in a memory circuit in the CPU 23, the memory circuit portion 25, or the like before the circuit is stopped. By storing data necessary for recovery of the circuit, high-speed recovery of the circuit stopped can be performed. Note that supply of a clock signal may be stopped to stop the circuit operation.

Some of the transistors in the functional circuit included in the element layer 40 can be provided in the element layer 50. Some of the transistors in the pixels 453 included in the element layer 50 can be provided in the element layer 40. Thus, the functional circuit can include a Si transistor and an OS transistor. The pixels 453 can each include a Si transistor and an OS transistor.

Either n-channel transistors or p-channel transistors can be used as the transistors included in the display device 500. Furthermore, both n-channel transistors and p-channel transistors can be used as the transistors included in the display device 500. For example, a CMOS circuit in which an n-channel transistor and a p-channel transistor are combined can be used as any of the circuits included in the display device 500.

A crystalline silicon substrate can be used as the element layer 40, and the functional circuit included in the element layer 40 can be formed using crystalline Si transistors. Alternatively, an SOI substrate can be used as the element layer 40. A thin film transistor can be used as each of the transistors in the display portion 452 included in the element layer 40. A thin film transistor can be provided over various substrates and is thus suitable as a transistor provided to overlap with the element layer 40.

The structure described in this embodiment can be used in appropriate combination with any of the structures described in the other embodiments and example.

### Embodiment 7

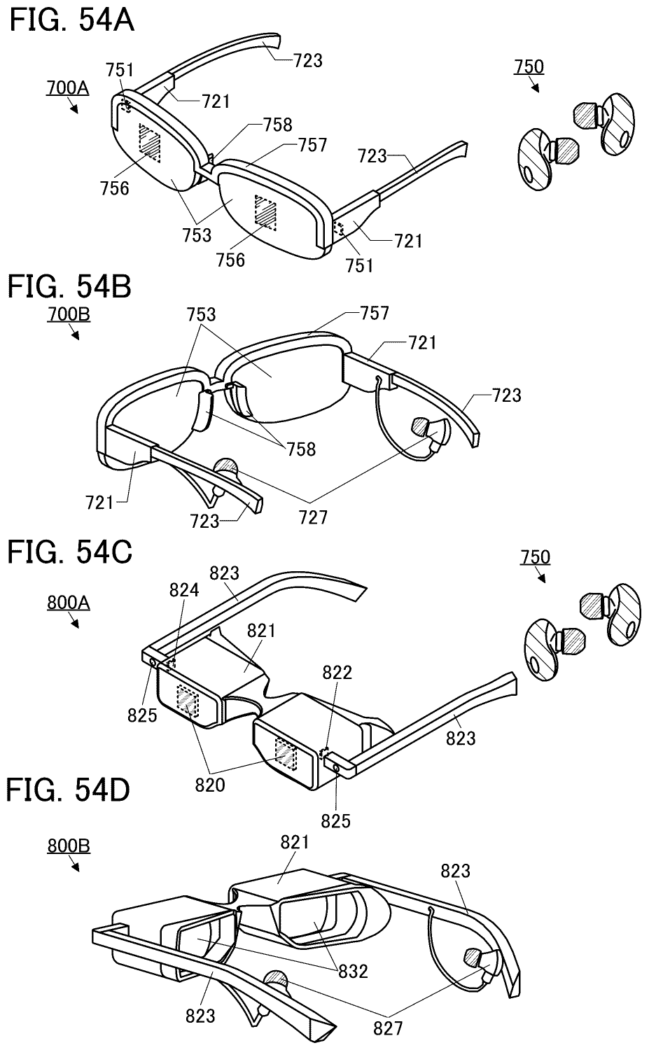

In this embodiment, electronic devices of one embodiment of the present invention will be described with reference to FIGS. 54A to 54D, FIGS. 55A to 55F, and FIGS. 56A to 56G.

In each of the electronic devices of this embodiment, a display portion includes a display device including the semiconductor device of one embodiment of the present invention (hereinafter, also simply referred to as a “display device”). The display device can be easily increased in resolution and definition. Thus, the display device can be used for a display portion of any of various electronic devices.

Examples of the electronic devices include a digital camera, a digital video camera, a digital photo frame, a mobile phone, a portable game machine, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display device of one embodiment of the present invention can have a high resolution, and thus can be used for an electronic device having a relatively small display portion. Examples of such an electronic device include wearable devices capable of being worn on a wrist, such as watch-type and bracelet-type information terminal devices; and wearable devices capable of being worn on a head, such as a virtual reality (VR) device like a head-mounted display, a glasses-type augmented reality (AR) device, a substitutional reality (SR) device, and a mixed reality (MR) device.

The definition of the display device of one embodiment of the present invention can be as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, it is possible to achieve a definition of 4K, 8K, or higher. The pixel density (resolution) of the display device of one embodiment of the present invention can be higher than or equal to 300 ppi, higher than or equal to 500 ppi, or higher than or equal to 1000 ppi. Alternatively, the resolution can be higher than or equal to 3000 ppi or higher than or equal to 5000 ppi. The use of the display device having one or both of such high definition and high resolution can further increase realistic sensation, sense of depth, and the like. There is no particular limitation on the screen ratio (the ratio of the vertical length to the horizontal length of the screen) of the display device of one embodiment of the present invention. For example, the display device of one embodiment of the present invention is compatible with a variety of screen ratios such as 1:1 (a square), 4:3, 16:9, and 16:10.

The electronic device described in this embodiment can include a sensor (a sensor having a function of sensing, detecting, or measuring force, displacement, position, speed, acceleration, angular velocity, rotational frequency, distance, light, liquid, magnetism, temperature, a chemical substance, sound, time, hardness, an electric field, current, voltage, power, radiation, a flow rate, humidity, gradient, oscillation, a smell, or infrared rays).

The electronic device described in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of head-mounted wearable devices will be described with reference to FIGS. 54A to 54D. The wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 700A illustrated in FIG. 54A and an electronic device 700B illustrated in FIG. 54B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic devices are capable of performing ultrahigh-resolution display.

The electronic devices 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic devices 700A and 700B are capable of AR display.

In the electronic devices 700A and 700B, a camera capable of capturing images of the front side can be provided as the image capturing portion. Furthermore, when the electronic devices 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential can be provided.

The electronic devices 700A and 700B are each provided with a battery so that they can be charged wirelessly and/or by wire.

A touch sensor module can be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be used for the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 54C and an electronic device 800B illustrated in FIG. 54D each include a pair of display portions 820, a housing 821, a communication portion 822, a pair of wearing portions 823, a control portion 824, a pair of image capturing portions 825, and a pair of lenses 832.

The display device of one embodiment of the present invention can be used for the display portions 820. Thus, the electronic devices are capable of performing ultrahigh-resolution display. Such electronic devices provide a high level of immersion to the user.

The display portions 820 are positioned inside the housing 821 so as to be seen through the lenses 832. When the pair of display portions 820 display different images, three-dimensional display using parallax can be performed.

The electronic devices 800A and 800B can be regarded as electronic devices for VR. The user who wears the electronic device 800A or the electronic device 800B can see images displayed on the display portions 820 through the lenses 832.

The electronic devices 800A and 800B preferably include a mechanism for adjusting the lateral positions of the lenses 832 and the display portions 820 so that the lenses 832 and the display portions 820 are positioned optimally in accordance with the positions of the user's eyes. Moreover, the electronic devices 800A and 800B preferably include a mechanism for adjusting focus by changing the distance between the lenses 832 and the display portions 820.

The electronic device 800A or the electronic device 800B can be worn on the user's head with the wearing portions 823. FIG. 54C and the like illustrate examples in which the wearing portions 823 have a shape like a temple of glasses; however, one embodiment of the present invention is not limited thereto. The wearing portions 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras can be provided so as to cover a plurality of fields of view, such as a telescope field of view and a wide field of view.

Although an example in which the image capturing portion 825 is provided is illustrated here, a range sensor (hereinafter, also referred to as a sensing portion) capable of measuring a distance between the user and an object may be provided. In other words, the image capturing portion 825 is one embodiment of the sensing portion. As the sensing portion, an image sensor or a range image sensor such as a light detection and ranging (LiDAR) sensor can be used, for example. By using images obtained by the cameras and images obtained by the range image sensor, more pieces of information can be obtained and a gesture operation with higher accuracy is possible.

The electronic device 800A can include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy videos and sound only by wearing the electronic device 800A.

The electronic devices 800A and 800B can each include an input terminal. To the input terminal, a cable for supplying a video signal from a video output device or the like, power for charging the battery provided in the electronic device, and the like can be connected.

The electronic device of one embodiment of the present invention can have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A in FIG. 54A has a function of transmitting information to the earphones 750 with the wireless communication function. For another example, the electronic device 800A in FIG. 54C has a function of transmitting information to the earphones 750 with the wireless communication function.

The electronic device can include earphone portions. The electronic device 700B in FIG. 54B includes earphone portions 727. For example, the earphone portion 727 can be connected to the control portion by wire. Part of a wiring that connects the earphone portion 727 and the control portion can be positioned inside the housing 721 or the wearing portion 723.

Similarly, the electronic device 800B in FIG. 54D includes earphone portions 827. For example, the earphone portion 827 can be connected to the control portion 824 by wire. Part of a wiring that connects the earphone portion 827 and the control portion 824 can be positioned inside the housing 821 or the wearing portion 823. Alternatively, the earphone portions 827 and the wearing portions 823 can include magnets. This is preferable because the earphone portions 827 can be fixed to the wearing portions 823 with magnetic force and thus can be easily housed.

The electronic device can include an audio output terminal to which earphones, headphones, or the like can be connected. The electronic device can include one or both of an audio input terminal and an audio input mechanism. As the audio input mechanism, a sound collecting device such as a microphone can be used, for example. The electronic device can have a function of a headset by including the audio input mechanism.

As described above, both the glasses-type device (e.g., the electronic devices 700A and 700B) and the goggles-type device (e.g., the electronic devices 800A and 800B) are preferable as the electronic device of one embodiment of the present invention.

The electronic device of one embodiment of the present invention can transmit information to earphones by wire or wirelessly.

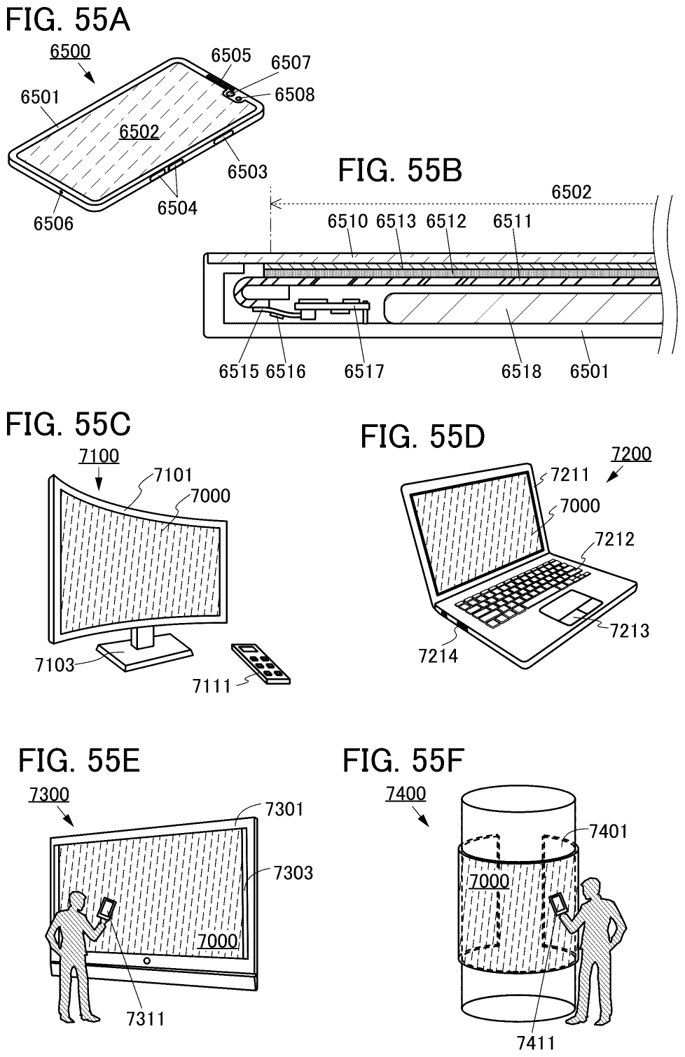

An electronic device 6500 illustrated in FIG. 55A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used for the display portion 6502.

FIG. 55B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display device of one embodiment of the present invention can be used for the display panel 6511. When the thickness of the display panel 6511 is reduced, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be obtained.

FIG. 55C illustrates an example of a television device. In a television device 7100, a display portion 7000 is incorporated in a housing 7101. Here, the housing 7101 is supported by a stand 7103. The display device of one embodiment of the present invention can be used for the display portion 7000 in FIG. 55C.

Operation of the television device 7100 illustrated in FIG. 55C can be performed with an operation switch provided in the housing 7101 and a separate remote control 7111. Alternatively, the display portion 7000 may include a touch sensor, and the television device 7100 can be operated by touch on the display portion 7000 with a finger or the like. The remote control 7111 can be provided with a display portion for displaying information output from the remote control 7111. With operation keys or a touch panel provided in the remote control 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (only from a transmitter to a receiver) or two-way (between a transmitter and a receiver or between receivers, for example) information communication can be performed.

FIG. 55D illustrates an example of a laptop computer. A laptop computer 7200 includes a housing 7211, a keyboard 7212, a pointing device 7213, an external connection port 7214, and the like. The display portion 7000 is incorporated in the housing 7211. The display device of one embodiment of the present invention can be used for the display portion 7000 in FIG. 55D.

FIGS. 55E and 55F illustrate examples of digital signage.

Digital signage 7300 illustrated in FIG. 55E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 55F illustrates digital signage 7400 attached to a cylindrical pillar 7401. The digital signage 7400 includes the display portion 7000 provided along a curved surface of the pillar 7401. The display device of one embodiment of the present invention can be used for the display portion 7000 in each of FIGS. 55E and 55F.

A larger area of the display portion 7000 allows a larger amount of information to be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIGS. 55E and 55F, it is preferable that the digital signage 7300 or the digital signage 7400 be capable of working with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

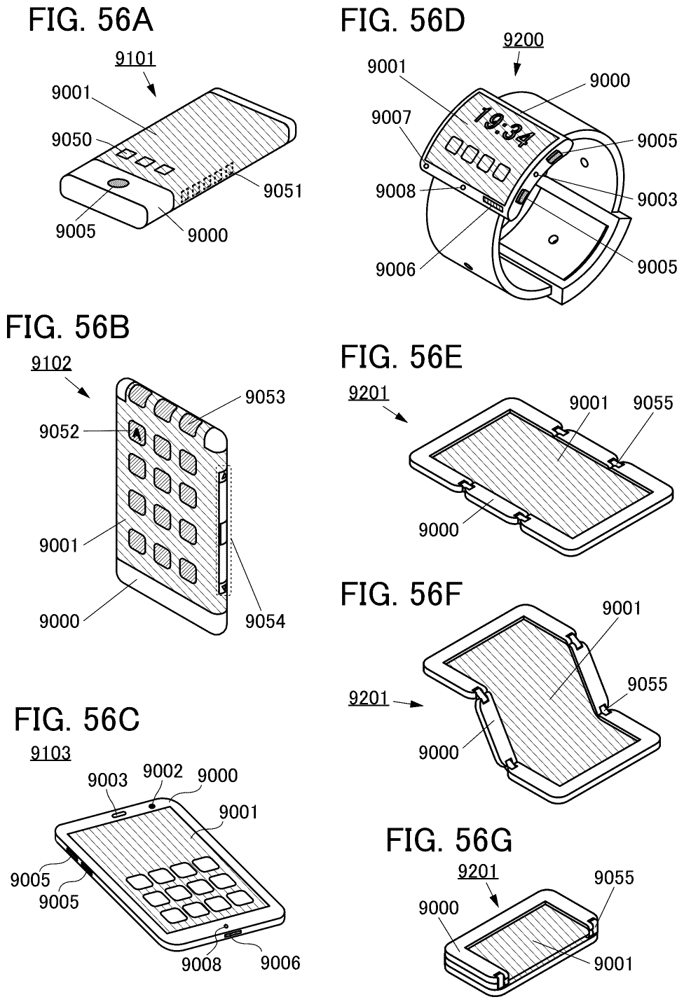

Electronic devices illustrated in FIGS. 56A to 56G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, an electric field, current, voltage, power, radiation, a flow rate, humidity, gradient, oscillation, a smell, or infrared rays), a microphone 9008, and the like.

The display device of one embodiment of the present invention can be used for the display portion 9001 in FIGS. 56A to 56G.

The electronic devices illustrated in FIGS. 56A to 56G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices can include a plurality of display portions. The electronic devices can be provided with a camera or the like and have a function of capturing a still image or a moving image and storing the captured image in a recording medium (an external recording medium or a recording medium incorporated in the camera), a function of displaying the captured image on the display portion, and the like.

The electronic devices illustrated in FIGS. 56A to 56G will be described in detail below.

FIG. 56A is a perspective view of a portable information terminal 9101. The portable information terminal 9101 can be used as a smartphone, for example. The portable information terminal 9101 can include the speaker 9003, the connection terminal 9006, the sensor 9007, and the like. The portable information terminal 9101 can display text and image information on its plurality of surfaces. FIG. 56A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like; the title, the sender, and the date and time of an e-mail, an SNS message, or the like; the time; the remaining battery; and the radio field intensity. Alternatively, the icon 9050 or the like can be displayed at the position where the information 9051 is displayed.

FIG. 56B is a perspective view of a portable information terminal 9102. The portable information terminal 9102 has a function of displaying information on three or more surfaces of the display portion 9001. Here, for example, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 56C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 56D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 56E to 56G are perspective views of a foldable portable information terminal 9201. FIG. 56E is a perspective view illustrating the portable information terminal 9201 that is opened. FIG. 56G is a perspective view illustrating the portable information terminal 9201 that is folded. FIG. 56F is a perspective view illustrating the portable information terminal 9201 that is shifted from one of the states in FIGS. 56E and 56G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

The structure described in this embodiment can be used in appropriate combination with any of the structures described in the other embodiments and example.

### Example

Six transistors 200F were fabricated under the conditions where the series number was any of three levels of 1, 2, and 3 and the thickness of a gate insulating layer (GI thickness) was either of two levels of 30 nm and 50 nm, and the reliability of the transistors was evaluated. Table 1 shows the sample names and conditions of the six fabricated transistors 200F.

TABLE 1

| Sample name | A30 | B30 | C30 | A50 | B50 | C50 |
|---|---|---|---|---|---|---|
| Plot name | 830a | 830b | 830c | 850a | 850b | 850c |
| GI thickness | 30 | 30 | 30 | 50 | 50 | 50 |
| (nm) | | | | | | |
| Series number | 1 | 2 | 3 | 1 | 2 | 3 |
| L (nm) | 200 | 200 × 2 | 200 × 3 | 200 | 200 × 2 | 200 × 3 |
| W (nm) | 130 | 130 | 130 | 130 | 130 | 130 |

A sample A30 is a single-gate transistor with a GI thickness of 30 nm, a channel length L of 200 nm, and a channel width W of 130 nm. A sample B30 is a multi-gate transistor with a GI thickness of 30 nm and a series number of 2. Since the series number of the sample B30 is 2, the channel length L is 200 nm×2 and the channel width W is 130 nm. A sample C30 is a multi-gate transistor with a GI thickness of 30 nm and a series number of 3. Since the series number of the sample C30 is 3, the channel length Lis 200 nm×3 and the channel width W is 130 nm.

A sample A50 is a single-gate transistor with a GI thickness of 50 nm, a channel length L of 200 nm, and a channel width W of 130 nm. A sample B50 is a multi-gate transistor with a GI thickness of 50 nm and a series number of 2. Since the series number of the sample B50 is 2, the channel length L is 200 nm×2 and the channel width W is 130 nm. A sample C50 is a multi-gate transistor with a GI thickness of 50 nm and a series number of 3. Since the series number of the sample C50 is 3, the channel length Lis 200 nm×3 and the channel width W is 130 nm.

The reliability of each transistor was evaluated in the following manner: a negative bias of −14.1 V was applied to the gate at 125° C. for a given time and a change in the electrical characteristics between before and after the negative bias application was measured.

Specifically, before the negative bias application, a drain current (Id) change with respect to a gate voltage (Vg) change (also referred to as “Id-Vg characteristics”) was measured first, and a value of Vg (also referred to as “Vsh”) at Id=1×10⁻¹² A was obtained from the measured Id-Vg characteristics. Note that Vsh at this time is referred to as initial Vsh.

The Id-Vg characteristics were measured under the conditions where the drain voltage (Vd) was set to 3.3 V, the source voltage was set to 0 V, and Vg was swept from −3.3 V to 3.3 V in increments of 0.1 V. The same potential was applied to the gate and the back gate. The Id-Vg characteristics were measured at 125° C.

Then, the negative bias was applied to the gate, the Id-Vg characteristics were measured and Vsh was obtained at given intervals, and a difference between the obtained Vsh and the initial Vsh (also referred to as “dVsh”) was obtained.

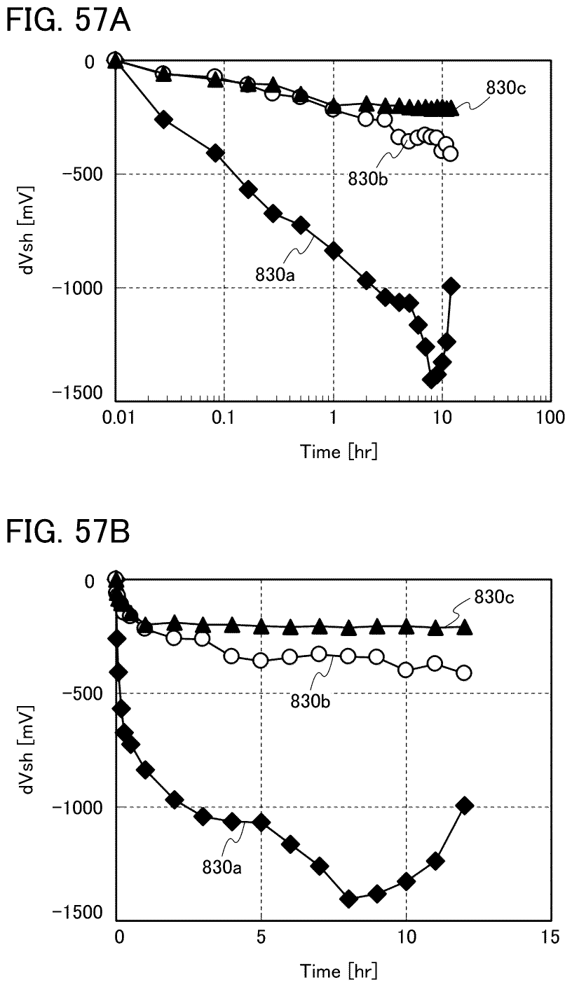

FIGS. 57A and 57B show the evaluation results of the reliability of the samples A30, B30, and C30. In FIGS. 57A and 57B, dVsh changes in the sample A30, the sample B30, and the sample C30 are denoted by a plot 830a, a plot 830b, and a plot 830c, respectively.

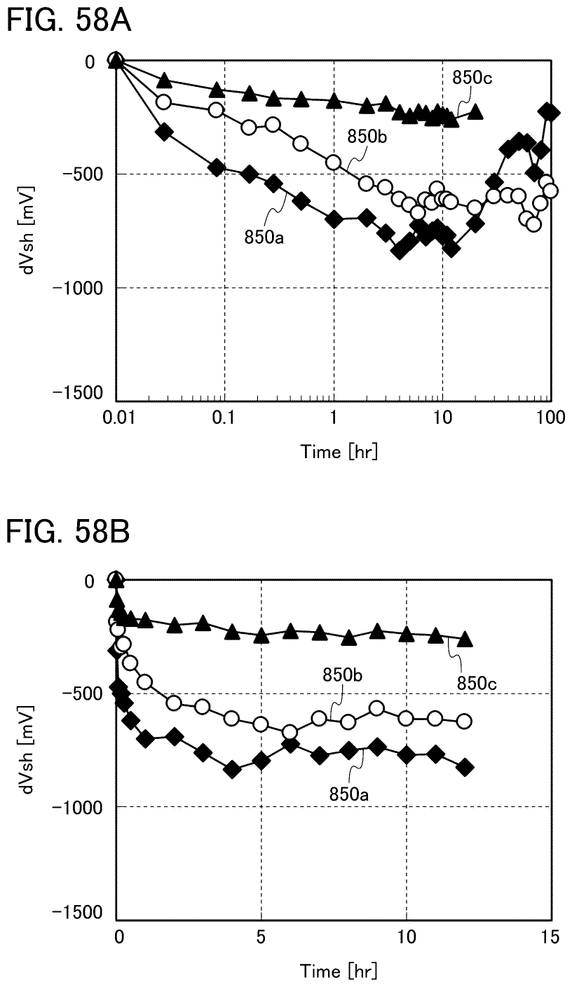

FIGS. 58A and 58B show the evaluation results of the reliability of the samples A50, B50, and C50. In FIGS. 58A and 58B, dVsh changes in the sample A50, the sample B50, and the sample C50 are denoted by a plot 850a, a plot 850b, and a plot 850c, respectively.

In each of FIGS. 57A and 57B and FIGS. 58A and 58B, the horizontal axis represents the application time of the negative bias and the vertical axis represents dVsh. The horizontal axis in each of FIG. 57A and FIG. 58A is on a log scale, and the horizontal axis in each of FIG. 57B and FIG. 58B is on a linear scale. FIGS. 57A and 57B show the same data, and FIGS. 58A and 58B show the same data.

FIGS. 57A and 57B and FIGS. 58A and 58B show that negative dVsh is caused by the negative bias application in all the samples. This indicates that the Id-Vg characteristics shift in the negative direction. That is, the transistor with a larger dVsh is more likely to be normally on by the negative bias application. Accordingly, the transistor with a smaller dVsh can be regarded as having higher reliability.

FIGS. 57A and 57B and FIGS. 58A and 58B reveal that the transistor with a larger series number has a smaller dVsh, i.e., higher reliability. In particular, each of the samples C30 and C50 with a series number of 3 has a smaller dVsh increase over time and higher reliability than the samples with a series number of 2 or less.

Thus, in the case where a large negative bias is applied to a gate of a transistor and/or in the case where a negative bias is applied to a gate for a long period, it is preferable to use a multi-gate transistor with a series number of 3 or more as the transistor. With the use of transistors each with a series number of 3 or more as at least some of transistors included in a semiconductor device, the reliability of the semiconductor device can be increased.

This application is based on Japanese Patent Application Serial No. 2024-012045 filed with Japan Patent Office on Jan. 30, 2024, the entire contents of which are hereby incorporated by reference.

What is claimed is:

1. A semiconductor device comprising:
a first transistor;
a second transistor;
a third transistor;
a fourth transistor;
a fifth transistor;
a sixth transistor;
a seventh transistor;
a first capacitor;
a second capacitor;
a third capacitor; and
a light-emitting element,
wherein the first transistor, the second transistor, the third transistor, the fourth transistor, the fifth transistor, the sixth transistor, and the seventh transistor each comprise a gate, a first terminal, and a second terminal,
wherein the first capacitor, the second capacitor, the third capacitor, and the light-emitting element each comprise a first terminal and a second terminal,
wherein the second transistor comprises a back gate,
wherein the second terminal of the first transistor is electrically connected to the gate of the second transistor, the first terminal of the third transistor, and the first terminal of the first capacitor,
wherein the back gate of the second transistor is electrically connected to the second terminal of the fourth transistor and the first terminal of the second capacitor,
wherein the second terminal of the second transistor is electrically connected to the second terminal of the third transistor, the second terminal of the first capacitor, the second terminal of the second capacitor, the first terminal of the fifth transistor, and the first terminal of the sixth transistor,
wherein the gate of the fifth transistor is electrically connected to the first terminal of the third capacitor and the second terminal of the seventh transistor,
wherein the second terminal of the fifth transistor is electrically connected to the second terminal of the third capacitor and the first terminal of the light-emitting element, and
wherein a channel length of the first transistor is longer than each of a channel length of the third transistor, a channel length of the fourth transistor, and a channel length of the seventh transistor.

2. The semiconductor device according to claim 1,
wherein the gate of the first transistor is electrically connected to a first wiring,
wherein the gate of the third transistor and the gate of the fourth transistor are electrically connected to a second wiring,
wherein the first terminal of the seventh transistor is electrically connected to a third wiring,
wherein the gate of the sixth transistor and the gate of the seventh transistor are electrically connected to a fourth wiring,
wherein the first terminal of the first transistor is electrically connected to a fifth wiring,
wherein the first terminal of the second transistor is electrically connected to a sixth wiring,
wherein the first terminal of the fourth transistor is electrically connected to a seventh wiring,
wherein the second terminal of the sixth transistor is electrically connected to an eighth wiring, and
wherein the second terminal of the light-emitting element is electrically connected to a ninth wiring.

3. The semiconductor device according to claim 1, wherein a semiconductor layer where a channel of the first transistor is formed comprises an oxide semiconductor.

4. The semiconductor device according to claim 1, wherein the light-emitting element is an organic EL element.

5. A semiconductor device comprising:
a first transistor;
a second transistor;
a third transistor;
a fourth transistor;
a fifth transistor;
a sixth transistor;
a seventh transistor;
a first capacitor;
a second capacitor;
a third capacitor; and
a light-emitting element,
wherein the first transistor, the second transistor, the third transistor, the fourth transistor, the fifth transistor, the sixth transistor, and the seventh transistor each comprise a gate, a first terminal, and a second terminal,
wherein the first capacitor, the second capacitor, the third capacitor, and the light-emitting element each comprise a first terminal and a second terminal,
wherein the second transistor comprises a back gate,
wherein the second terminal of the first transistor is electrically connected to the gate of the second transistor, the first terminal of the third transistor, and the first terminal of the first capacitor,
wherein the back gate of the second transistor is electrically connected to the second terminal of the fourth transistor and the first terminal of the second capacitor,
wherein the second terminal of the second transistor is electrically connected to the second terminal of the third transistor, the second terminal of the first capacitor, the second terminal of the second capacitor, the first terminal of the fifth transistor, and the first terminal of the sixth transistor,
wherein the gate of the fifth transistor is electrically connected to the first terminal of the third capacitor and the second terminal of the seventh transistor,
wherein the second terminal of the fifth transistor is electrically connected to the second terminal of the third capacitor and the first terminal of the light-emitting element,
wherein the first transistor is a multi-gate transistor with a series number greater than or equal to 3, and
wherein the third transistor, the fourth transistor, and the seventh transistor are each a multi-gate transistor with a series number less than or equal to the series number of the first transistor.

6. The semiconductor device according to claim 5,
wherein the gate of the first transistor is electrically connected to a first wiring,
wherein the gate of the third transistor and the gate of the fourth transistor are electrically connected to a second wiring,
wherein the first terminal of the seventh transistor is electrically connected to a third wiring,
wherein the gate of the sixth transistor and the gate of the seventh transistor are electrically connected to a fourth wiring,
wherein the first terminal of the first transistor is electrically connected to a fifth wiring,
wherein the first terminal of the second transistor is electrically connected to a sixth wiring,
wherein the first terminal of the fourth transistor is electrically connected to a seventh wiring,
wherein the second terminal of the sixth transistor is electrically connected to an eighth wiring, and
wherein the second terminal of the light-emitting element is electrically connected to a ninth wiring.

7. The semiconductor device according to claim 5, wherein a semiconductor layer where a channel of the first transistor is formed comprises an oxide semiconductor.

8. The semiconductor device according to claim 5, wherein the light-emitting element is an organic EL element.
